(19) United States
(12) Patent Application Publication
(10) Pub. No.: US 2024/0349592 A1
(43) Pub. Date: Oct. 17, 2024

(54) ORGANIC COMPOUND AND ORGANIC LIGHT-EMITTING ELEMENT

(71) Applicant: CANON KABUSHIKI KAISHA, Tokyo (JP)

(72) Inventors: NAOKI YAMADA, Tokyo (JP); JUN KAMATANI, Tokyo (JP); HIROKI OHRUI, Tokyo (JP); HIRONOBU IWAWAKI, Kanagawa (JP); YOSUKE NISHIDE, Kanagawa (JP); HIROKAZU MIYASHITA, Miyagi (JP)

(21) Appl. No.: 18/749,442

(22) Filed: Jun. 20, 2024

Related U.S. Application Data
(63) Continuation of application No. PCT/JP2022/046016, filed on Dec. 14, 2022.

(30) Foreign Application Priority Data
Dec. 22, 2021 (JP) 2021-208535

(51) Int. Cl. H10K 85/30; C07F 15/00; C09K 11/06; H10K 50/12; H10K 101/10

(52) U.S. Cl. CPC H10K 85/342; C07F 15/0033; C09K 11/06; C09K 2211/1029; C09K 2211/185; H10K 50/12; H10K 2101/10

(57) ABSTRACT

An organometallic complex represented by any one of formulas (1) to (3):

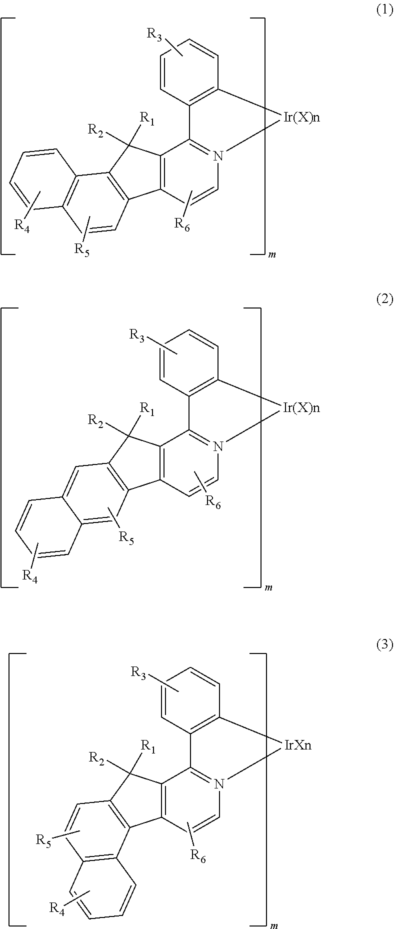

In formulas (1) to (3), R₁ and R₂ are each independently selected from the group consisting of a hydrogen atom, a deuterium atom, hydrogen atoms, alkyl groups, silyl groups, and aryl groups. R₃s are each independently selected from the group consisting of a deuterium atom, halogen atoms, a cyano group, alkyl groups, alkoxy groups, silyl groups, aryl groups, heterocyclic groups, and amino groups. Substituents may form a ring with each other. R₄ to R₆ are each independently selected from the group consisting of a deuterium atom, halogen atoms, a cyano group, alkyl groups, alkoxy groups, silyl groups, aryl groups, heterocyclic groups, and amino groups.

### CROSS-REFERENCE TO RELATED APPLICATIONS

This application is a Continuation of International Patent Application No. PCT/JP2022/046016, filed Dec. 14, 2022, which claims the benefit of Japanese Patent Application No. 2021-208535, filed Dec. 22, 2021, both of which are hereby incorporated by reference herein in their entirety.

### TECHNICAL FIELD

The present disclosure relates to an organic compound and an organic light-emitting element using the same.

### BACKGROUND ART

An organic light-emitting element (hereinafter also referred to as “organic electroluminescent element” or “organic EL element”) includes a pair of electrodes and an organic compound layer disposed between the electrodes. Electrons and holes are injected into the organic compound layer from the electrodes, thereby generating excitons of the luminescent organic compound in the organic compound layer. When the excitons return to the ground state, the organic light-emitting element emits light.

Organic light-emitting elements have recently advanced remarkably and feature low driving voltage, a variety of emission wavelengths, fast response, and the possibility of achieving thinner and lighter-weight light-emitting devices.

Luminescent organic compounds have been actively developed up to now. Developing highly luminescent compounds is important for providing a high-performance organic light-emitting element.

The following compound A-1, which is disclosed in PTL 1, is a compound that has been developed so far.

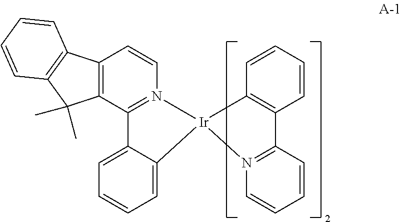

### CITATION LIST

### Patent Literature

PTL 1 PCT Japanese Translation Patent Publication No. 2012-522844
PTL 1 discloses Compound A-1 as a luminescent material, but Compound A-1 has an disadvantage with luminous efficiency.

### SUMMARY OF INVENTION

Accordingly, the present disclosure provides an organometallic complex with excellent luminous efficiency.

The organometallic complex of the present disclosure is represented by any one of formulas (1) to (3):

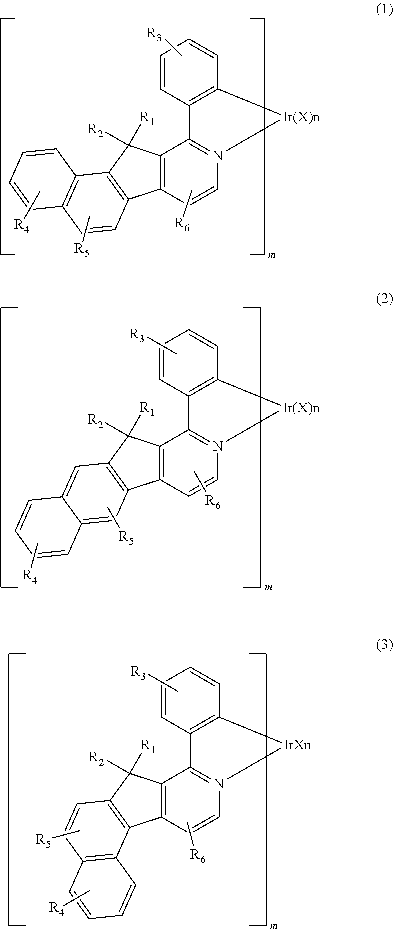

In formulas (1) to (3), R₁ and R₂ are each independently selected from the group consisting of a hydrogen atom, a deuterium atom, halogen atoms, substituted or unsubstituted alkyl groups, substituted or unsubstituted silyl groups, and substituted or unsubstituted aryl groups. R₃ represents a substituent of the phenyl groups, and plural R₃s are each independently selected from the group consisting of a deuterium atom, halogen atoms, a cyano group, substituted or unsubstituted alkyl groups, substituted or unsubstituted alkoxy groups, substituted or unsubstituted silyl groups, substituted or unsubstituted aryl groups, substituted or unsubstituted heterocyclic groups, and substituted or unsubstituted amino groups. The substituents may form a ring with each other. R₄ to R₆ are substituents of the ring structures forming an azabenzofluorene and are each independently selected from the group consisting of a deuterium atom, halogen atoms, a cyano group, substituted or unsubstituted alkyl groups, substituted or unsubstituted alkoxy groups, substituted or unsubstituted silyl groups, substituted or unsubstituted aryl groups, substituted or unsubstituted heterocyclic groups, and substituted or unsubstituted amino groups. m represents an integer of 1 to 3, n represents an integer of 0 to 2, and m+n is 3. X represents a bidentate ligand, and the substructure Ir(X)n is represented by either general formula (4) or (5). The three ligands may be the same or different.

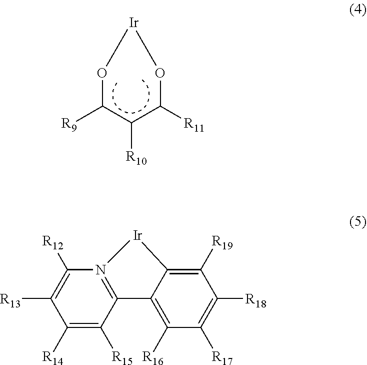

In general formula (4) or (5), R₉ to R₁₉ are each independently selected from the group consisting of a hydrogen atom, a deuterium atom, halogen atoms, a cyano group, substituted or unsubstituted alkyl groups, substituted or unsubstituted alkoxy groups, substituted or unsubstituted silyl groups, substituted or unsubstituted aryl groups, and substituted or unsubstituted heterocyclic groups. Substituents of R₁₆ to R₁₉ may form a ring with each other.

Further features of the present disclosure will become apparent from the following description of exemplary embodiments with reference to the attached drawings.

### BRIEF DESCRIPTION OF DRAWINGS

FIG. 1A is a schematic sectional view of a pixel of display device according to an embodiment of the present disclosure.

FIG. 1B is a schematic sectional view of a display device using an organic light-emitting element according to an embodiment of the present disclosure.

FIG. 2 is a schematic illustrative representation of a display device according to an embodiment of the present disclosure.

FIG. 3A is a schematic illustrative representation of an imaging device according to an embodiment of the present disclosure.

FIG. 3B is a schematic illustrative representation of a mobile device according to an embodiment of the present disclosure.

FIG. 4A is a schematic illustrative representation of a display device according to an embodiment of the present disclosure.

FIG. 4B is a schematic illustrative representation of an example of foldable display devices.

FIG. 5A is a schematic illustrative representation of a lighting device according to an embodiment of the present disclosure.

FIG. 5B is a schematic illustrative representation of an automobile that is an implementation of the movable apparatus according to an embodiment of the present disclosure.

FIG. 6A is a schematic illustrative representation of a wearable device according to an embodiment of the present disclosure.

FIG. 6B is a schematic illustrative representation of a wearable device according to an embodiment of the present disclosure, including an imaging device.

FIG. 7A is a schematic illustrative representation of an image forming apparatus according to an embodiment of the present disclosure.

FIG. 7B is a schematic illustrative representation of an exposure light source of the image forming apparatus according to an embodiment of the present disclosure.

FIG. 7C is a schematic illustrative representation of another exposure light source of the image forming apparatus according to an embodiment of the present disclosure.

FIG. 8 is a schematic illustrative representation of the structure of an organometallic complex and the steric structure of the ligands.

### DESCRIPTION OF EMBODIMENTS

In the description herein, halogen atoms include, but are not limited to, fluorine, chlorine, bromine, and iodine.

Alkyl groups include, but are not limited to, methyl, ethyl, n-propyl, isopropyl, n-butyl, tert-butyl, sec-butyl, octyl, cyclohexyl, tert-pentyl, 3-methypentan-3-yl, and 1-adamantyl, and 2-adamantyl.

Alkoxy groups include, but are not limited to, methoxy, ethoxy, propoxy, isopropoxy, tert-butoxy, 2-ethyl-octyloxy, and benzyloxy.

Aryloxy groups include, but are not limited to, phenoxy, naphthoxy, and thienyloxy.

Aryl groups include, but are not limited to, phenyl, naphthyl, indenyl, biphenyl, terphenyl, fluorenyl, phenanthryl, triphenylenyl, pyrenyl, anthranil, perylenyl, chrysenyl, and fluoranthenyl.

Heterocyclic groups include, but are not limited to, pyridyl, pyrimidyl, pyrazyl, triazyl, benzofuranyl, benzothiophenyl, dibenzofuranyl, dibenzothiophenyl, oxazolyl, oxadiazolyl, thiazolyl, thiadiazolyl, carbazolyl, acridinyl, and phenanthrolyl.

Silyl groups include, but are not limited to, trimethylsilyl and triphenylsilyl.

Examples of amino groups include, but are not limited to, N-methylamino, N-ethylamino, N,N-dimethylamino, N,N-diethylamino, N-methyl-N-ethylamino, N-benzylamino, N-methyl-N-benzylamino, N,N-dibenzylamino, anilino, N,N-diphenylamino, N,N-dinaphthylamino, N,N-difluorenylamino, N-phenyl-N-tolylamino, N,N-ditolylamino, N-methyl-N-phenylamino, N,N-dianisolylamino, N-mesityl-N-phenylamino, N,N-dimesitylamino, N-phenyl-N-(4-tert-butylphenyl)amino, and N-phenyl-N-(4-trifluoromethylphenyl)amino, N-piperidyl, carbazolyl, acridyl, trimethylamino, and triphenylamino.

Examples of the substituents that the above-mentioned alkyl, alkoxy, amino, aryl, heterocyclic, aryloxy, and silyl groups may further have include, but are not limited to, deuterium; alkyl groups, such as methyl, ethyl, n-propyl, isopropyl, n-butyl, and tert-butyl; aralkyl groups, such as benzyl; aryl groups, such as phenyl and biphenyl; heterocyclic groups, such as pyridyl and pyrrolyl; amino groups, such as dimethylamino, diethylamino, dibenzylamino, diphenylamino, and ditolylamino; alkoxy groups, such as methoxy, ethoxy, and propoxy; aryloxy groups, such as phenoxy; halogen atoms, such as fluorine, chlorine, bromine, and iodine; and a cyano group.

### (1) Organometallic Complex

First, the organometallic complex disclosed herein will be described.

The organometallic complex of the present disclosure is a compound represented by any one of general formulas (1) to (3). In the description herein, coordination bonds are represented by arrows or straight lines, and bonds other than coordination bonds are represented by straight lines. Azabenzofluorene represents a ring structure in which one of the carbon atoms in the benzofluorene is replaced with a nitrogen atom.

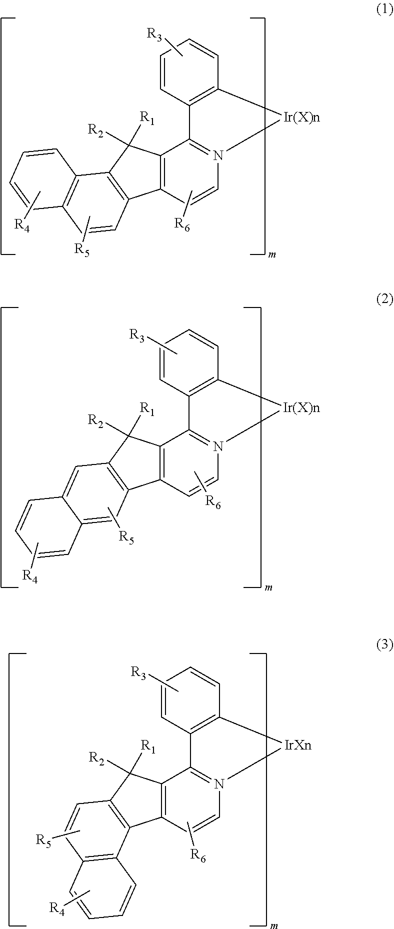

R₁ to R₆

In general formulas (1) to (3), R₁ and R₂ are each independently selected from the group consisting of a hydrogen atom, a deuterium atom, hydrogen atoms, substituted or unsubstituted alkyl groups, substituted or unsubstituted silyl groups, and substituted or unsubstituted aryl groups.

R₃ represents a substituent of the phenyl groups, and plural R₃s are each independently selected from the group consisting of a deuterium atom, halogen atoms, a cyano group, substituted or unsubstituted alkyl groups, substituted or unsubstituted alkoxy groups, substituted or unsubstituted silyl groups, substituted or unsubstituted aryl groups, substituted or unsubstituted heterocyclic groups, and substituted or unsubstituted amino groups. Substituents may form a ring with each other.

R₄ to R₆ are substituents of the ring structures forming an azabenzofluorene and are each independently selected from the group consisting of a deuterium atom, halogen atoms, a cyano group, substituted or unsubstituted alkyl groups, substituted or unsubstituted alkoxy groups, substituted or unsubstituted silyl groups, substituted or unsubstituted aryl groups, substituted or unsubstituted heterocyclic groups, and substituted or unsubstituted amino groups.

In the organometallic complexes represented by general formulas (1) to (3), R₁ and R₂ are preferably substituents, more preferably halogen atoms or substituted or unsubstituted alkyl groups with 1 to 4 carbon atoms, and each particularly preferably a fluorine atom or a methyl group.

Also, in the organometallic complexes represented by general formulas (1) to (3), at least either R₃ or R₄ is preferably a substituent, more preferably a tertiary alkyl group with 4 to 10 carbon atoms. Particularly preferably, the tertiary alkyl group is a tert-butyl group. Particularly preferably, R₃ has a substituent.

In the organometallic complexes represented by general formulas (1) to (3), a ring structure formed by plural R₃s is preferably a condensed ring structure of four or fewer rings, and the condensed ring structure preferably contains at least one of carbon, nitrogen, sulfur, oxygen, phosphorus, selenium, and tellurium atoms.

In general formulas (1) to (3), also, plural R₃S may form any one of the ring structures represented by the following general formulas (10) to (20), wherein the asterisk * indicates the position of the bond to the azabenzofluorene ring.

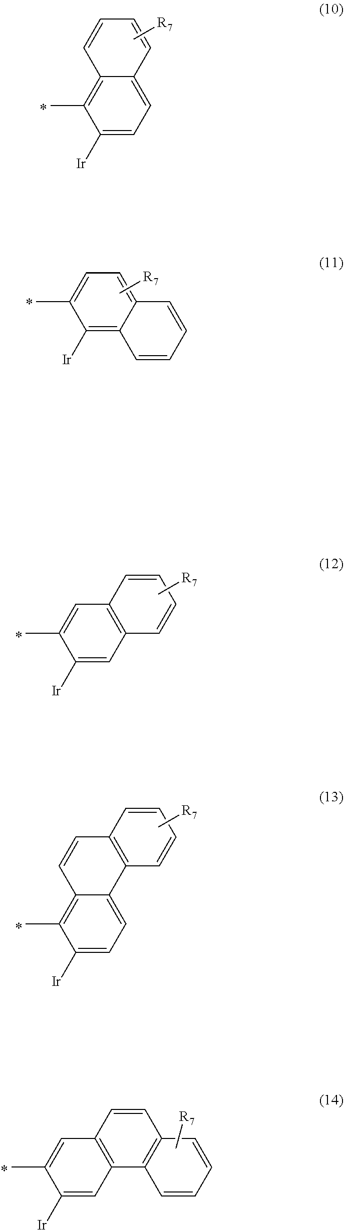

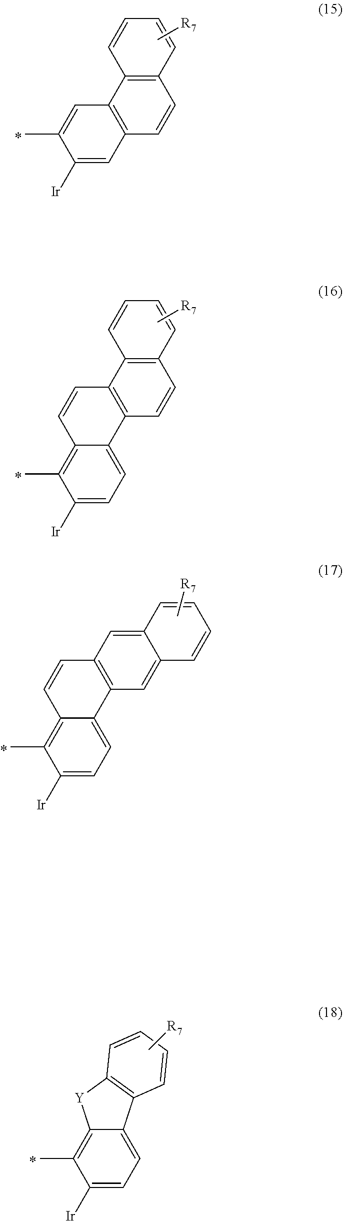

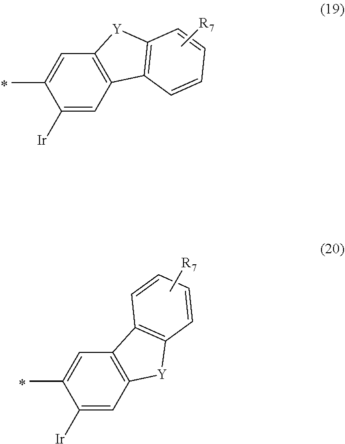

### R₇

R₇s in general formulas (10) to (20) are each independently selected from the group consisting of a hydrogen atom, a deuterium atom, halogen atoms, a cyano group, substituted or unsubstituted alkyl groups, substituted or unsubstituted alkoxy groups, substituted or unsubstituted silyl groups, substituted or unsubstituted aryl groups, and substituted or unsubstituted heterocyclic groups

### Y

Y represents any one of an oxygen atom, a sulfur atom, and C(R₂₀) (R₂₁).

R₂₀ and R₂₁

In general formulas (10) to (20), R₂₀ and R₂₁ are each a hydrogen atom, a deuterium atom, a substituted or unsubstituted alkyl group, a substituted or unsubstituted silyl group, or a substituted or unsubstituted aryl group.

m and n

In general formulas (1) to (3), m represents an integer of 1 to 3, and n represents an integer of 0 to 2. Also, m+n is 3.

### X

In general formulas (1) to (3), X represents a bidentate ligand, and the substructure Ir(X)n is represented by either general formula (4) or (5). The three ligands coordinating to the iridium atom may be the same as or different from each other.

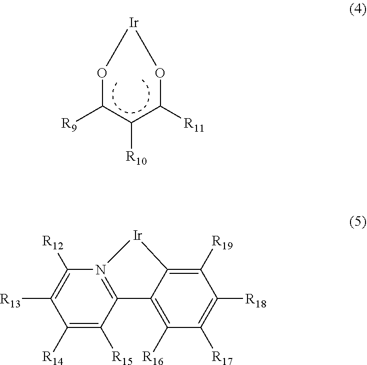

R₉ to R₁₉

In general formula (4) or (5), R₉ to R₁₉ are each independently selected from the group consisting of a hydrogen atom, a deuterium atom, halogen atoms, a cyano group, substituted or unsubstituted alkyl groups, substituted or unsubstituted alkoxy groups, substituted or unsubstituted silyl groups, substituted or unsubstituted aryl groups, and substituted or unsubstituted heterocyclic groups. Substituents of R₁₆ to R₁₉ may form a ring with each other.

The organometallic complexes represented by general formulas (1) to (3) have the following features:
(1-1) Exhibiting high emission quantum yield because the ligands include an azabenzofluorene ring; and
(1-2) Exhibiting high hole transporting ability because the ligands include an azabenzofluorene ring.

These features will now be described.

(1-1) Exhibiting high emission quantum yield because the ligands include an azabenzofluorene ring The iridium complexes represented by general formulas (1) to (3) have large transition dipole moments and high emission quantum yields because of the coordination of an azabenzofluorene ring to the iridium atom. Also, Table 1 shows that Compounds 1 and 2, which have an azabenzofluorene ring as a ligand, have higher emission quantum yields than Comparative Compound 1, which has an azafluorene ring as a ligand. Compounds 1 and 2 are Exemplified Compounds C-1 and E-1, respectively, which will be described later. In Compounds 1 and 2, benzene rings one more than in Comparative Compound 1 are fused, and this probably increases the transition dipole moment and emission quantum yield. Quantum yield was obtained by measuring the absolute quantum yield in dilute toluene solution using an absolute PL quantum yield measurement apparatus (C9920-02) manufactured by Hamamatsu Photonics. Each quantum yield is represented by a relative value to the quantum yield 1.0 of Compound 1.

TABLE 1

| Compound | | Emission quantum yield |
|---|---|---|
| Compound 1 (C-1) | 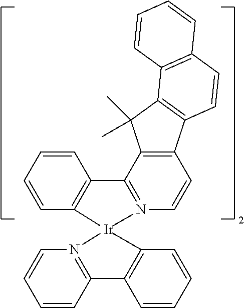 | 1.0 |
| Compound 2 (E-1) | 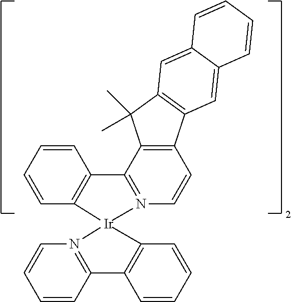 | 1.0 |
| Comparative Compound 1 | 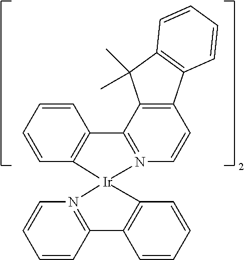 | 1.0 |

(1-2) Exhibiting high hole transporting ability because the ligands include an azabenzofluorene ring

The iridium complexes represented by general formulas (1) to (3) exhibit high hole transporting ability because the ligands include an azabenzofluorene ring. Probably, azabenzofluorene rings as ligands are likely to overlap with each other, and such a structure enables holes to easily hop among the ligands.

Preferably, the compound of the present disclosure further has the following features:
(1-3) Emitting luminescence with high color purity when R₁ and R₂ are substituents; and
(1-4) Exhibiting high sublimability when at least either the substituent R₃ or R₄ is a tertiary alkyl group.

These features will now be described.

(1-3) Emitting luminescence with high color purity when R₁ and R₂ are substituents

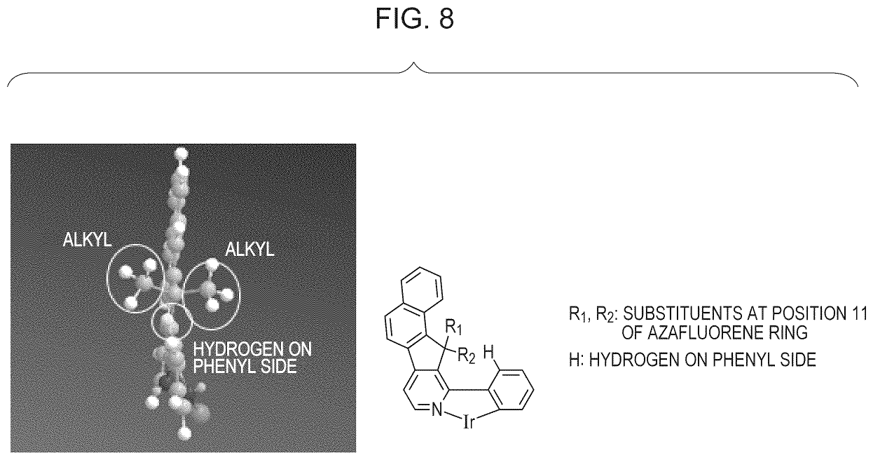

In the iridium complexes represented by general formulas (1) to (3), the two substituents R₁ and R₂ at the 11-position of the azabenzofluorene ring are located so as to sandwich a hydrogen atom of the phenyl group, as shown in FIG. 8. The hydrogen atom of the phenyl group repels both substituents of the azabenzofluorene ring, and thus, the dihedral angle between the phenyl group and the azabenzofluorene ring is fixed to reduce the vibration caused by rotation of the two rings. Consequently, the emission spectrum of the iridium complexes has a narrow half-width, and the complexes emit luminescence with high color purity. To obtain more of the above effects, R₁ and R₂ are preferably substituents, more preferably halogen atoms or substituted or unsubstituted alkyl groups with 1 to 4 carbon atoms, and each particularly preferably a fluorine atom methyl group.

In general formulas (1) to (3), preferably, plural R₃s form a ring structure represented by general formula (11), (12), (14), (15), (17), (19), or (20). In such a case, the two substituents R₁ and R₂ at the 11-position of the azabenzofluorene ring are easily located so as to sandwich a hydrogen atom of the phenyl group, consequently producing more of the above effects.

(1-4) Exhibiting high sublimability when at least either the substituent R₃ or R₄ is a substituent

The iridium complexes represented by general formulas (1) to (3) have the above-described features (1-1) to (1-3) because of the presence of an azabenzofluorene ring as a ligand. However, such a condensed polycyclic group increases the molecular weight of the complex and may reduce the sublimability. More specifically, the temperature for sublimation purification becomes high, or the resulting complex may partially decompose after sublimation purification. Accordingly, at least either R₃ or R₄ is preferably a substituent, more preferably a tertiary alkyl group with 4 to 10 carbon atoms, and particularly preferably a tert-butyl group. In this instance, the molecules of the complex are prevented from stacking, reducing the sublimation temperature. Tertiary alkyl groups have a large excluded volume effect and can prevent molecules from stacking effectively. Additionally, in the case of a tertiary alkyl group, radical cleavage of hydrogens at the benzylic position is reduced even at high temperatures.

Table 2 will now present the bond-dissociation energies of carbon-hydrogen bonds.

TABLE 2

| | Bond | Bond-dissociation energy (kcal/mol) |
|---|---|---|
| Methyl | 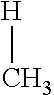 | 105 |
| Ethyl | 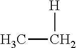 | 101 |
| Phenyl | 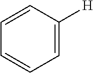 | 113 |
| Benzyl | 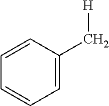 | 90 |

Higher bond dissociation energies indicate stronger bonds, while lower bond dissociation energies indicate weaker bonds. Thus, the carbon-hydrogen bond at the benzylic position is weaker than other bonds. This is because when a hydrogen atom at the benzylic position desorbs to form a radical, n-electron resonance occurs between the radical and the adjacent benzene ring to stabilize the radical. This is the reason why the carbon-hydrogen bond at the benzylic position is weaker than other bonds. Therefore, structures having no benzylic position or the like in the molecule, in which carbon-hydrogen bonds are not likely to be cleaved, are preferred.

Specific examples of the organometallic complex according to the present disclosure include, but are not limited to, the following:

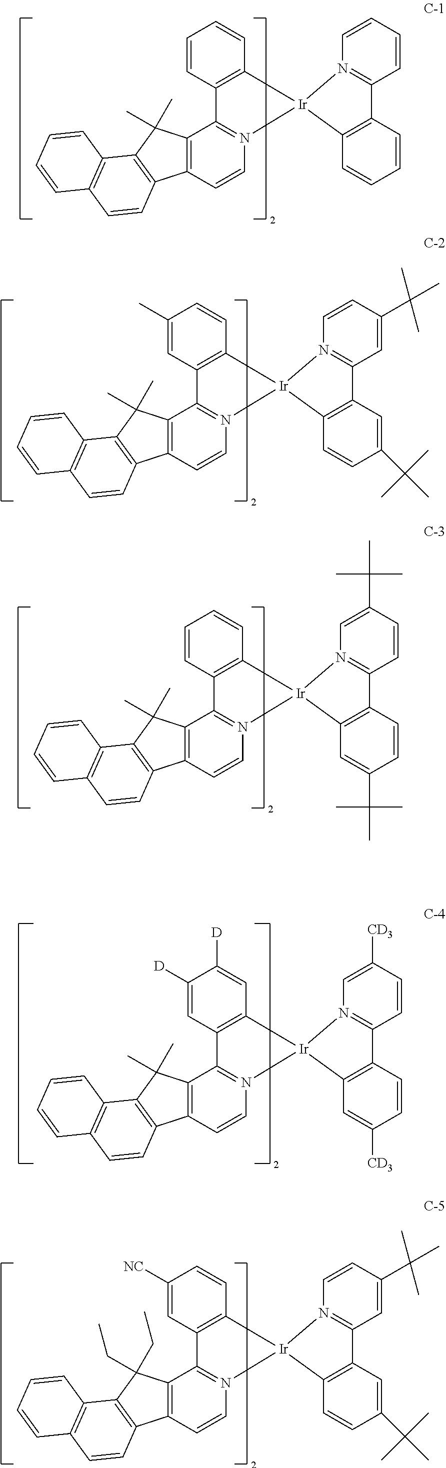

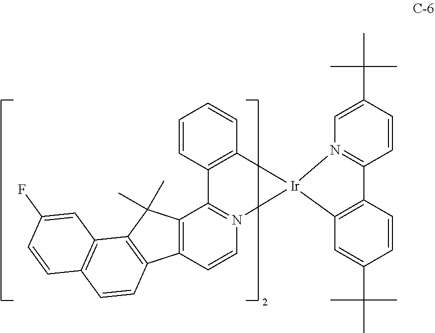

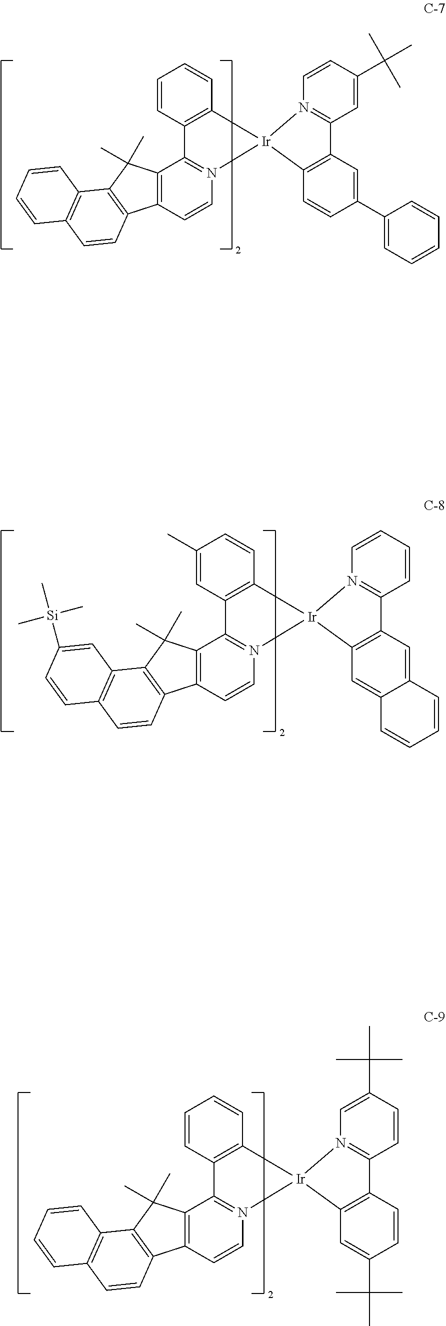

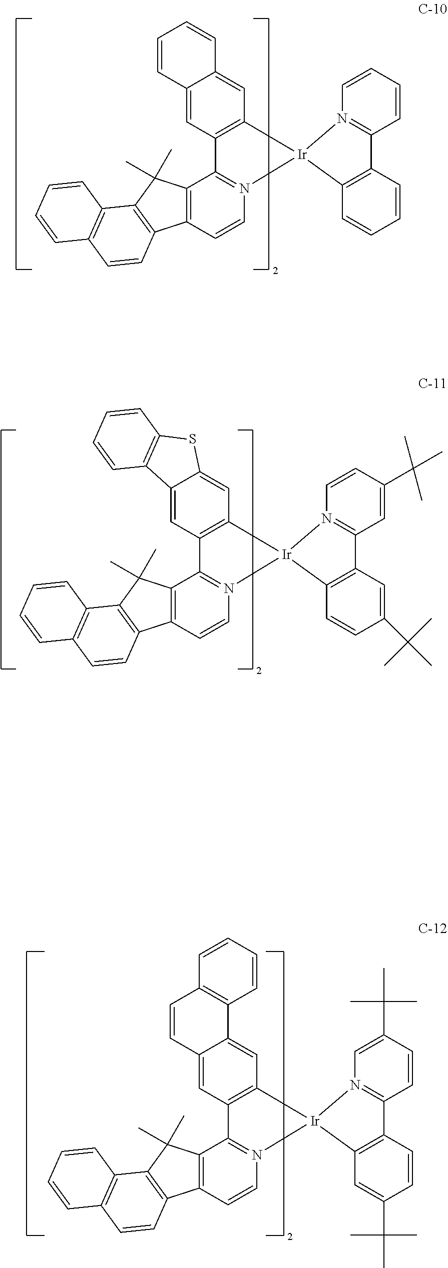

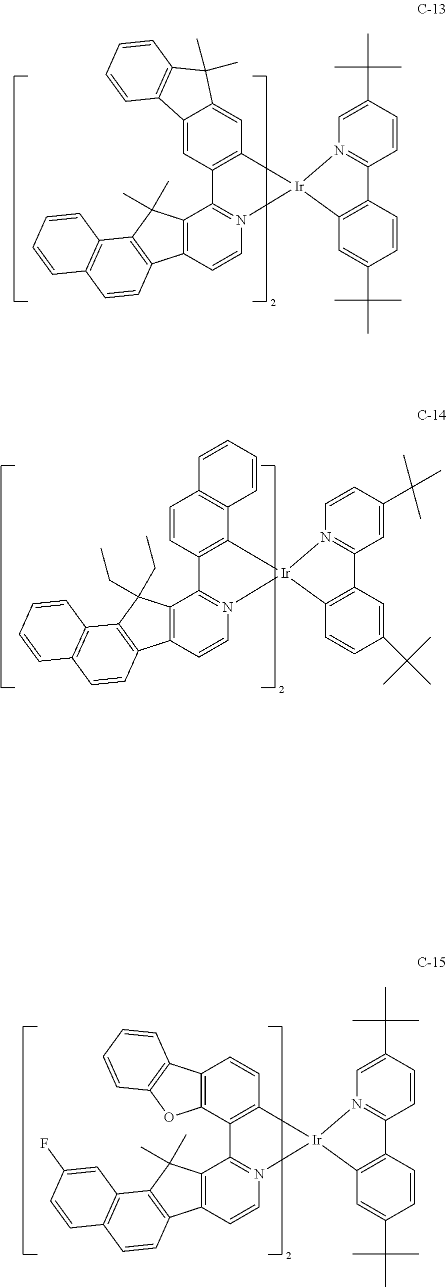

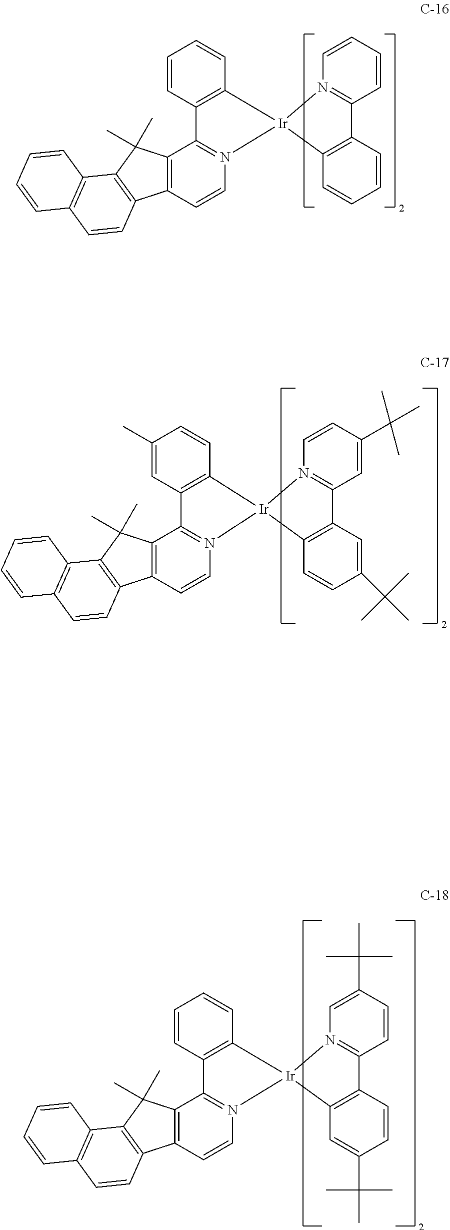

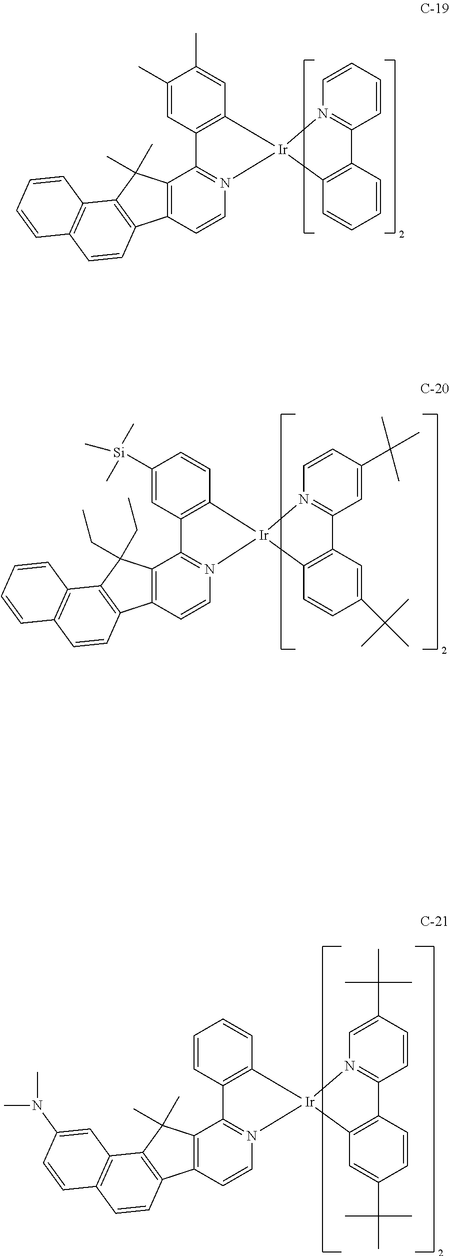

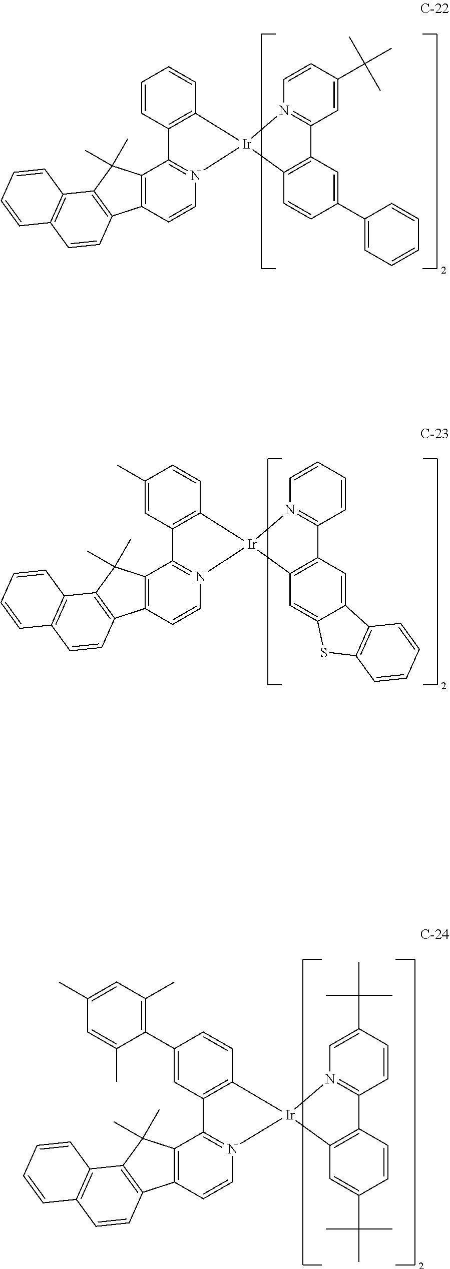

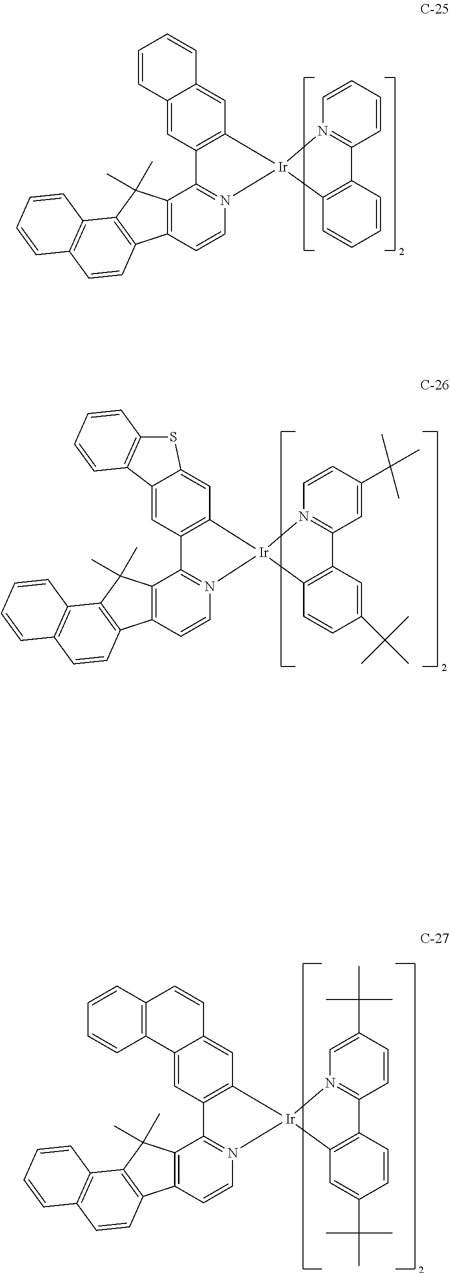

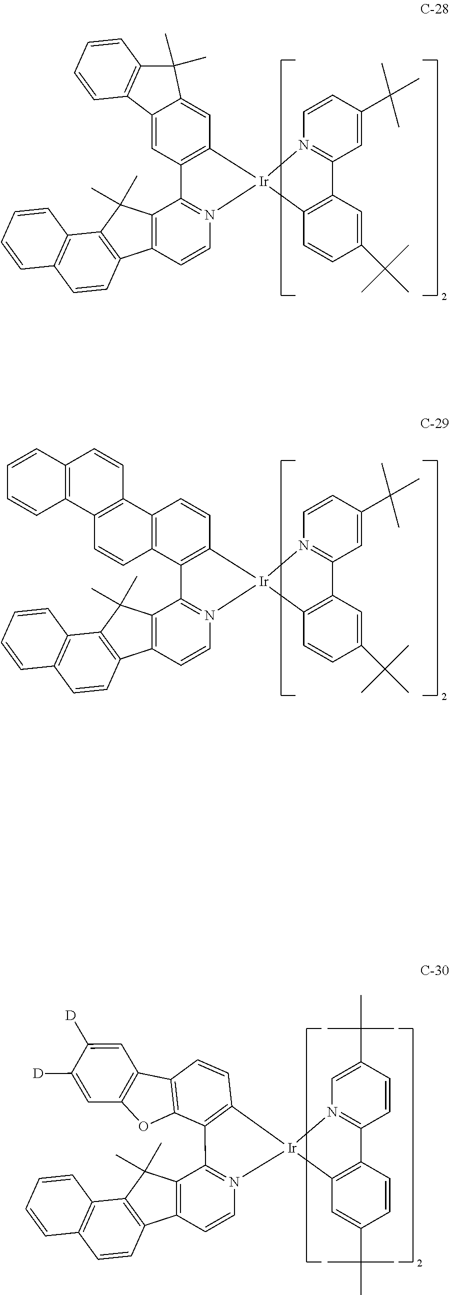

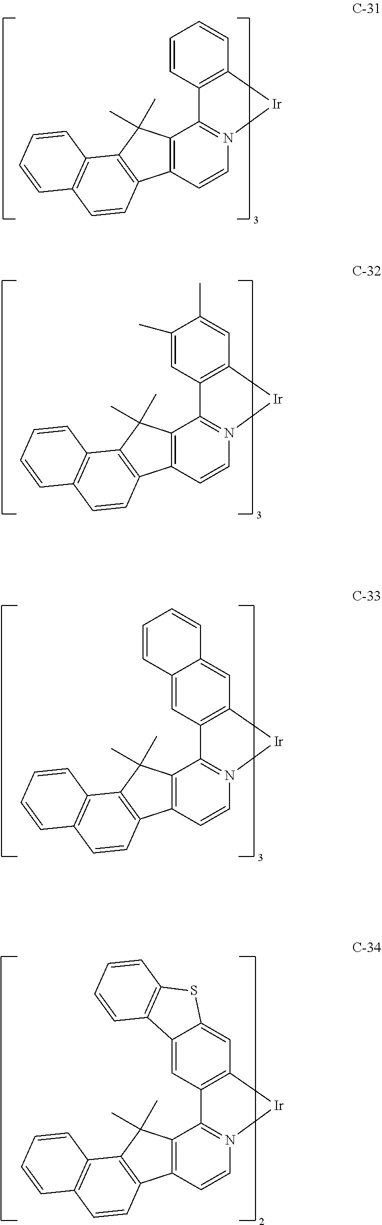

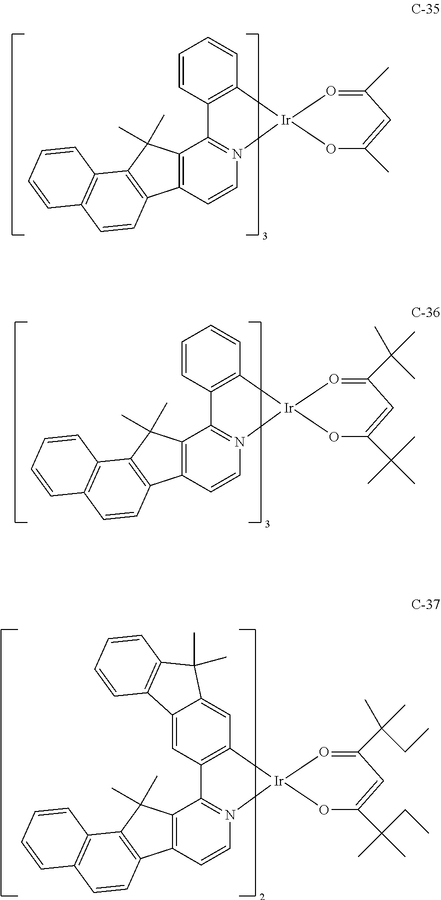

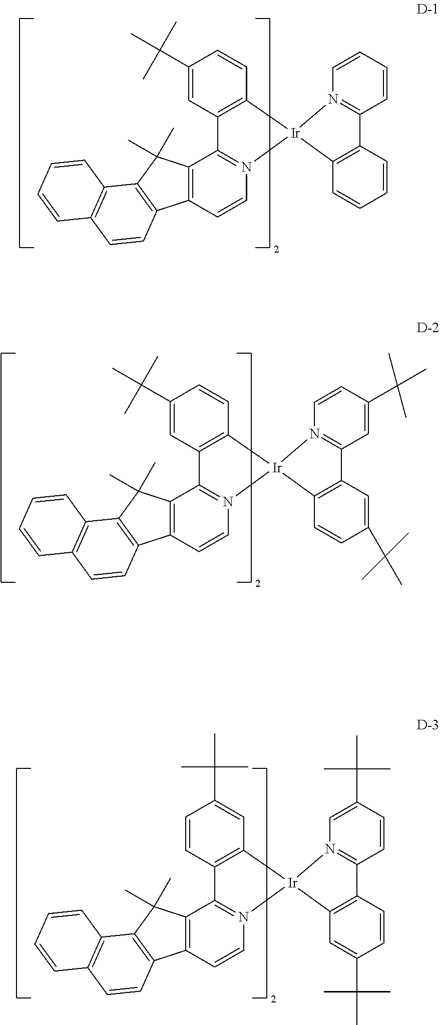

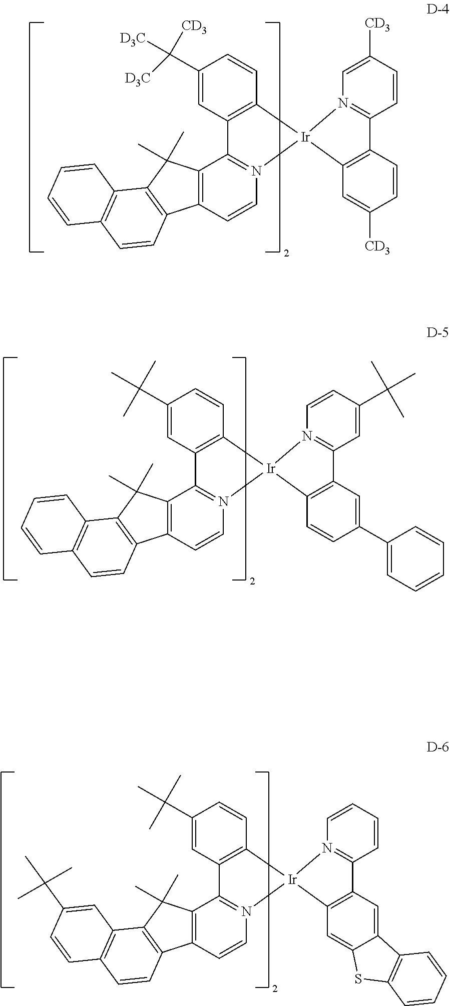

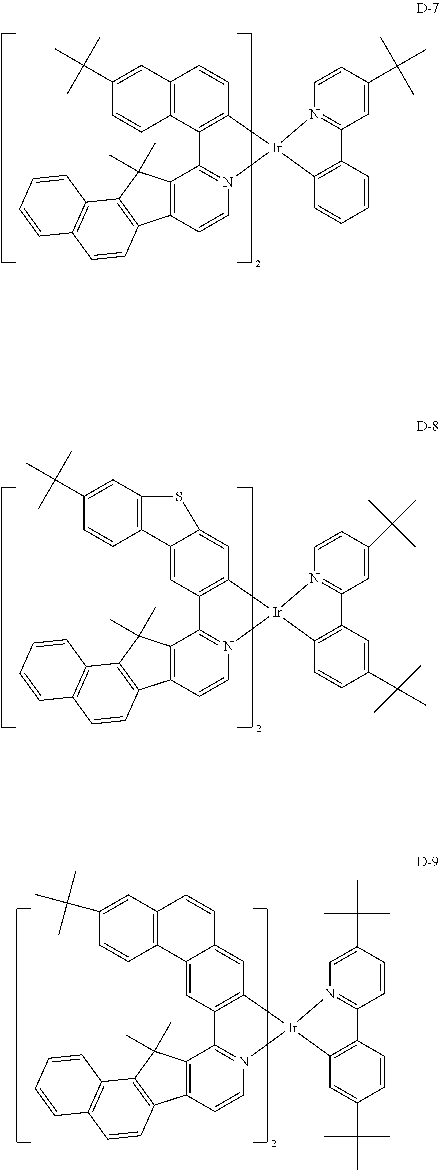

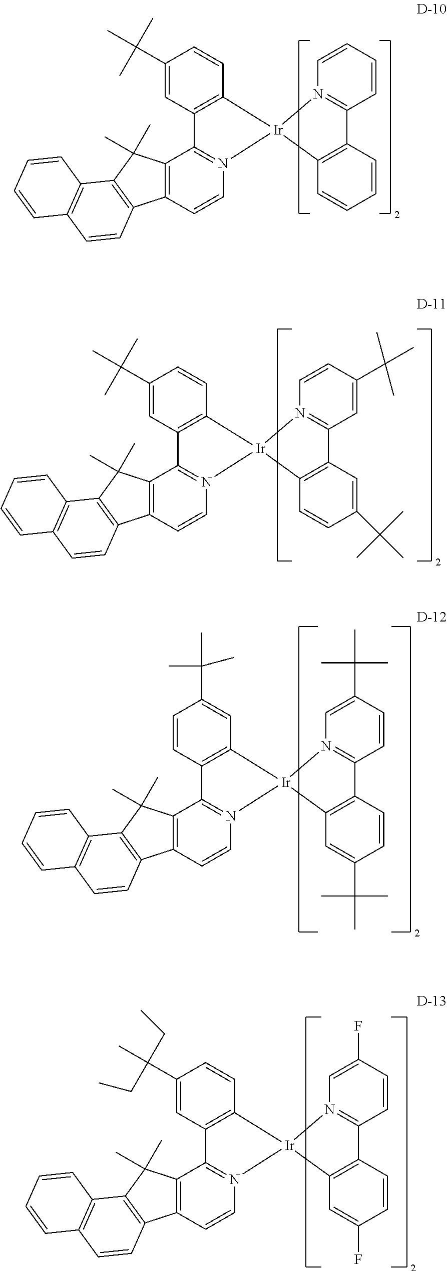

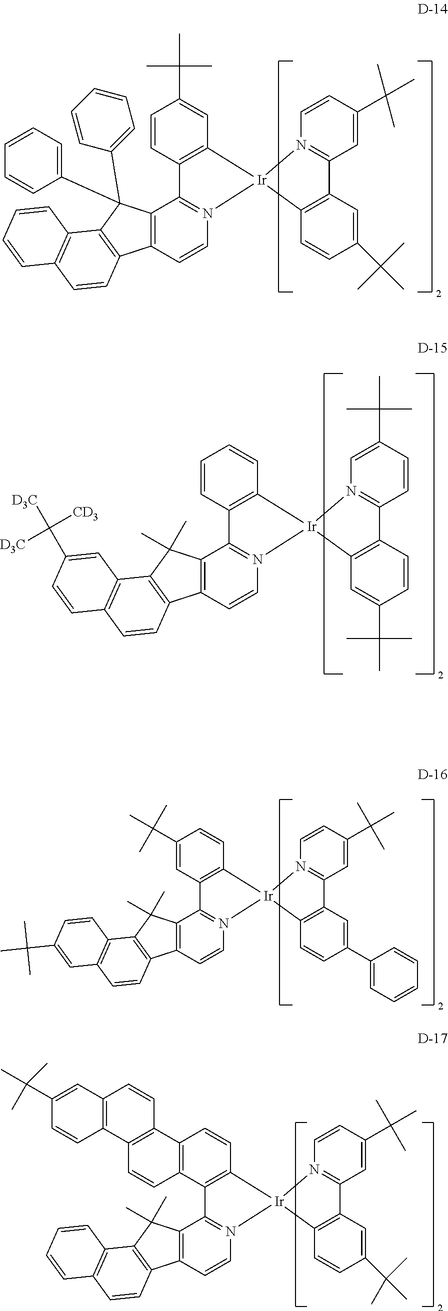

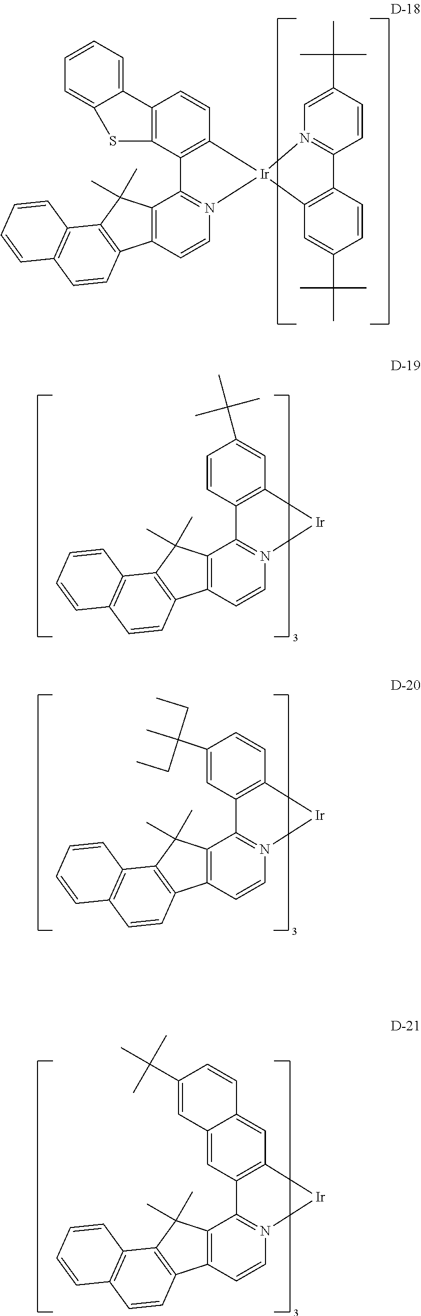

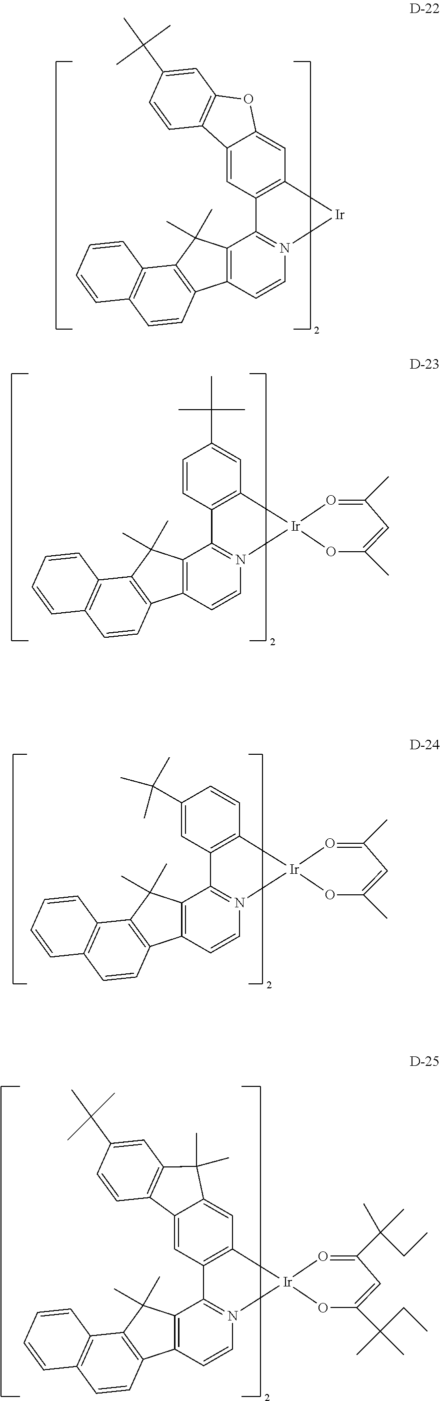

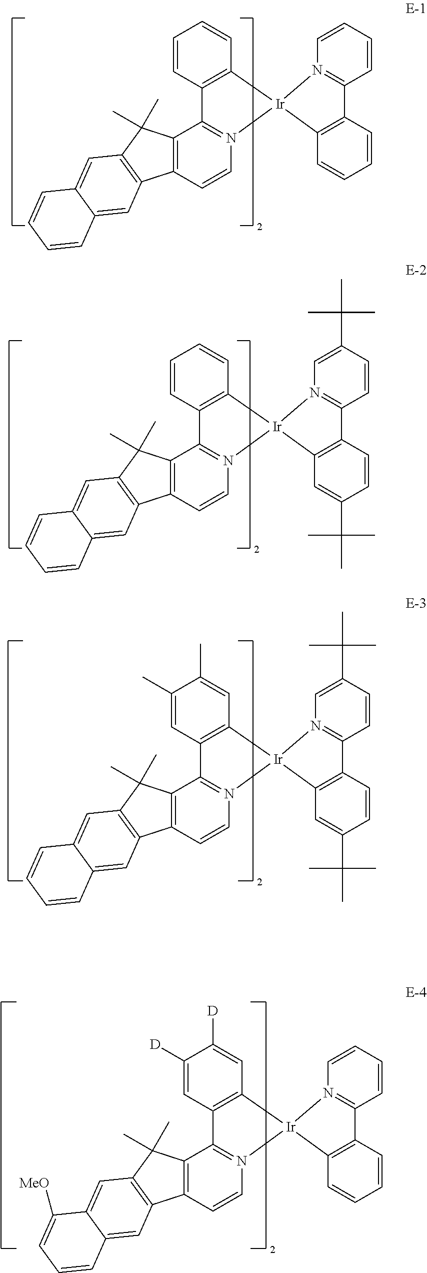

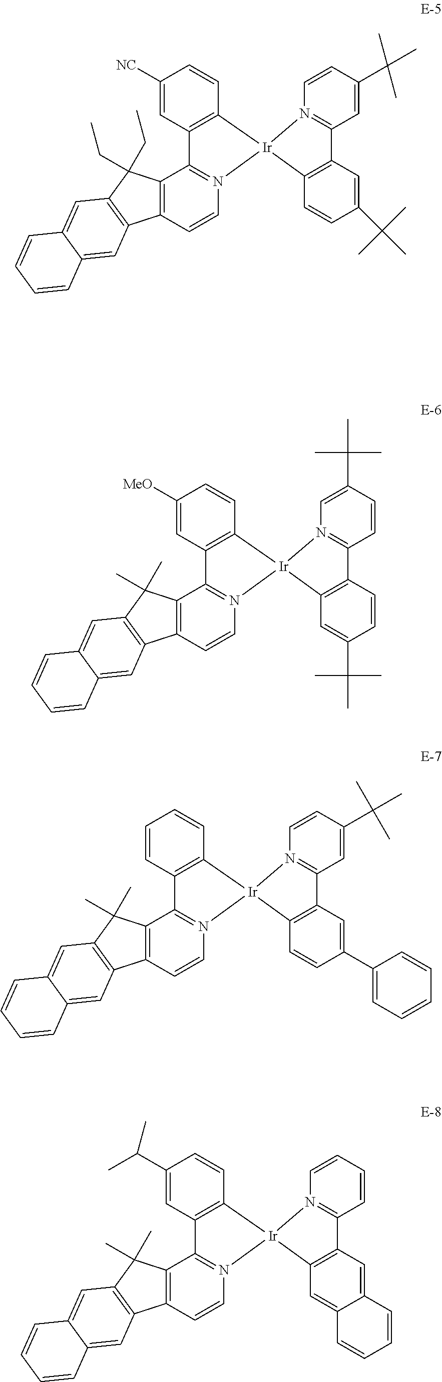

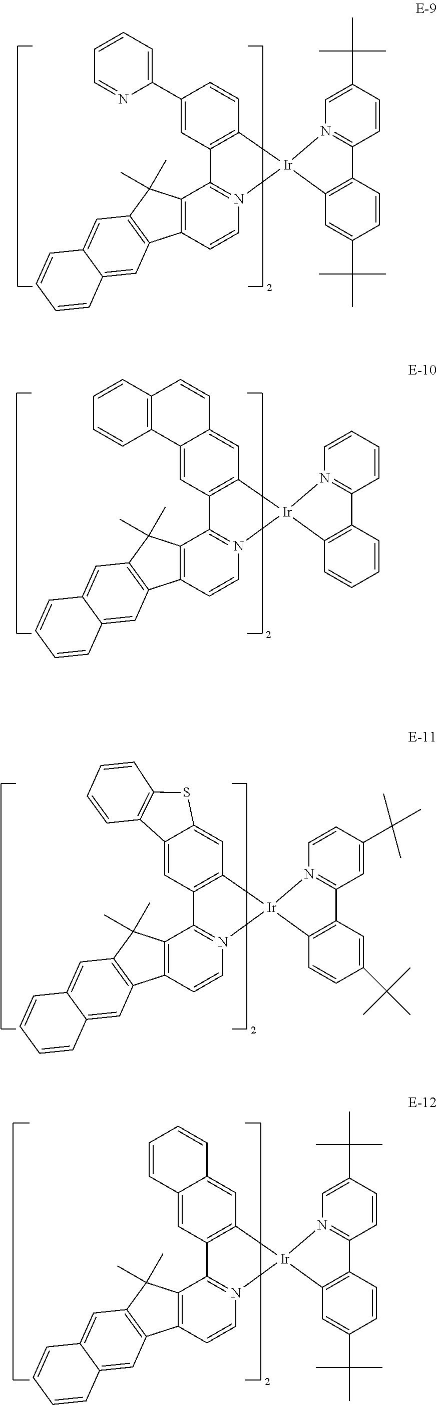

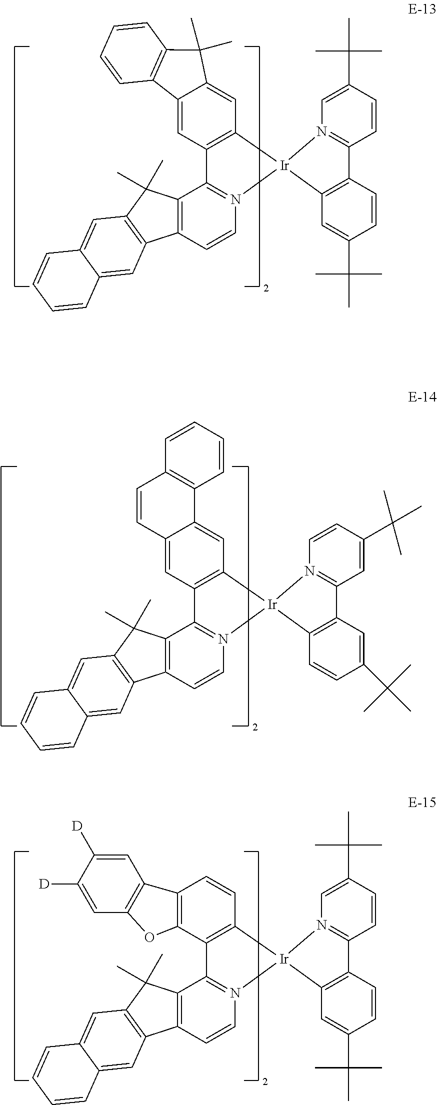

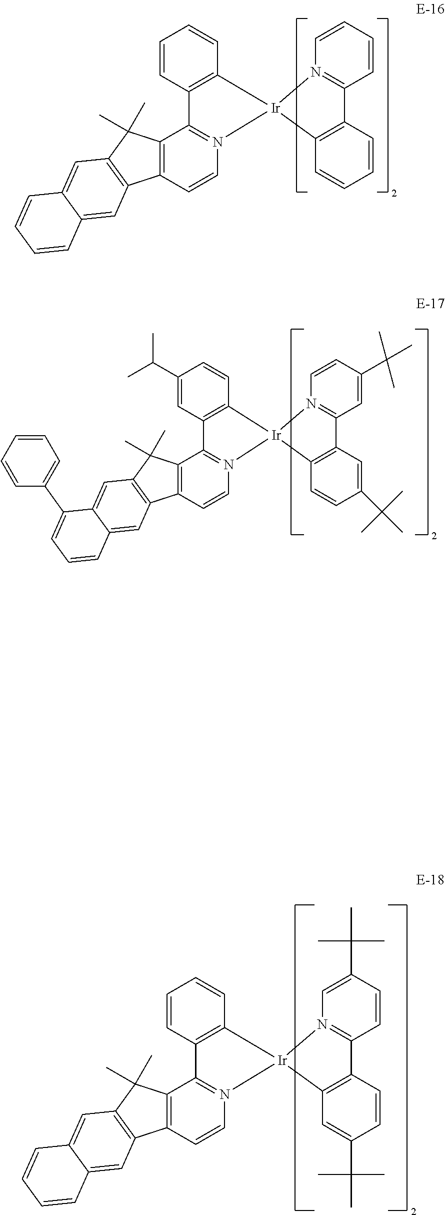

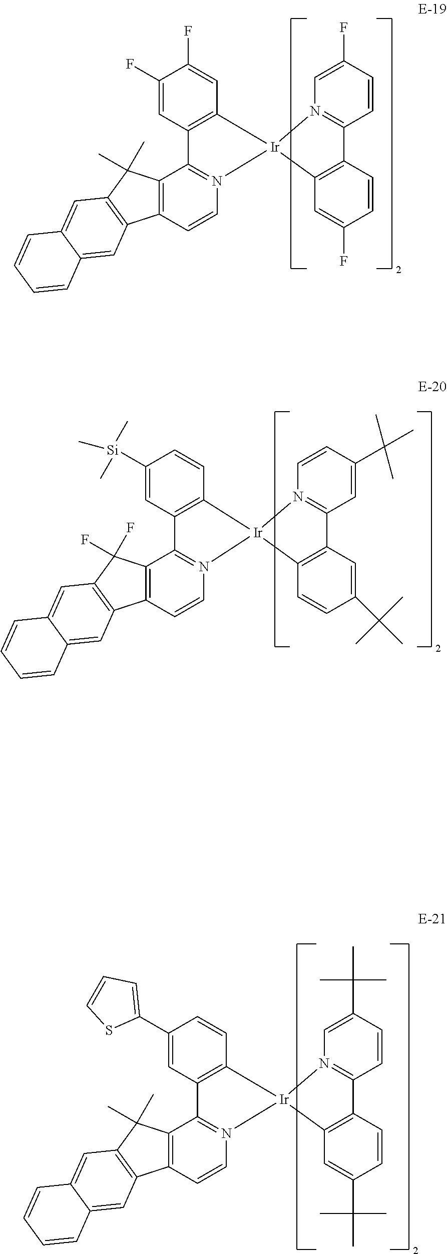

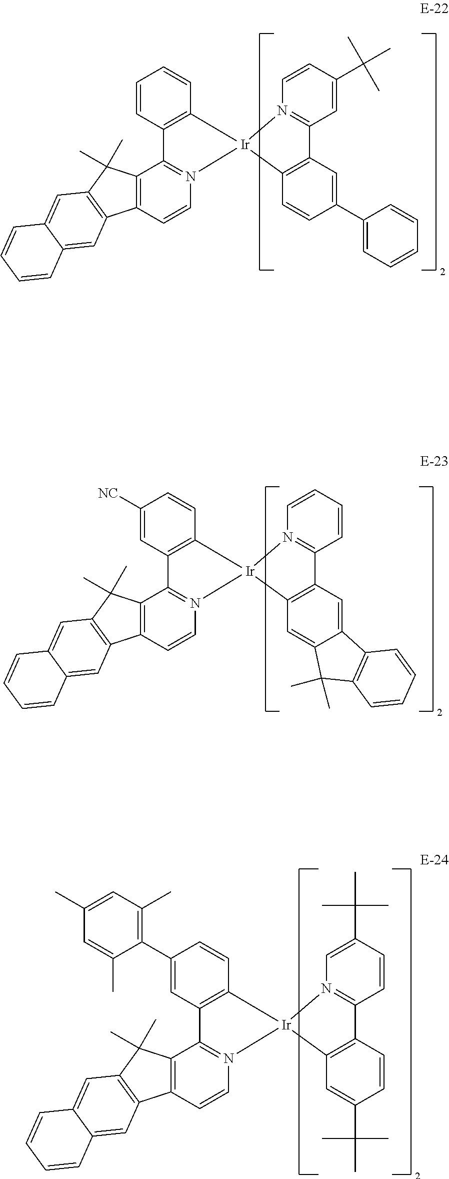

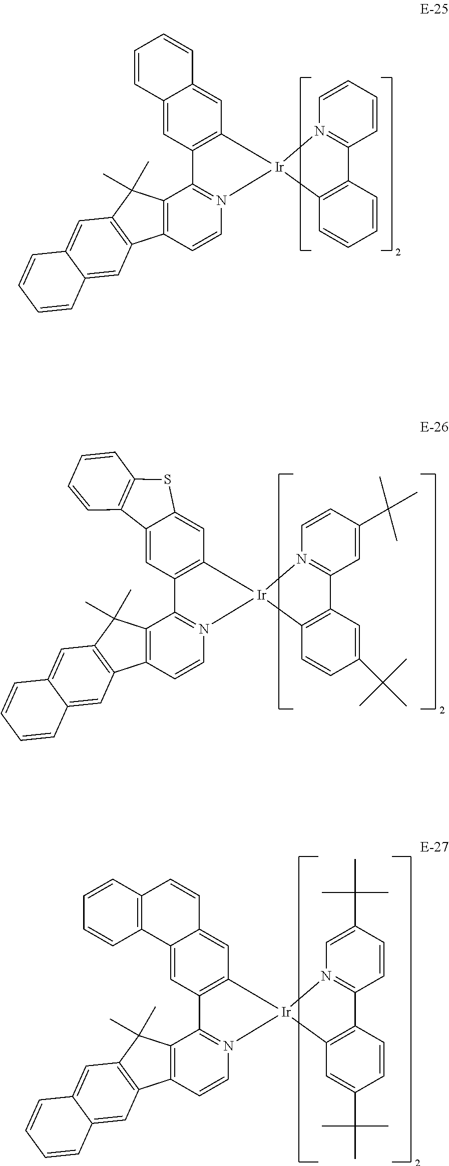

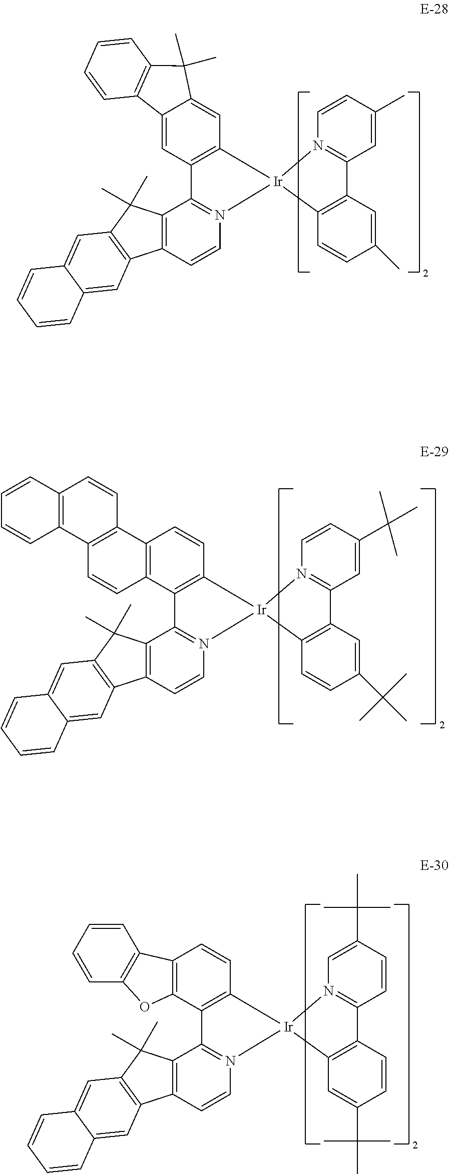

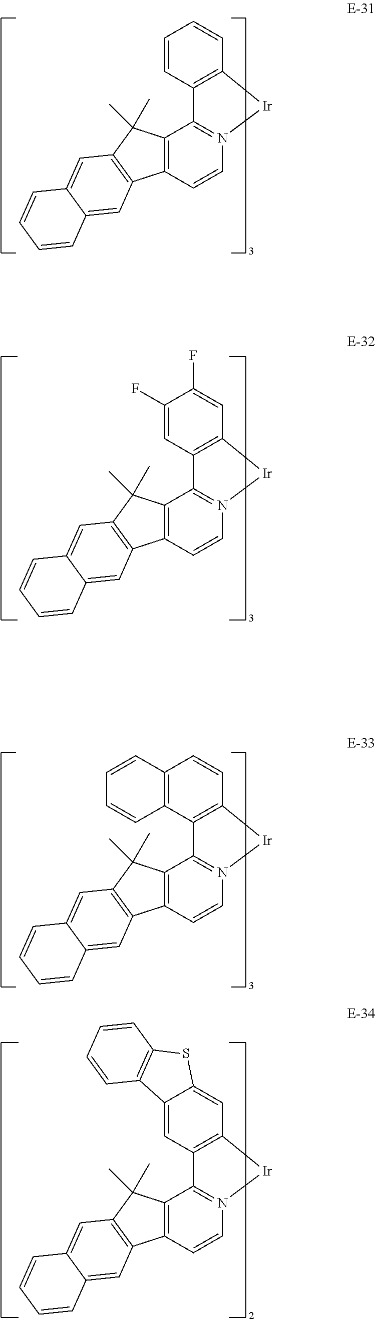

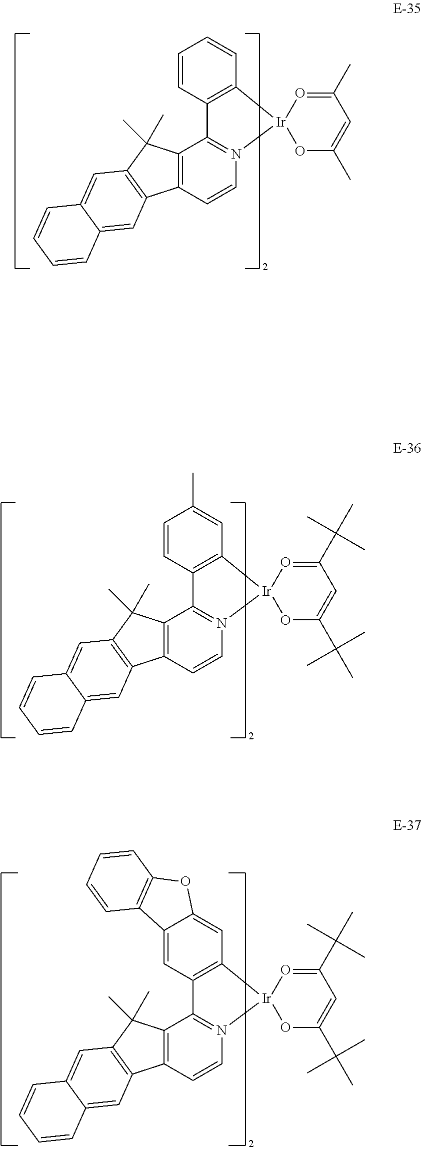

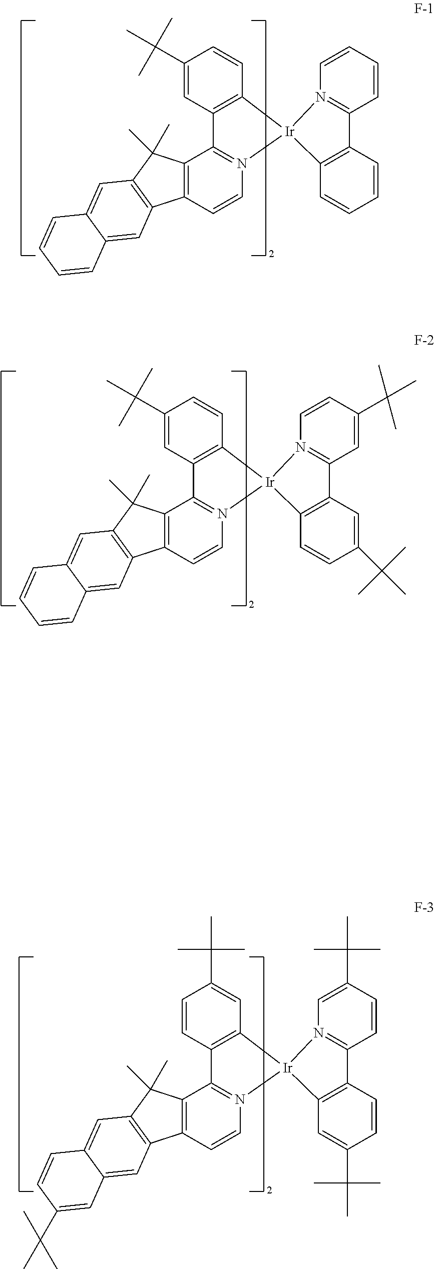

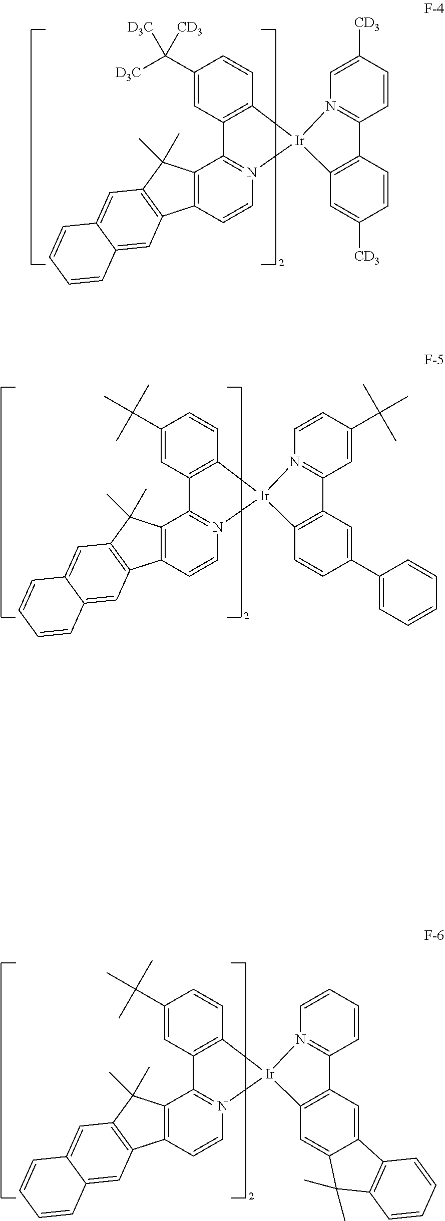

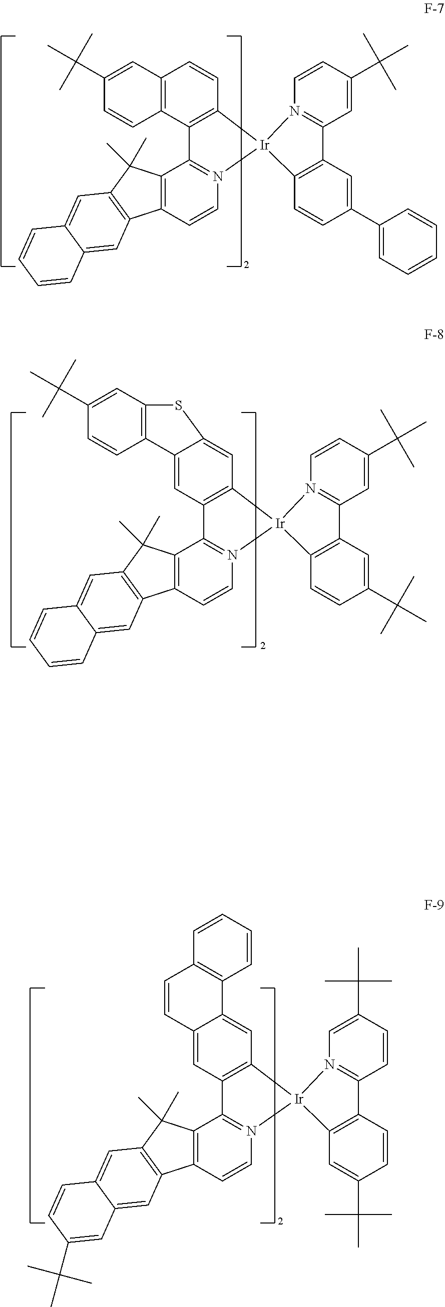

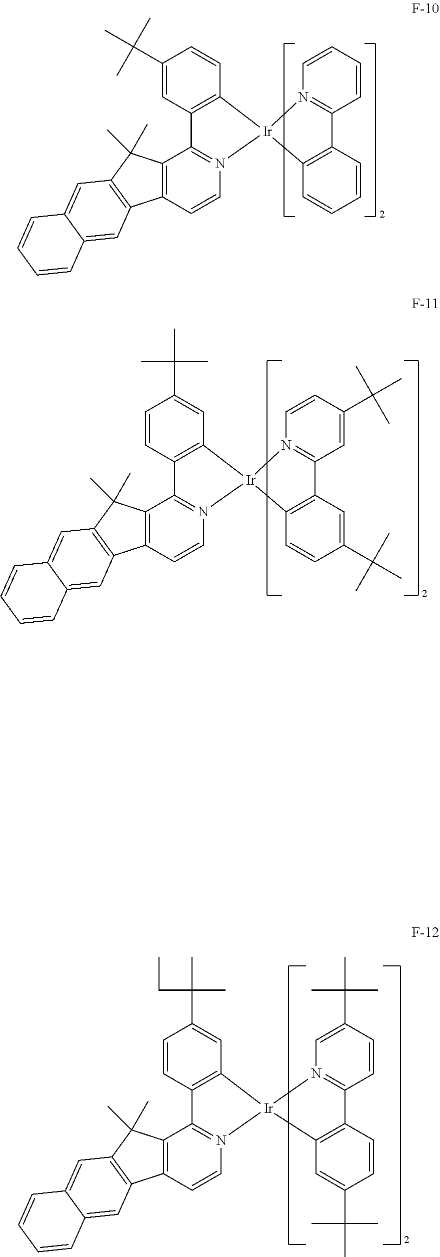

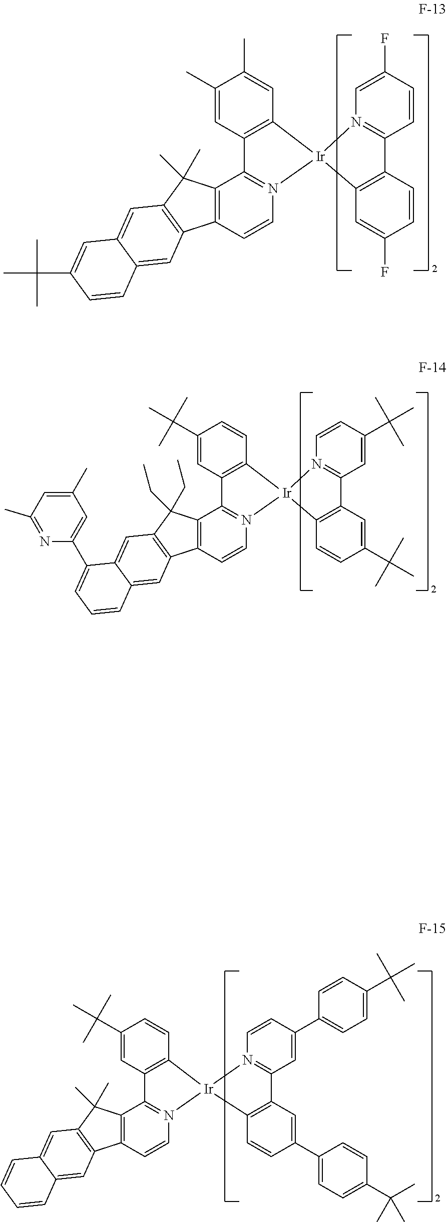

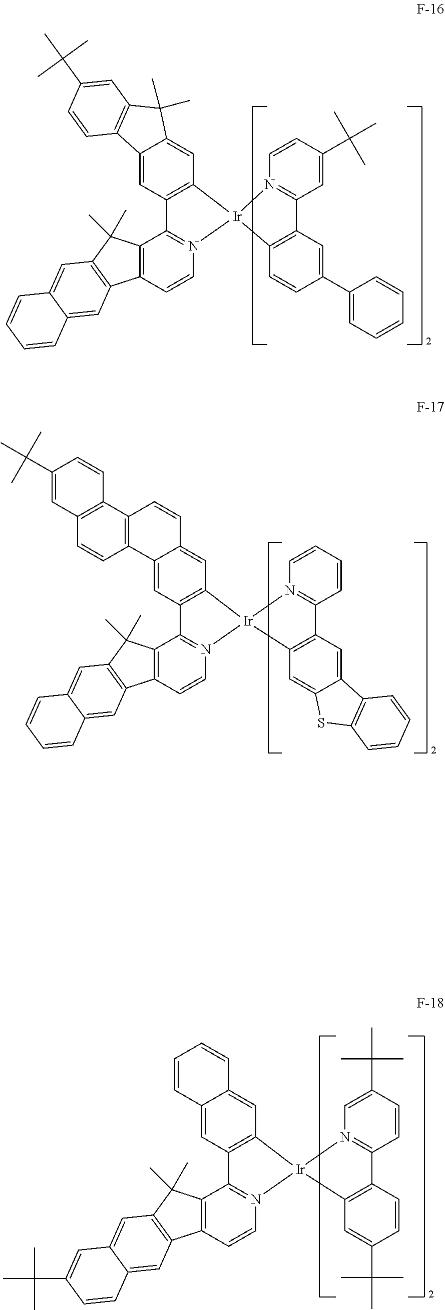

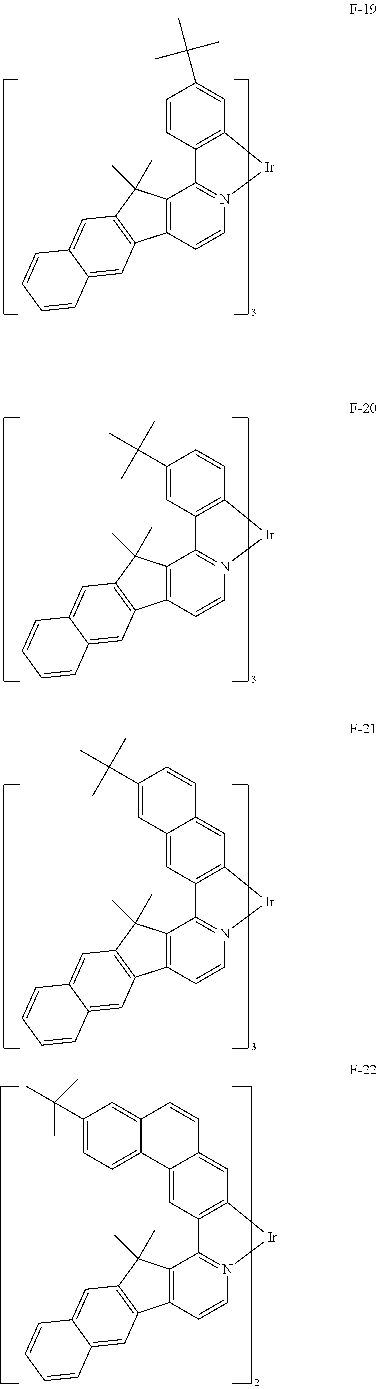

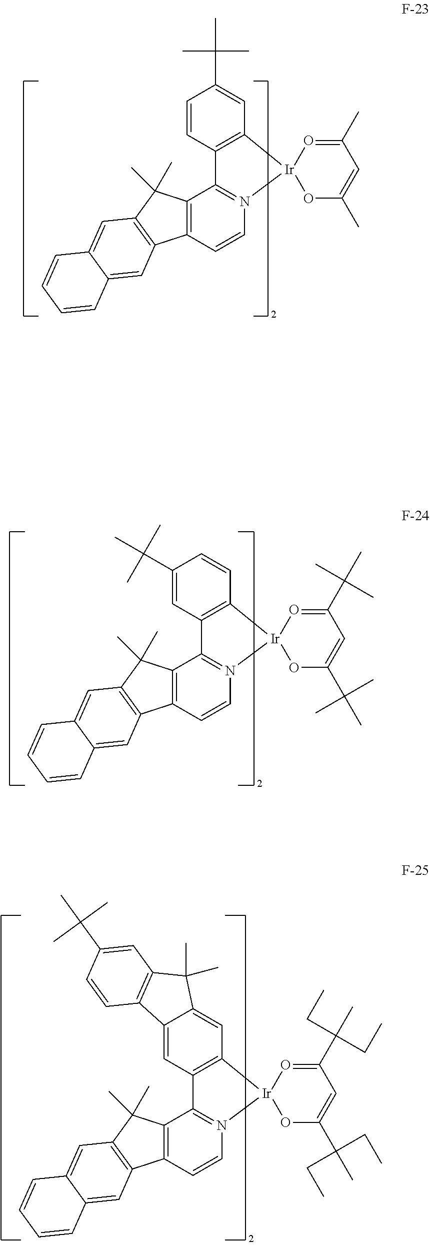

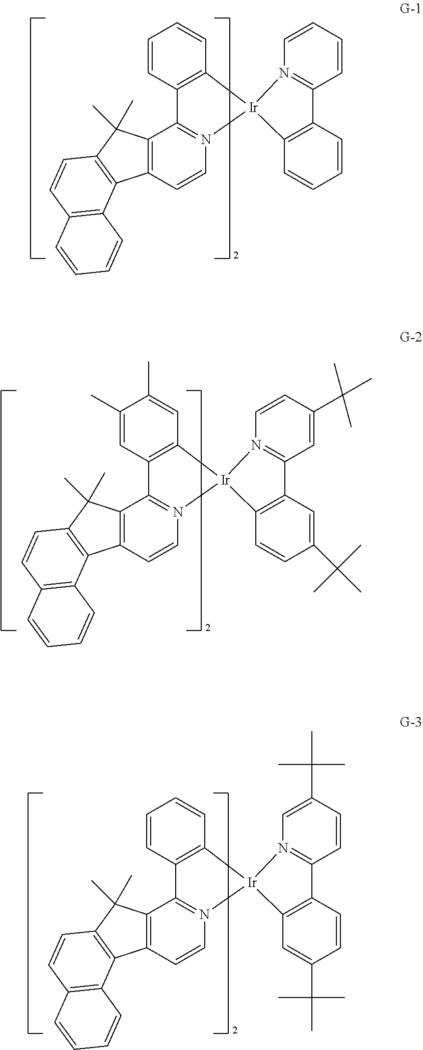

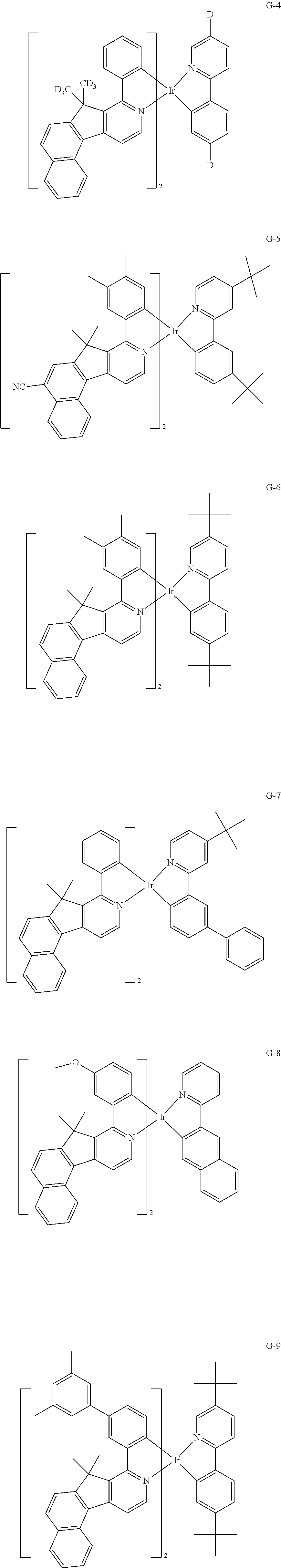

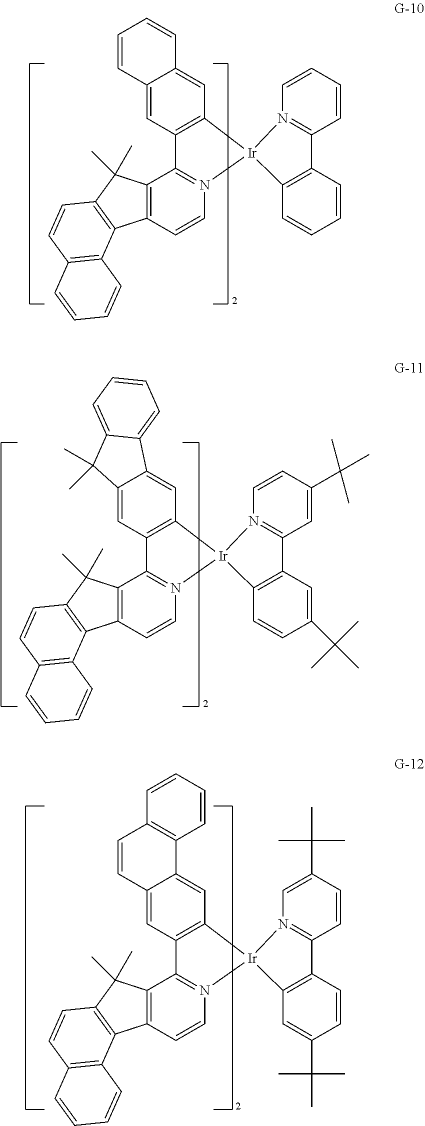

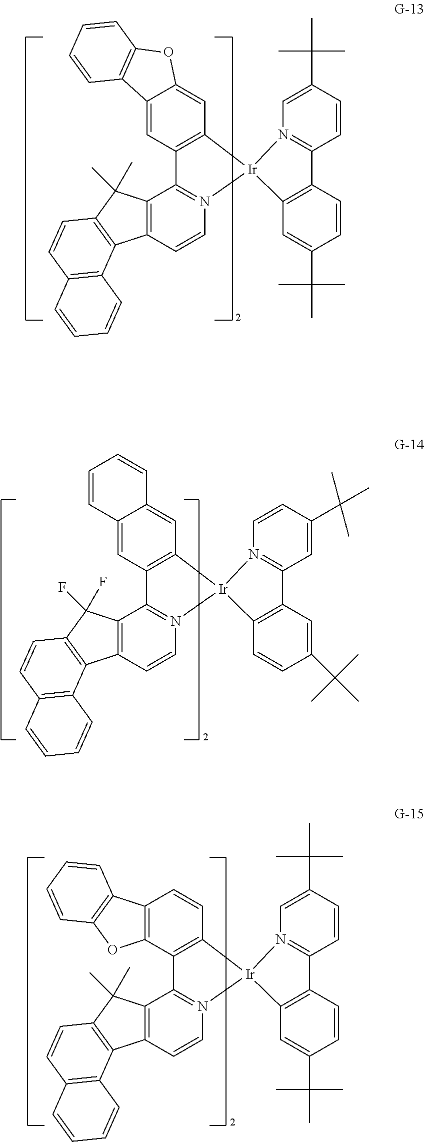

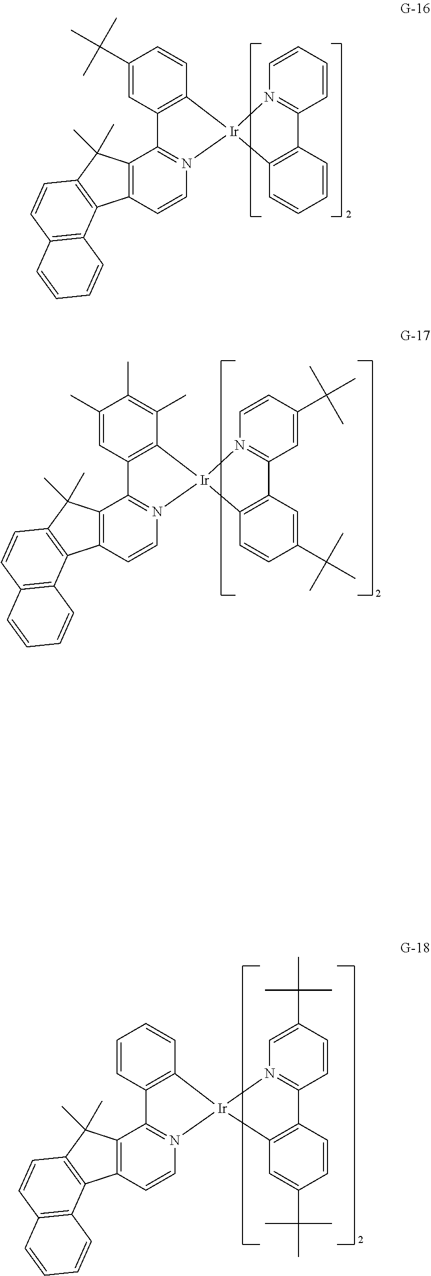

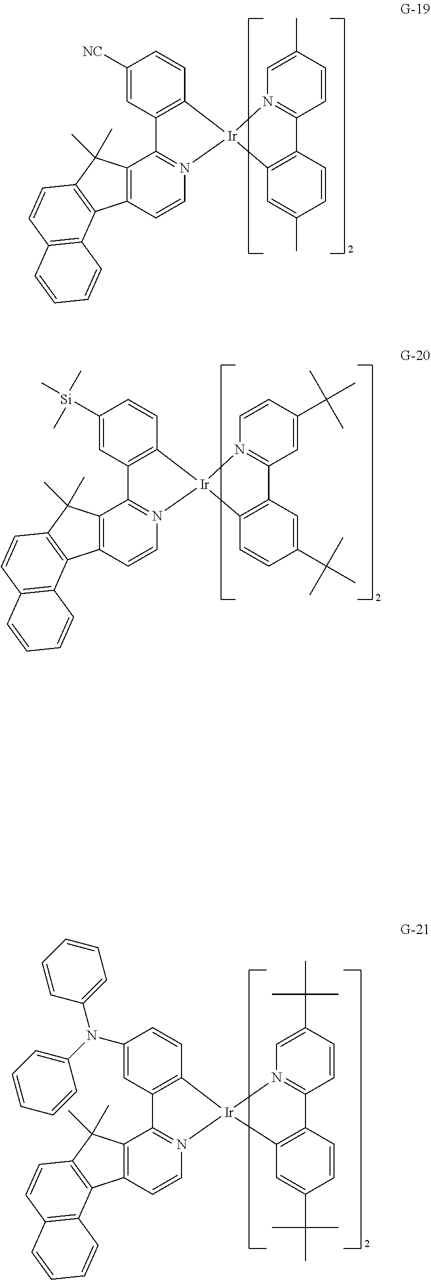

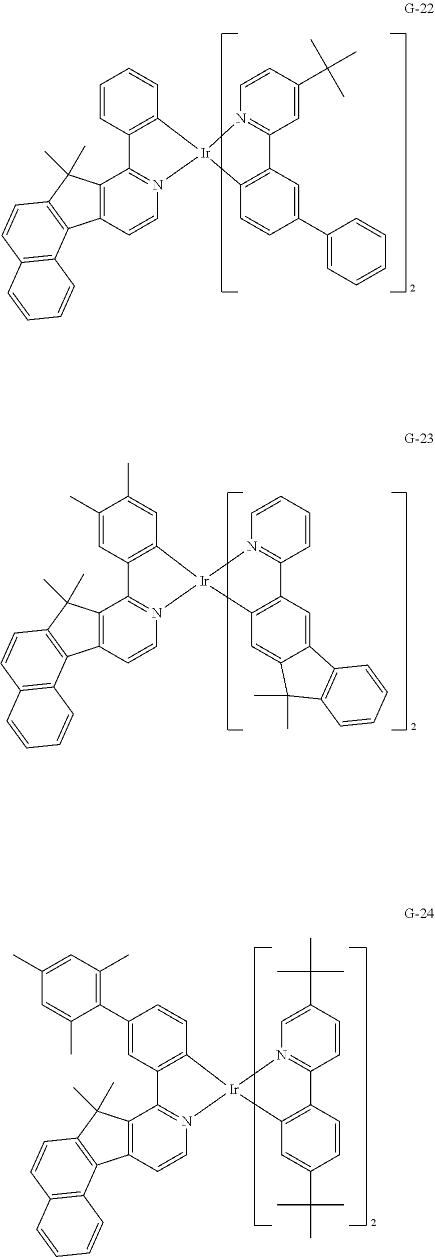

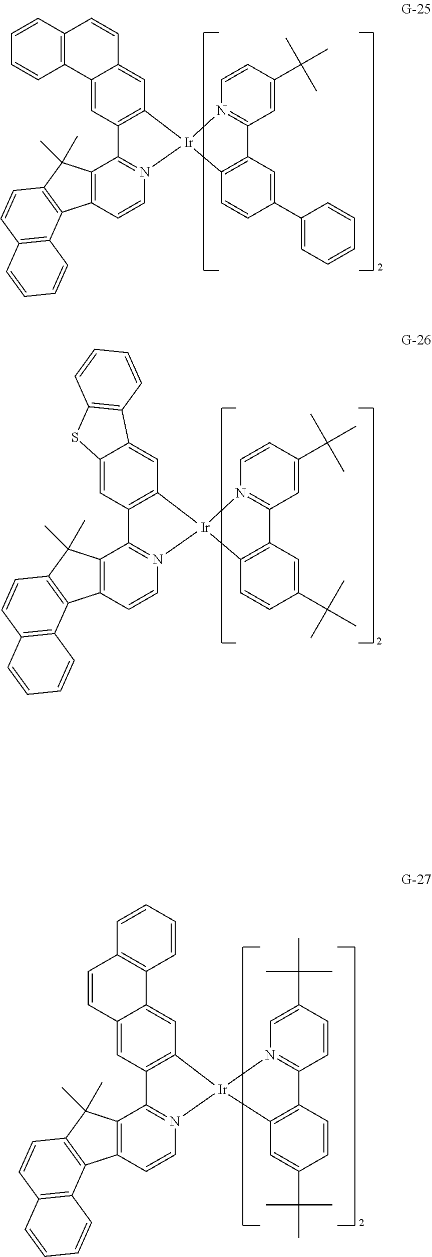

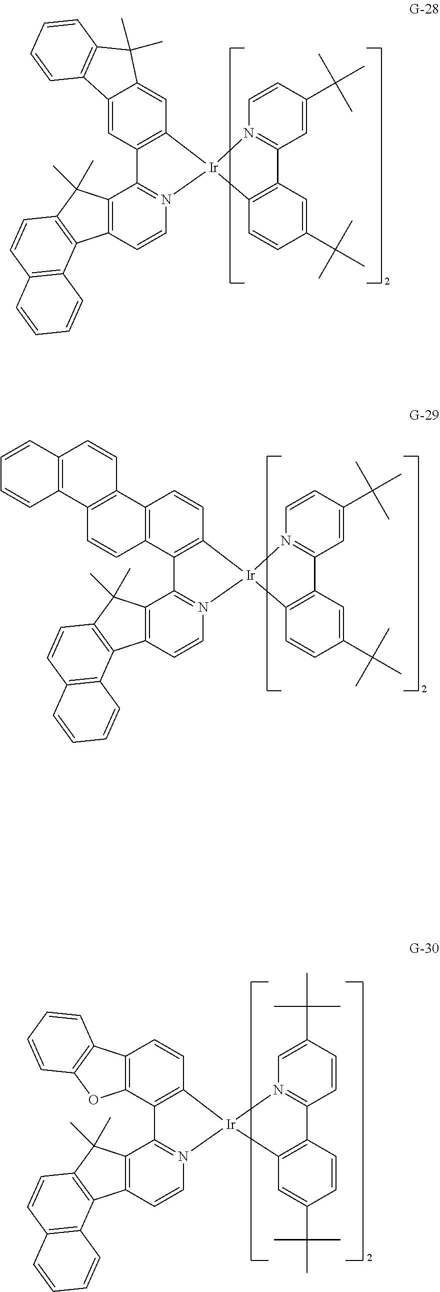

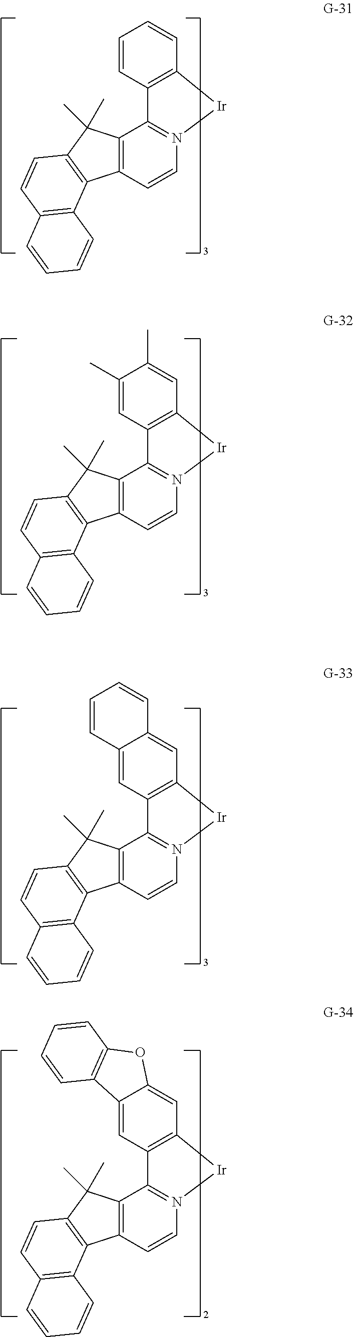

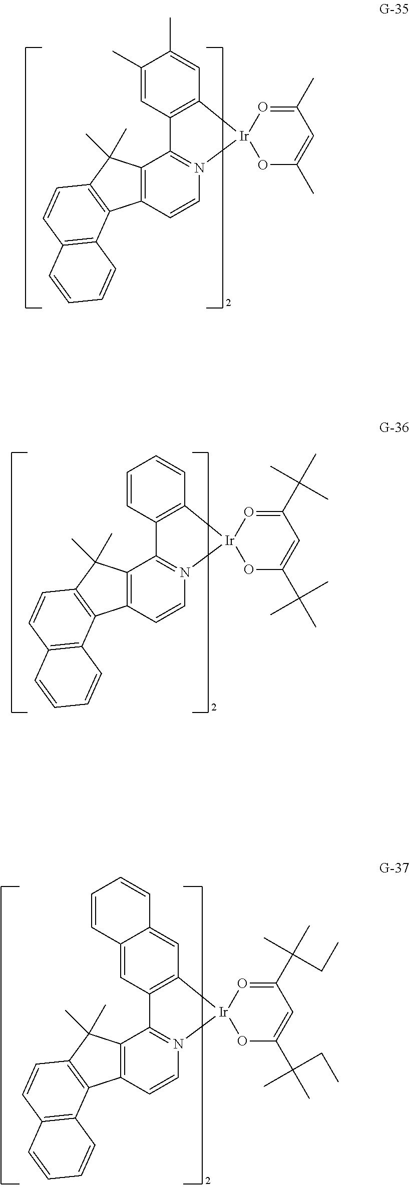

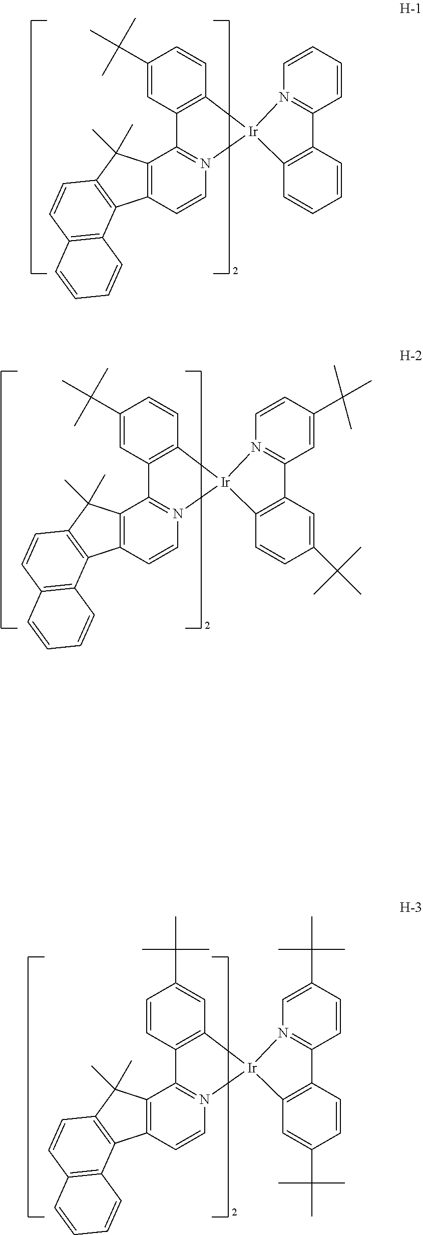

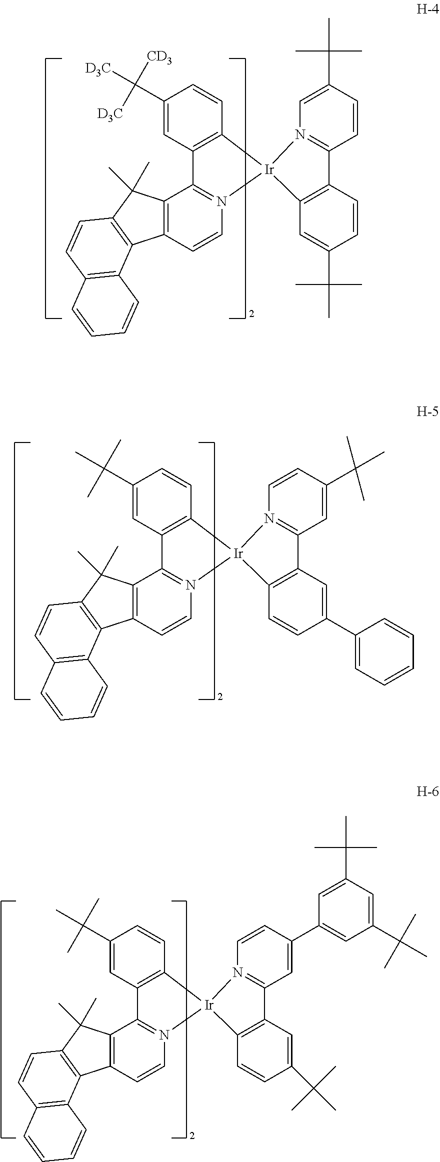

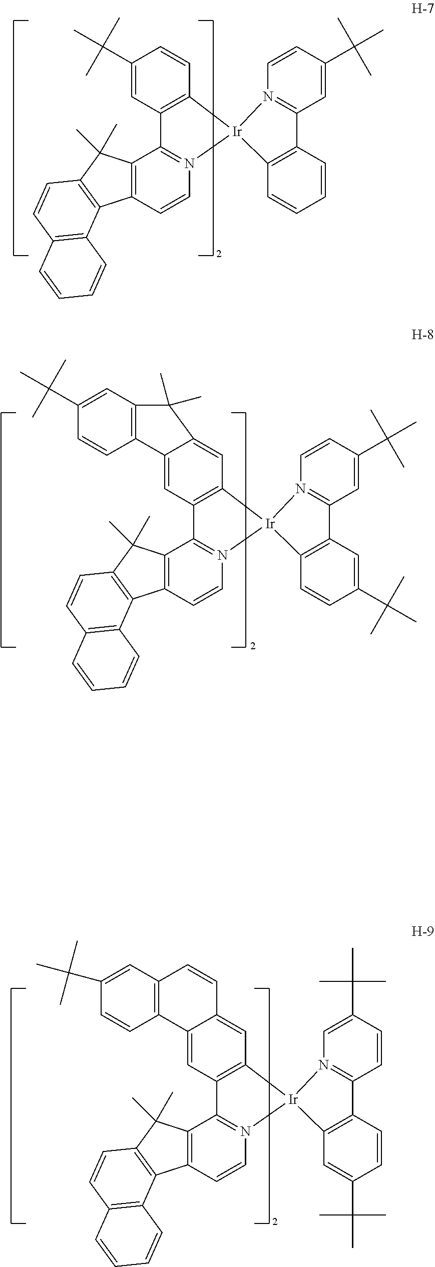

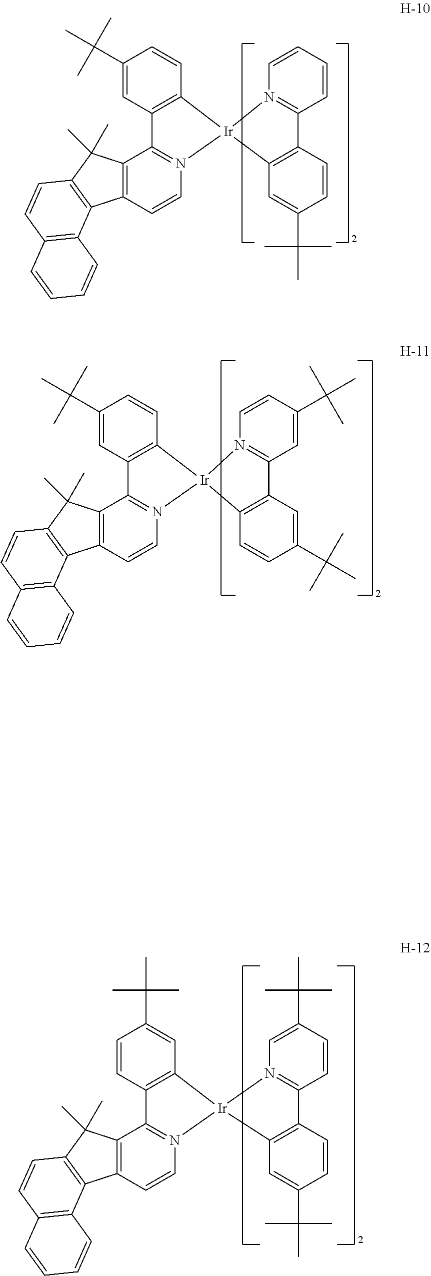

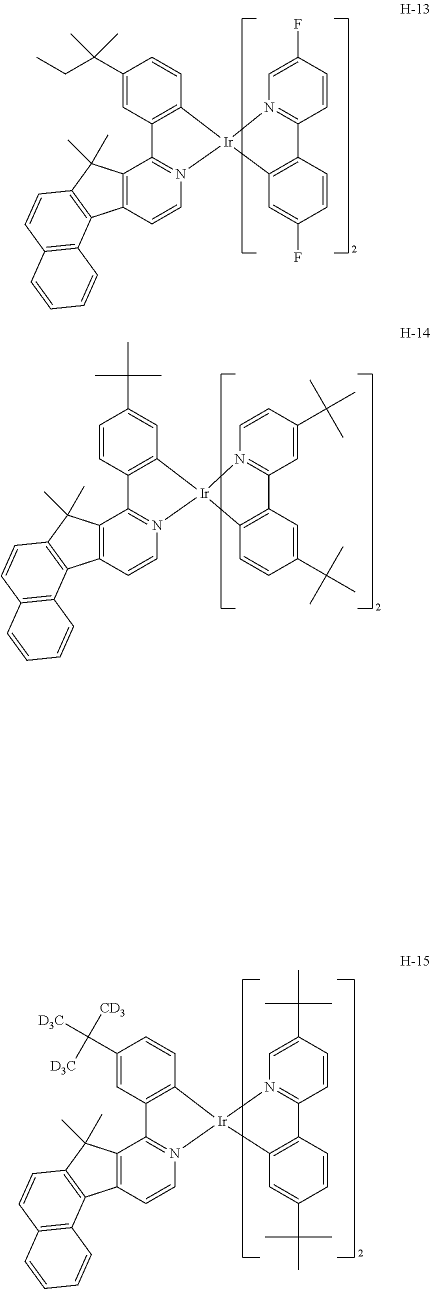

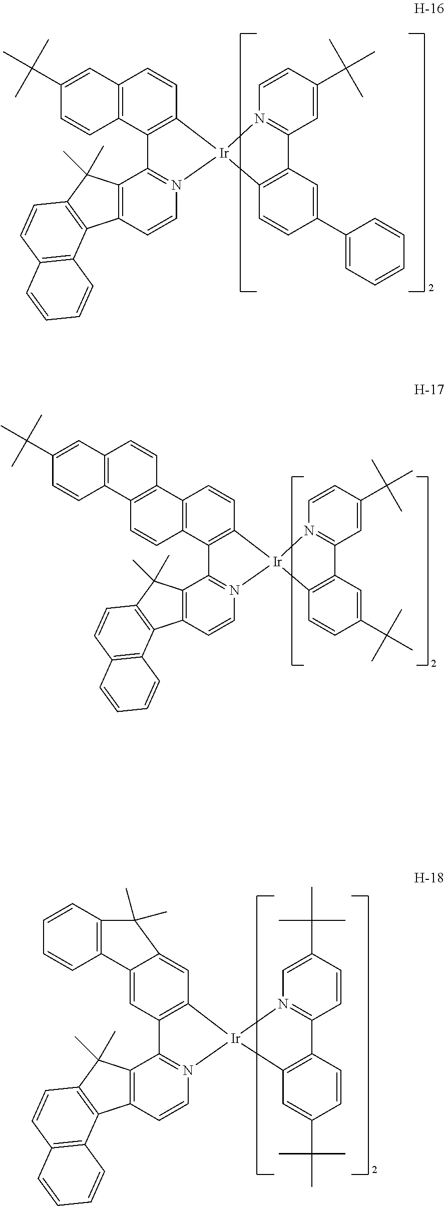

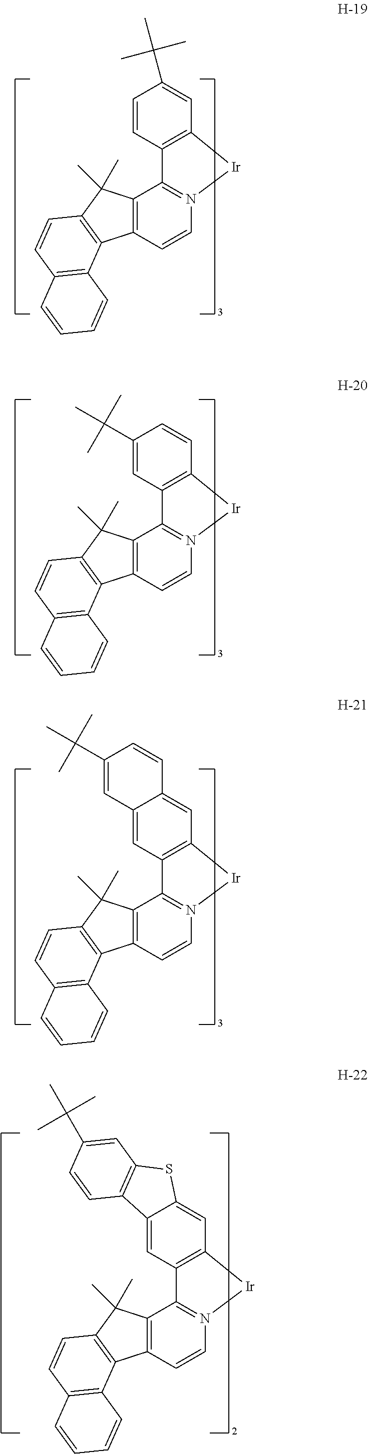

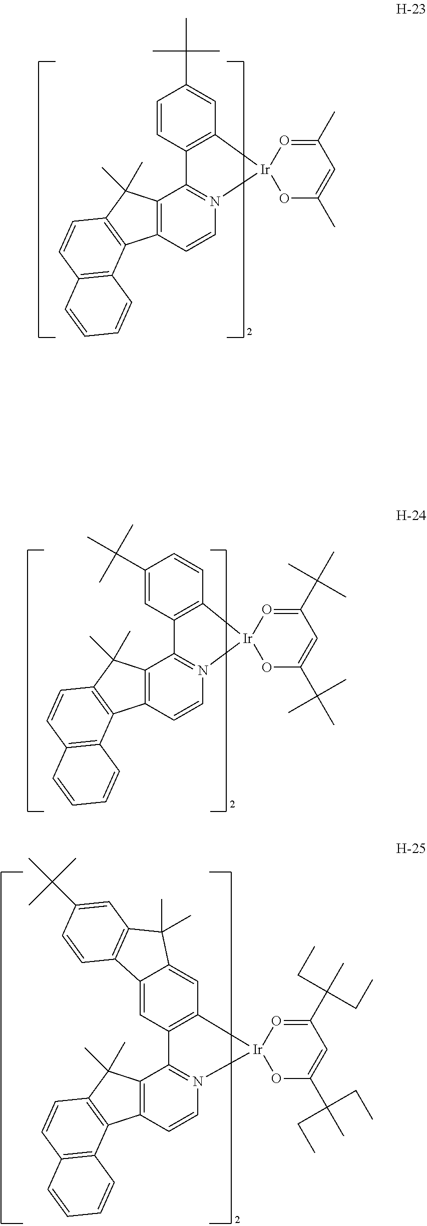

The exemplified compounds belonging to group C are organometallic complexes represented by general formula (1). The presence of an azabenzofluorene ring as a ligand increases the emission quantum yield.

The exemplified compounds belonging to group D excepting for exemplified compound D-18 are organometallic complexes represented by general formula (1) in which at least either R₃ or R₄ is a tertiary alkyl group. The presence of a tertiary alkyl group prevents the molecules from stacking on one another, suppresses the increase of sublimation temperature, and reduces the concentration quenching in the luminescent layer.

The exemplified compounds belonging to group E are compounds represented by general formula (2). The presence of an azabenzofluorene ring as a ligand increases the emission quantum yield.

The exemplified compounds belonging to group F are compounds represented by general formula (2) in which at least either R₃ or R₄ is a tertiary alkyl group. The presence of a tertiary alkyl group prevents the molecules from stacking on one another, suppresses the increase of sublimation temperature, and reduces the concentration quenching in the luminescent layer.

The exemplified compounds belonging to group G are compounds represented by general formula (3). The presence of an azabenzofluorene ring as a ligand increases the emission quantum yield.

The exemplified compounds belonging to group H are compounds represented by general formula (3) in which at least either R₃ or R₄ is a tertiary alkyl group. The presence of a tertiary alkyl group prevents the molecules from stacking on one another, suppresses the increase of sublimation temperature, and reduces the concentration quenching in the luminescent layer.

### (2) Features of Organic Light-Emitting Element

The organic light-emitting element of the present disclosure includes a first electrode, a luminescent layer, and a second electrode, in this order. The luminescent layer contains an organometallic complex (hereinafter also referred to as “dopant material”) represented by any one of general formulas (1) to (3) and a first compound (hereinafter also referred to as “host material”) and features the following:
(2-1) Facilitating energy transfer because of strong interactions between the dopant material and the host material being a hydrocarbon compound
(2-2) Increasing the hole transporting ability in the luminescent layer because of the effect of the above feature (2-1), which promotes the hopping transport of holes between the dopant material and the host material

These features will now be described.

(2-1) Facilitating energy transfer because of strong interactions between the dopant material and the host material being a hydrocarbon compound

The organometallic complexes represented by general formulas (1) to (3) have an azabenzofluorene ring, which is a condensed polycyclic group of four rings, as a ligand. The host material is preferably an organic compound containing a condensed polycyclic group, and more preferably, the condensed polycyclic group is hydrocarbon. When the organometallic complex and the host material each contain a condensed polycyclic group, n-n interaction occurs easily and facilitates energy transfer from the host material to the dopant material.

Incidentally, the triplet energy used in phosphorescent light-emitting elements is known to be transferred by the Dexter mechanism. In the Dexter mechanism, energy transfer takes place through contact among molecules. In other words, the I-n interaction between the host material and the guest material reduces the intermolecular distance to allow efficient energy transfer from the host material to the guest material.

Thus, the above effect provides a highly efficient organic light-emitting element because triplet excitons generated in the host material are quickly consumed for luminescence. Also, the material deterioration by a high-energy triplet excited state, which results from further excitation of triplet excitons not used for luminescence, is reduced. Thus, the organic light-emitting element has good drive endurance.

(2-2) Increasing the hole transporting ability in the luminescent layer because of the effect of the above feature (2-1), which promotes the hopping transport of holes between the dopant material and the host material

The organometallic complexes represented by general formulas (1) to (3) have higher HOMO levels because of the effect of containing an azabenzofluorene ring as a ligand and, accordingly, tend to have higher HOMO levels than the host material. The holes injected from the hole transport layer are transported by the host material while being repeatedly trapped and de-trapped between the host material and the dopant material. Preferably, at this time, similar skeletons between the host material and the dopant materials are used. In this instance, the condensed rings of the host material and the dopant material overlap strongly with each other, allowing holes to efficiently move between the host material and the dopant material. Consequently, voltage increase in the luminescent layer is suppressed, providing a low-voltage organic light-emitting element with good drive endurance.

The organic light-emitting element of the present disclosure preferably further has the following feature:

(2-3) The light-emitting element has increased luminous efficiency because of the luminescent layer further containing a second compound (hereinafter also referred to as “assist material”) having a higher LUMO level (far from the vacuum level) than the host material.

This features will now be described.

(2-3) The light-emitting element has increased luminous efficiency because of the luminescent layer further containing a second compound (assist material) having a higher LUMO level (far from the vacuum level) than the host material

The organometallic complexes represented by general formulas (1) to (3) promote the injection of holes into the luminescent layer. From the viewpoint of injecting electrons and holes into the luminescent layer in good balance, the injection of electrons into the luminescent layer is preferably promoted. Host materials that are hydrocarbon compounds are characterized by wide band gaps. Accordingly, the host material has a high LUMO level, and electrons may be less likely to be injected from the electron transport layer or the hole blocking layer. Preferably, therefore, the luminescent layer further contains an assist material to facilitate the injection of electrons into the luminescent layer. Also, the assist material preferably has a lower LUMO level than the host material. Consequently, the injection of both holes and electrons into the luminescent layer is improved to maintain the carrier balance in the luminescent layer, and thus, a highly efficient light-emitting element can be provided.

In the element disclosed herein, the dopant material in the luminescent layer promotes the injection of holes, as described above, producing the effect of hole traps to confine holes in the luminescent layer. Consequently, the injection of holes from the luminescent layer into the hole blocking layer or electron transport layer is reduced to reduce the likelihood that holes degrade the hole blocking layer and electron transport layer.

Also, the assist material, which has a lower LUMO level than the host material, promotes the injection of electrons, producing the effect of electron trap to confine electrons in the luminescent layer. Consequently, the injection of electrons from the luminescent layer into the electron blocking layer or hole transport layer is reduced to reduce the likelihood that electrons degrade the electron blocking layer and hole transport layer.

### (3) Host Material

The lowest excited triplet energy (T1) of the host material used in the present disclosure is higher than that of the dopant material. Desirably, the host material has the following features:
(3-1) Having, preferably, at least any one skeleton of triphenylene, naphthalene, phenanthrene, chrysene, and fluoranthene; and
(3-2) Containing no SP3 carbon.

These features will now be described.

(3-1) Having, preferably, at least any one skeleton of triphenylene, naphthalene, phenanthrene, chrysene, and fluoranthene

The organometallic complexes represented by general formulas (1) to (3) have an azabenzofluorene ring as a ligand. Azabenzofluorene rings are highly planar in structure. Host materials having a highly planar structure are preferred for the interaction between the dopant material and the host material as in the above features (2-1) and (2-2). This is because highly planar structures allow highly planar moieties to come closer to each other. More specifically, the fluorene moiety of the dopant and a planar moiety of the host material come close more easily. Accordingly, it is expected that the intermolecular distance between the dopant material and the host material will decrease. This effect leads to the effect of increasing the energy transfer efficiency described in feature (2-1).

Highly planar structures include condensed polycyclic groups with three or more rings, and preferred examples include compounds with hydrocarbon condensed polycyclic rings, such as triphenylene, naphthalene, phenanthrene, chrysene, and fluoranthene.

(3-2) Containing no SP3 carbon, desirably

The dopant material disclosed herein is a compound that improves the distance from the host material, as described in the above feature (3-1), and thereby improves luminescent characteristics and interaction with the host material. Additionally, host materials containing no SP3 carbon are preferable because such materials can reduce the distance from the dopant material.

Specific examples of the host material include, but are not limited to, the following:

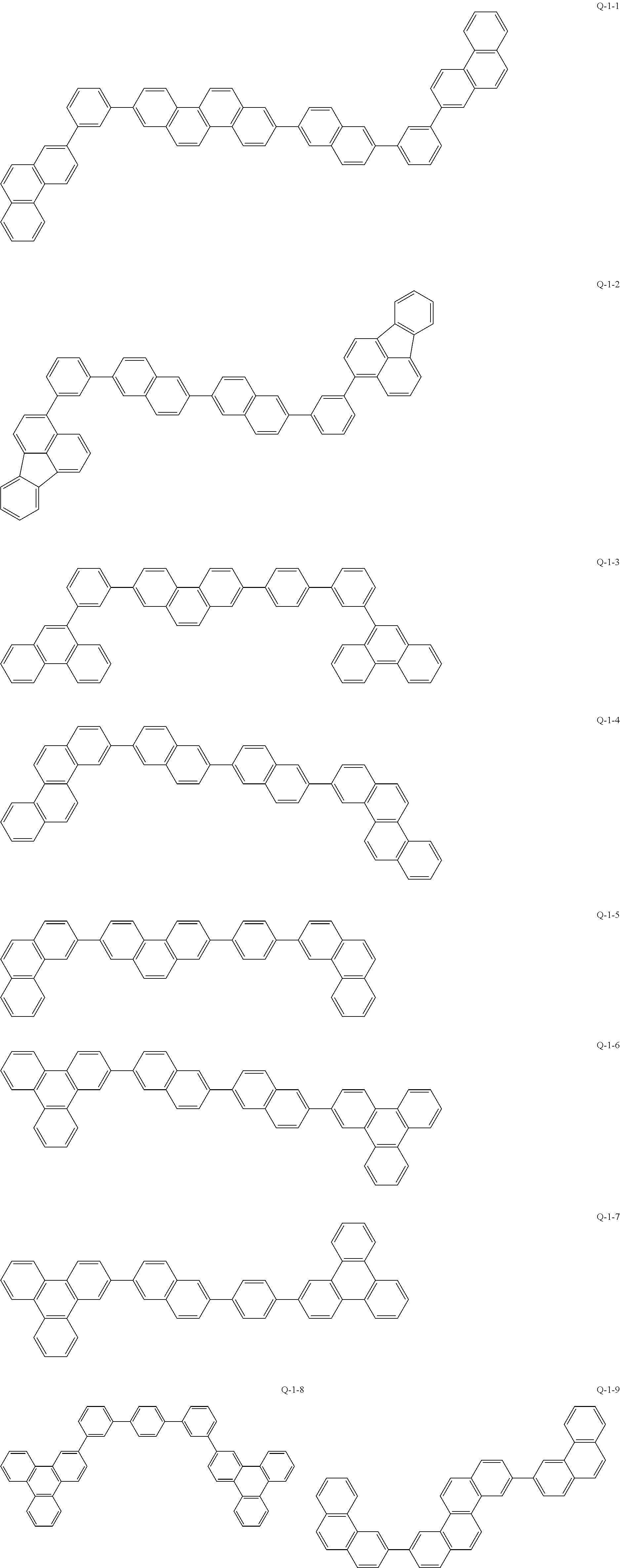

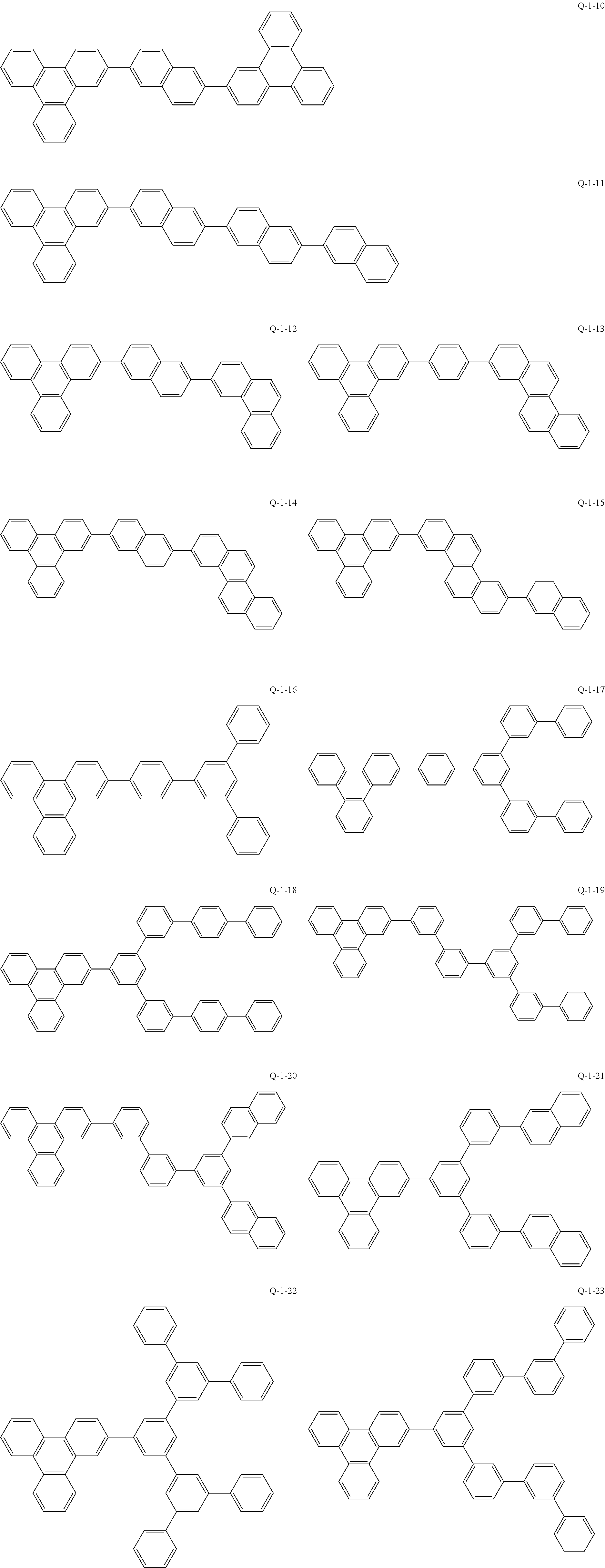

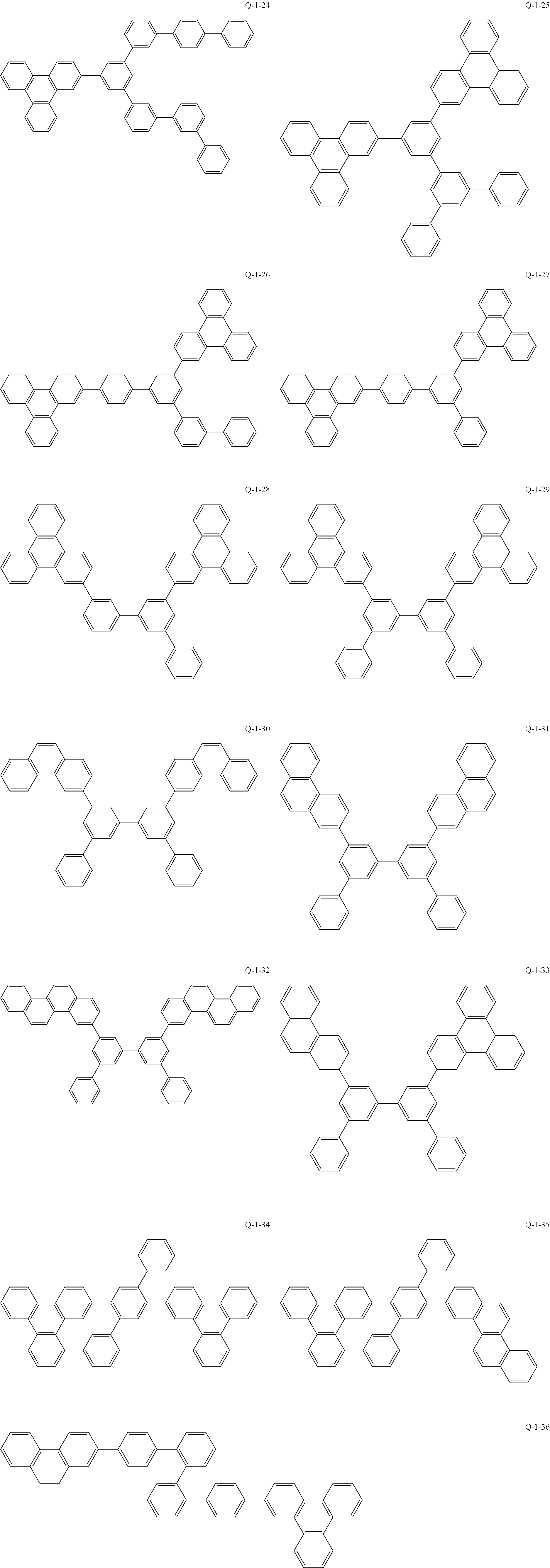

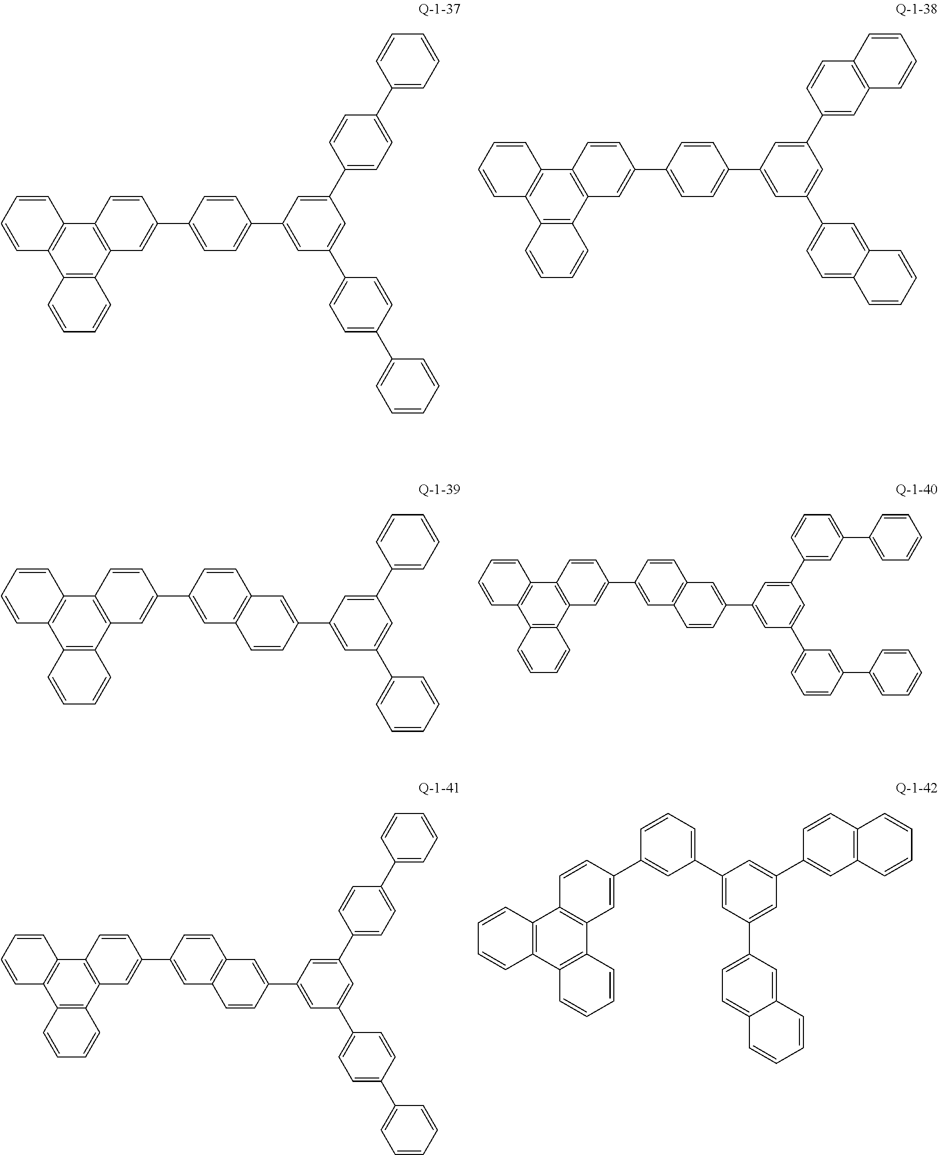

The above exemplified compounds have at least any one of the skeletons of triphenylene, naphthalene, phenanthrene, chrysene, and fluoranthene and do not contain SP3 carbon. Therefore, these compounds can come closer to the dopant material and thus can be a host material with strong interaction and allowing favorable energy transfer to the dopant material. Among these, compounds with a triphenylene skeleton are highly planar and particularly preferable.

### (4) Assist Material

In the present disclosure, the T1 of the assist material is equal to or higher than the T1 of the dopant material. Preferably, the assist material is a compound having at least one of the following structures:

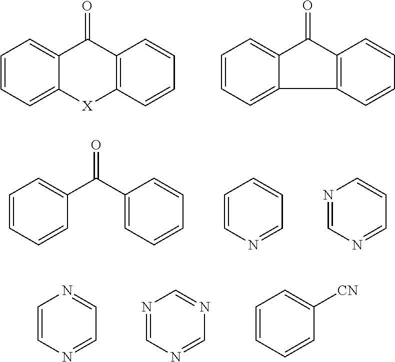

X represents an oxygen atom, a sulfur atom, or a substituted or unsubstituted carbon atom.

The above structures have electron-withdrawing groups, being effective in reducing the LUMO level of the assist material. The organometallic complexes represented by general formulas (1) to (3) have low HOMO levels and are likely to trap holes. Also, they have low LUMO levels and are less likely to trap electrons. Accordingly, the presence of an assist material with a high LUMO level in the luminescent layer facilitates the trapping of electrons in the luminescent layer. Consequently, an element with appropriate carrier balance is provided, and a highly efficient, long-life element is provided.

The above structures may or may not have a substituent. Also, the carbon atom represented by X may or may not have a substituent. Examples of the substituents include halogen atoms, alkyl groups, alkoxy groups, aryloxy groups, aryl groups, heterocyclic groups, silyl groups, and amino groups.

Specific examples of the assist material include, but are not limited to, the following:

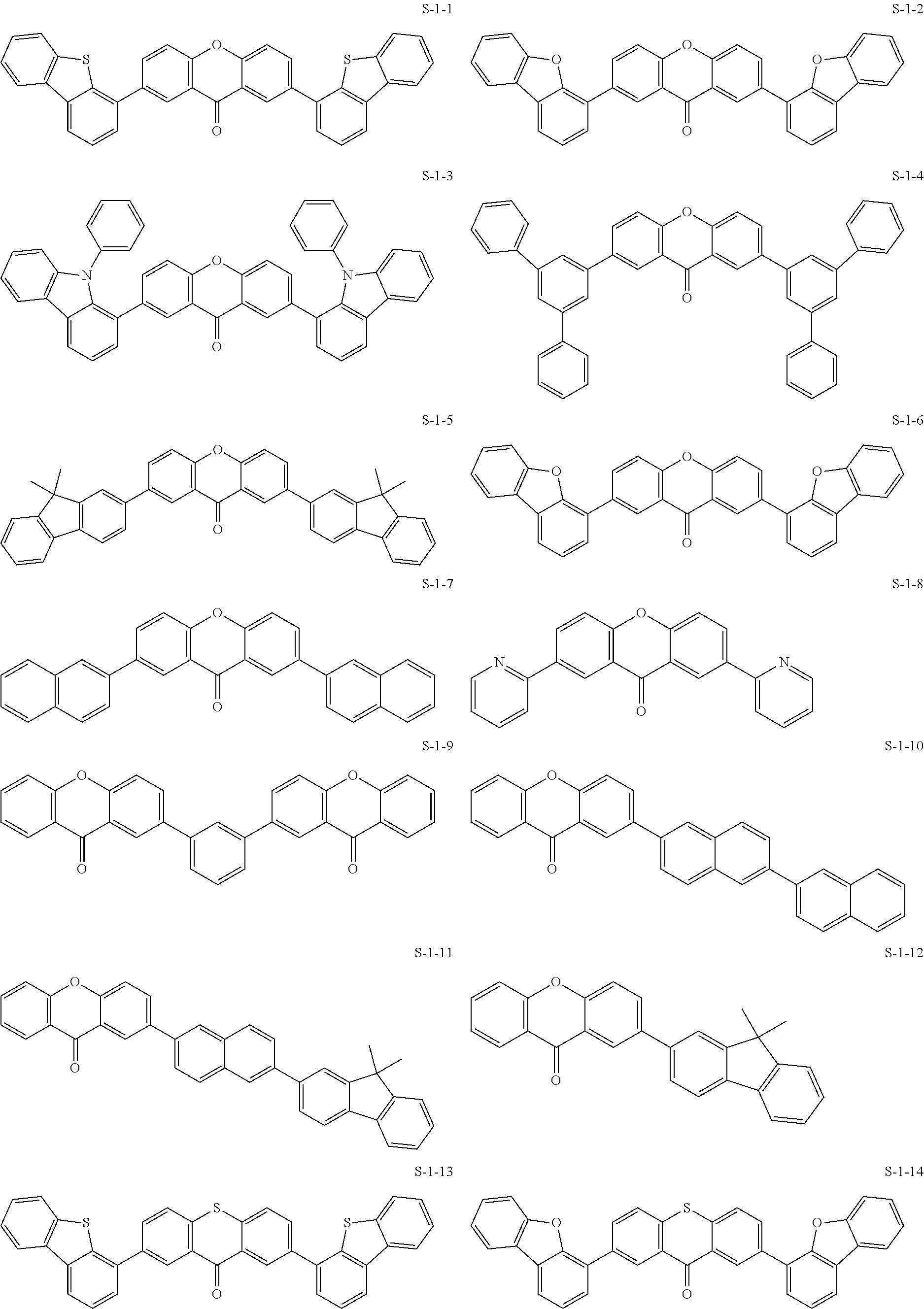

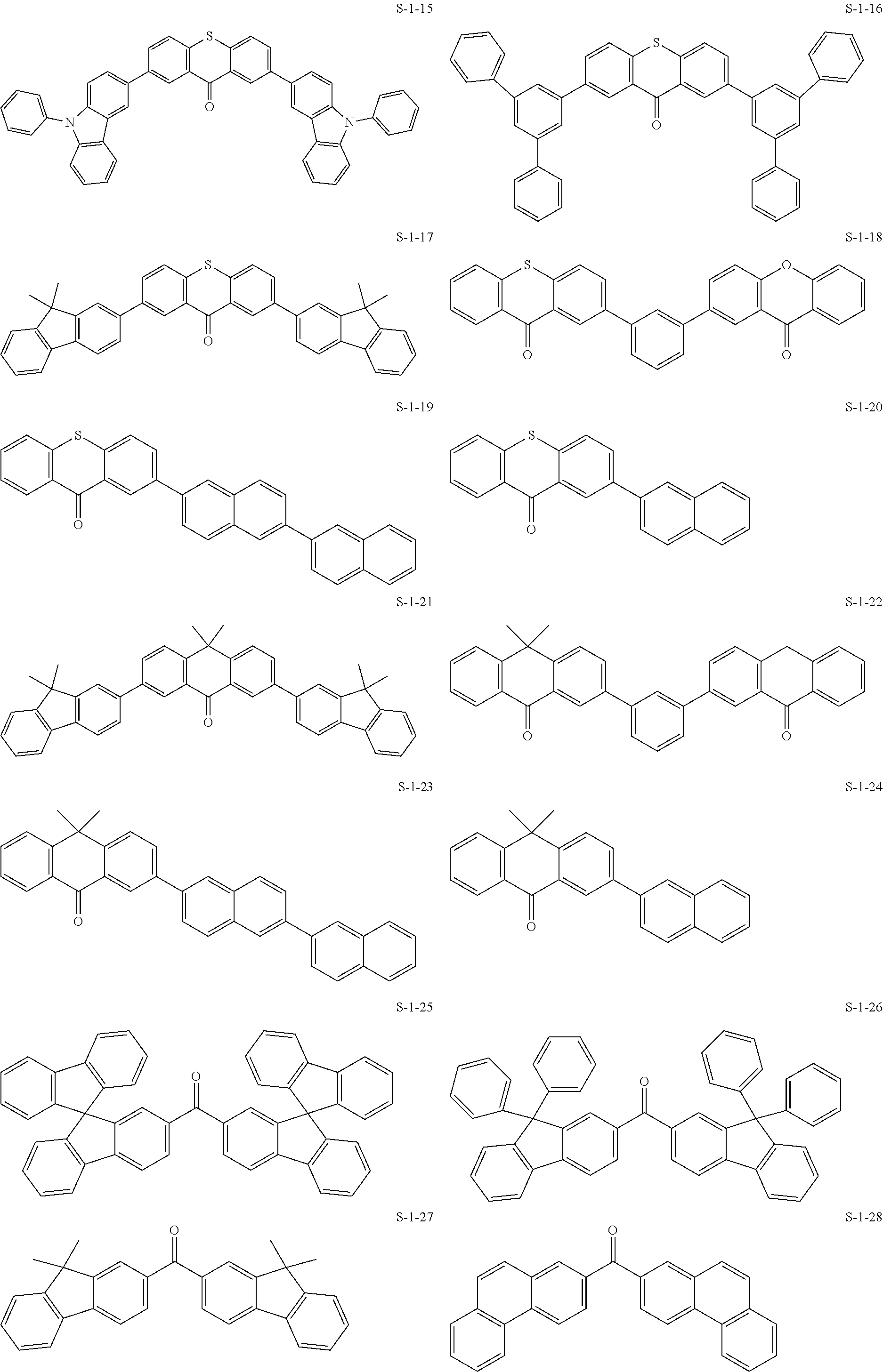

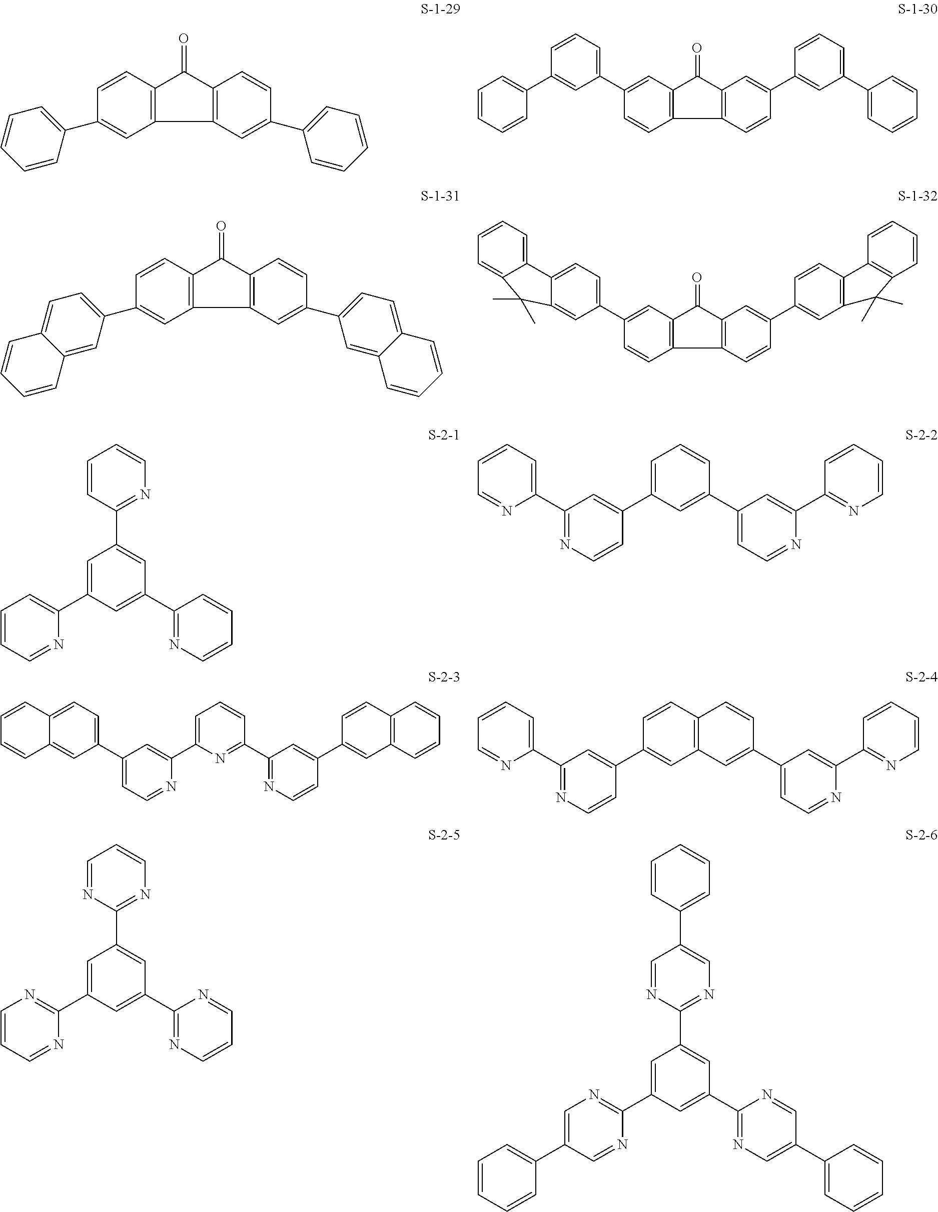

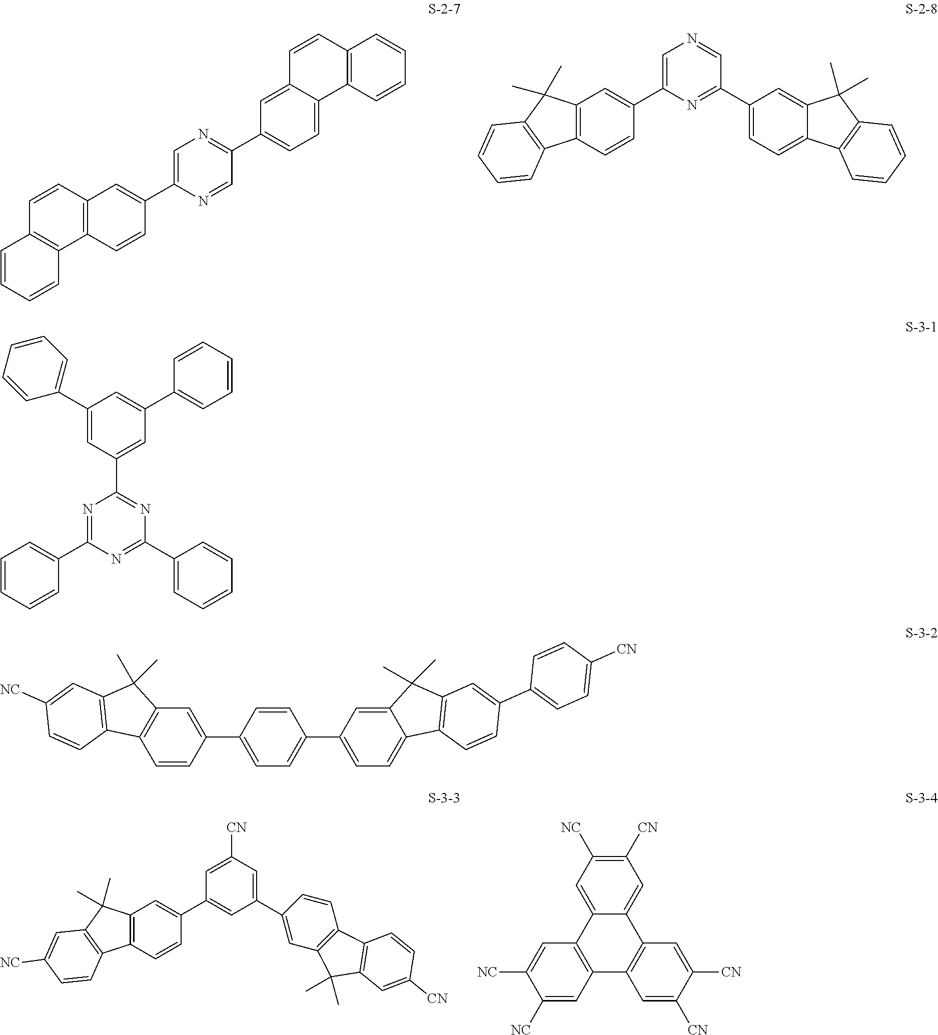

The amount of the assist material is preferably 0.1% to 45% by weight, more preferably 5% to 40% by weight, relative to the total mass of the luminescent layer.

### (5) Details of Organic Light-Emitting Element

The organic light-emitting element disclosed herein will now be described. The organic light-emitting element disclosed herein includes a first electrode, a second electrode, and an organic compound layer between the electrodes. One of the first and second electrodes is an anode, and the other is a cathode. In the organic light-emitting element disclosed herein, the organic compound layer may be composed of a single layer or have a multilayer structure including a plurality of layers, provided that the organic compound layer includes a luminescent layer. When the organic compound layer has a multilayer structure including a plurality of layers, the organic compound layer may include, a hole injection layer, a hole transport layer, an electron blocking layer, a hole/exciton blocking layer, an electron transport layer, and an electron injection layer, in addition to the luminescent layer. The luminescent layer may be composed of a single layer or have a multilayer structure including a plurality of layers.

In the organic light-emitting element disclosed herein, at least one layer of the above-mentioned organic compound layers contains the organometallic complex according to an embodiment of the disclosure. More specifically, the organometallic complex disclosed herein is contained in any of the above-mentioned luminescent layer, hole injection layer, hole transport layer, electron blocking layer, hole/exciton blocking layer, electron transport layer, electron injection layer, and the like. In a preferred embodiment, the organometallic complex is contained in the luminescent layer.

In an embodiment of the organic light-emitting element in which the luminescent layer contains the organometallic complex of an embodiment of the disclosure, the luminescent layer may be made of only the organometallic complex or the organometallic complex and other compounds. When the luminescent layer is made of the organometallic complex and other compounds, the organometallic complex disclosed herein may be used as the host or the guest in the luminescent layer. Alternatively, the organometallic complex may be used as an assist material that may be contained in the luminescent layer. The host used here refers to the compound accounting for the highest percentage of the total mass of the compounds in the luminescent layer. Also, the guest used here refers to a compound in a lower percentage by mass than the host in the luminescent layer and is responsible for the main luminescence. The assist material refers to a compound in a lower percentage by mass than the host in the luminescent and helps the guest emit light. The assist material is also called the second host. The host material may be called a first compound, and the assist material may be called a second compound.

When the organometallic complex disclosed herein is used as the guest in the luminescent layer, the amount of the guest is preferably 0.01% to 30% by mass, more preferably 2% to 20% by mass, relative to the total mass of the luminescent layer.

The present inventors have found that using the organometallic complex disclosed herein as the host or the guest, particularly as the guest, in the luminescent layer can provide an element that efficiently emits light with high luminance and has extremely high endurance. The luminescent layer may be composed of a single layer or may have a multilayer structure. Also, the luminescent layer may contain another luminescent material exhibiting another emission color to emit a color light mixed with red, which is the emission color of the disclosed compound. The multilayer structure refers to a state where different luminescent layers are stacked one on top of another. In this instance, the emission color of the organic light-emitting element is not limited to red. For example, the emission color may be white or intermediate color. When the emission color is white, another luminescent layer emits a color light other than red light, such as blue or green. The luminescent layer is formed by vapor deposition or coating. This process will be described in detail later.

The organometallic complex disclosed herein may be used as a constituent of other organic compound layers of the organic light-emitting element disclosed herein, apart from the luminescent layer. For example, the organometallic complex may be used as a constituent of the electron transport layer, the electron injection layer, the hole transport layer, the hole injection layer, the hole blocking layer, or the like. In this instance, the emission color of the organic light-emitting element is not limited to red. For example, the emission color may be white or intermediate color.

The organometallic complex disclosed herein may be used in combination with known low-molecular-weight or polymeric compounds such as a hole injecting or hole transporting compound, a compound functioning as a host, a luminescent compound, and an electron injecting or electron transporting compound, as needed. Examples of these compounds are presented below.

As the hole injecting or transporting material, materials with high hole mobility are preferred to facilitate the injection of holes from the anode and to transport the injected holes to the luminescent layer. Also, materials with a high glass transition temperature are preferred to reduce the crystallization or any other deterioration of the layer in the organic light-emitting element. Low-molecular-weight or polymeric hole injecting or transporting materials include triarylamine derivatives, aryl carbazole derivatives, phenylenediamine derivatives, stilbene derivatives, phthalocyanine derivatives, porphyrin derivatives, poly(vinyl carbazole), poly(thiophene), and other electrically conductive polymers. Such a hole injecting or transporting material is also suitably used in the electron blocking layer. Examples of the compounds that can be used as the hole injecting or transporting material include, but are not limited to, the following:

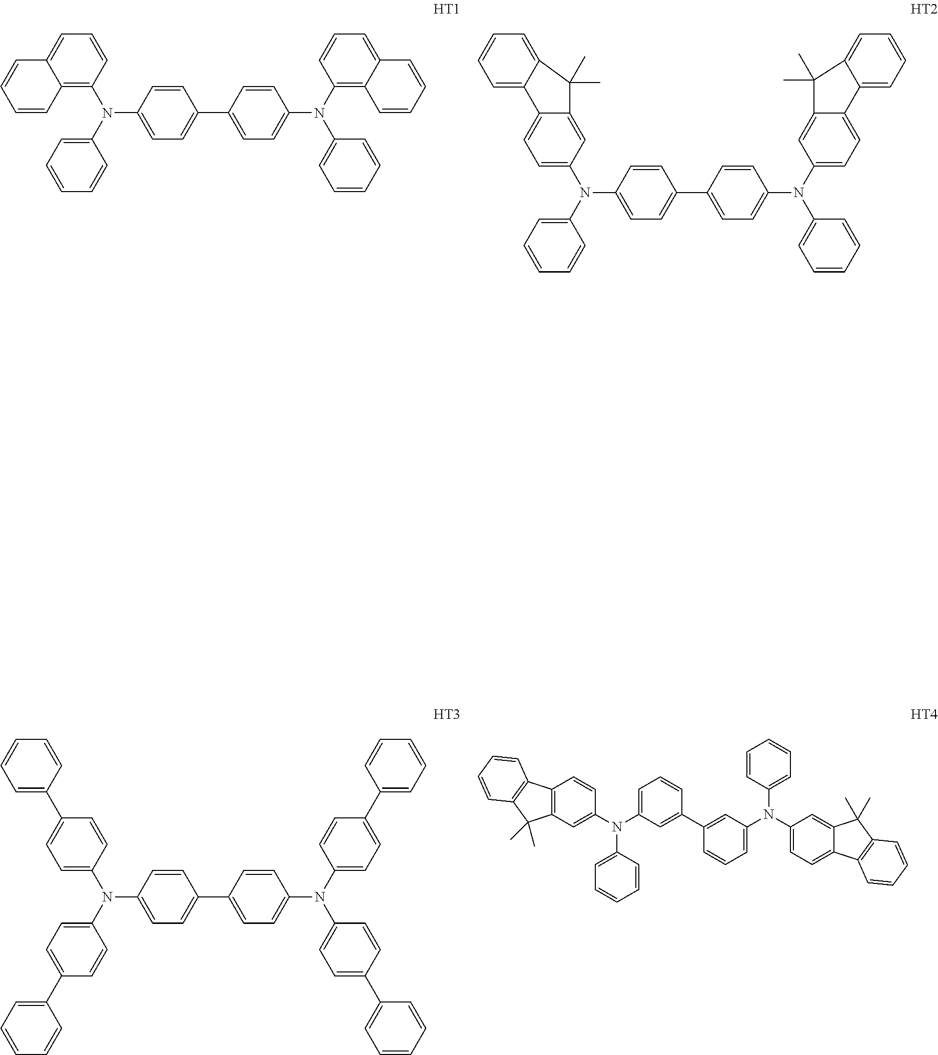 [SMILES: c1ccc(N(c2ccc(-c3ccc(N(c4ccccc4)c4cccc5ccccc45)cc3)cc2)c2cccc3ccccc23)cc1 ; CC1(C)c2ccccc2-c2ccc(N(c3ccccc3)c3ccc(-c4ccc(N(c5ccccc5)c5ccc6c(c5)C(C)(C)c5ccccc5-6)cc4)cc3)cc21 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; CC1(C)c2ccccc2-c2ccc(N(c3ccccc3)c3cccc(-c4cccc(N(c5ccccc5)c5ccc6c(c5)C(C)(C)c5ccccc5-6)c4)c3)cc21]

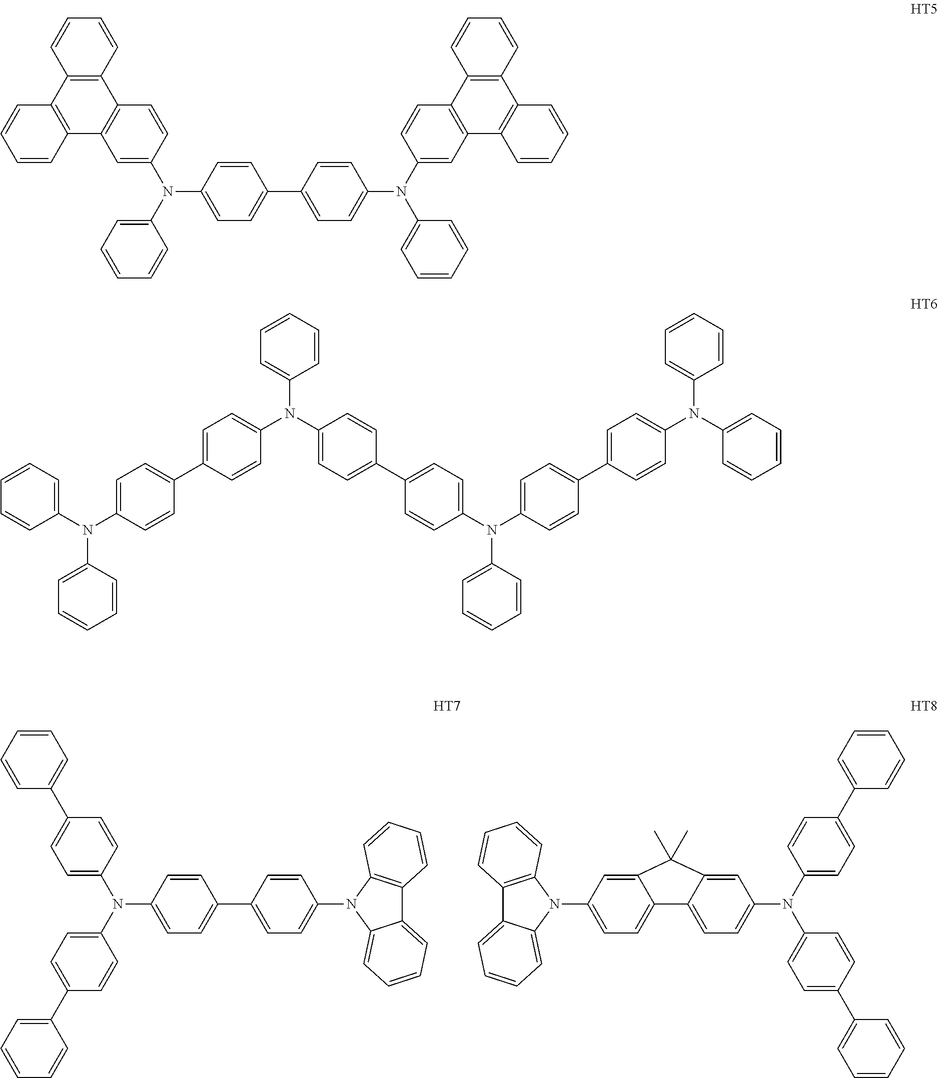 [SMILES: c1ccc(N(c2ccc(-c3ccc(N(c4ccccc4)c4ccc5c6ccccc6c6ccccc6c5c4)cc3)cc2)c2ccc3c4ccccc4c4ccccc4c3c2)cc1 ; c1ccc(N(c2ccccc2)c2ccc(-c3ccc(N(c4ccccc4)c4ccc(-c5ccc(N(c6ccccc6)c6ccc(-c7ccc(N(c8ccccc8)c8ccccc8)cc7)cc6)cc5)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2cc(N(c3ccc(-c4ccccc4)cc3)c3ccc(-c4ccccc4)cc3)ccc2-c2ccc(-n3c4ccccc4c4ccccc43)cc21]

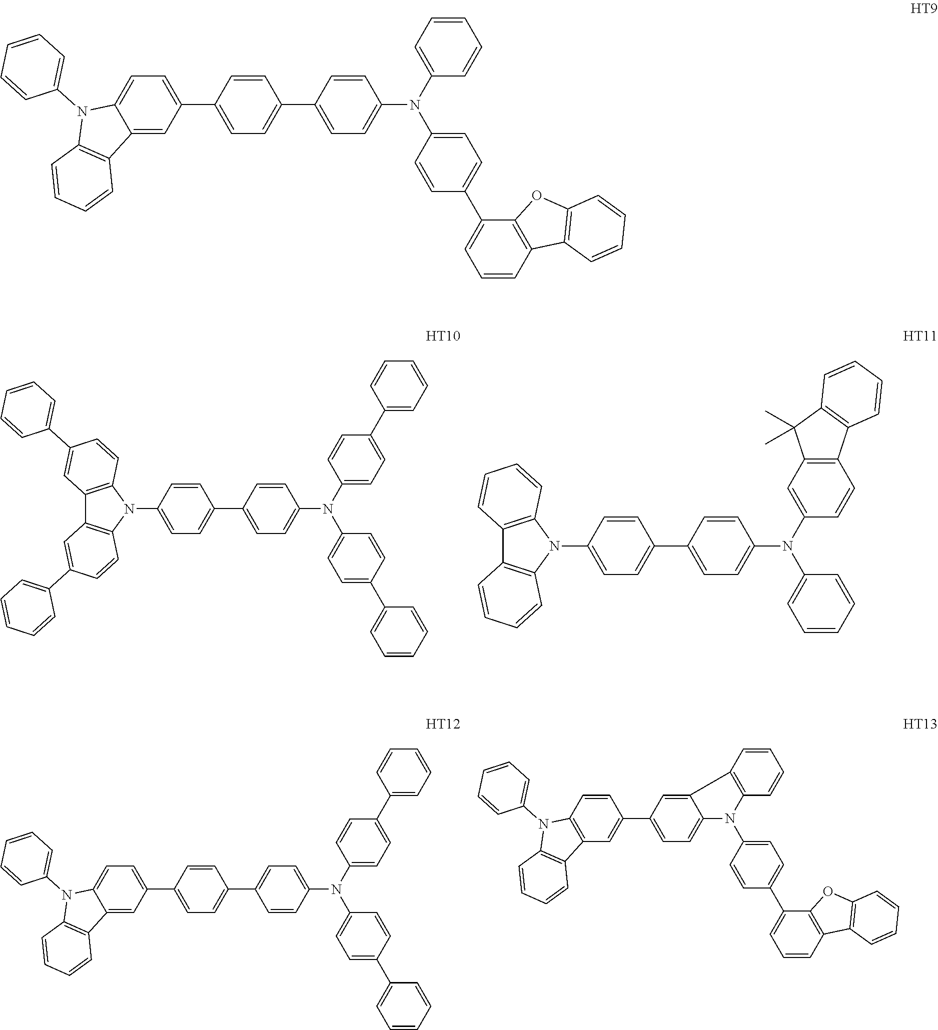 [SMILES: c1ccc(N(c2ccc(-c3ccc(-c4ccc5c(c4)c4ccccc4n5-c4ccccc4)cc3)cc2)c2ccc(-c3cccc4c3oc3ccccc34)cc2)cc1 ; c1ccc(-c2ccc(N(c3ccc(-c4ccccc4)cc3)c3ccc(-c4ccc(-n5c6ccc(-c7ccccc7)cc6c6cc(-c7ccccc7)ccc65)cc4)cc3)cc2)cc1 ; CC1(C)c2ccccc2-c2ccc(N(c3ccccc3)c3ccc(-c4ccc(-n5c6ccccc6c6ccccc65)cc4)cc3)cc21 ; c1ccc(-c2ccc(N(c3ccc(-c4ccccc4)cc3)c3ccc(-c4ccc(-c5ccc6c(c5)c5ccccc5n6-c5ccccc5)cc4)cc3)cc2)cc1 ; c1ccc(-n2c3ccccc3c3cc(-c4ccc5c(c4)c4ccccc4n5-c4ccc(-c5cccc6c5oc5ccccc56)cc4)ccc32)cc1]

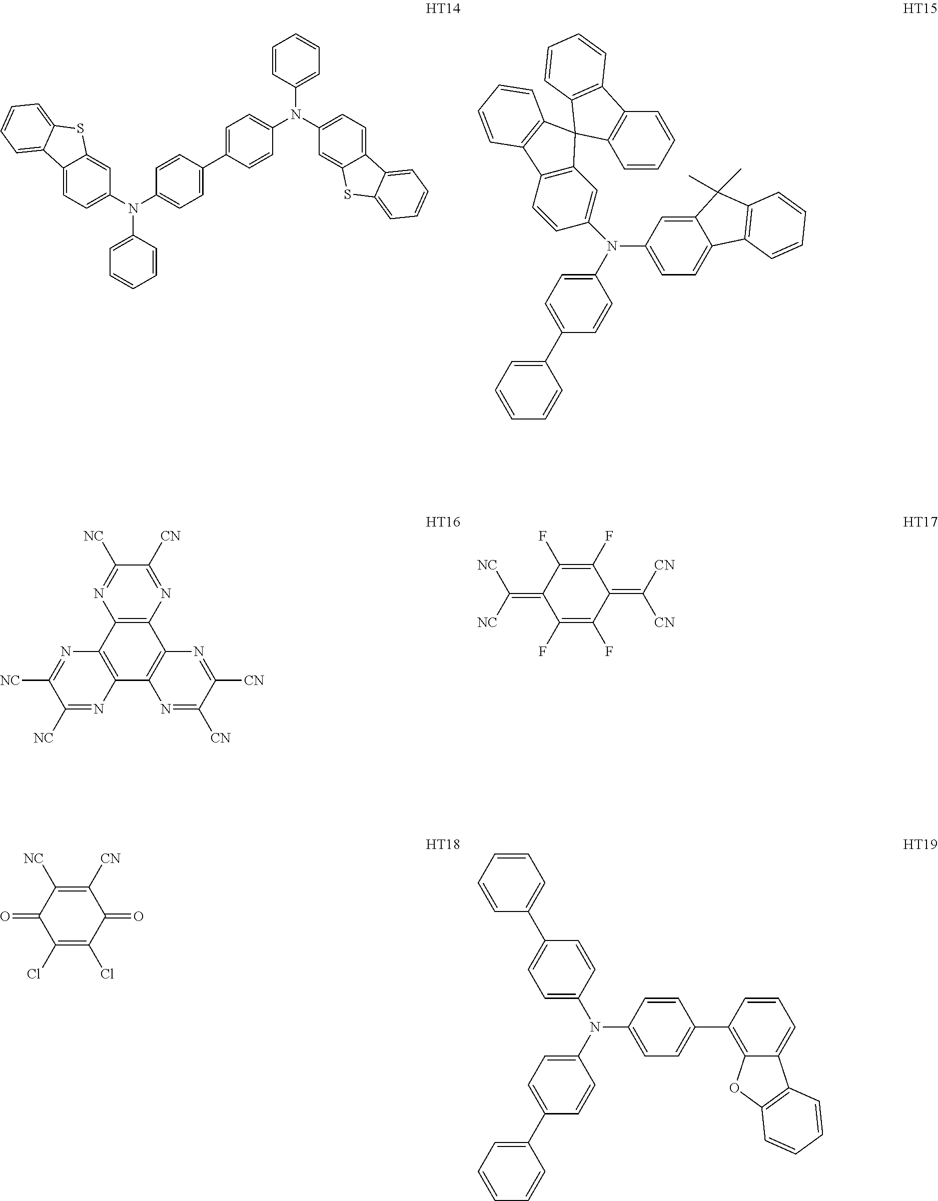 [SMILES: c1ccc(N(c2ccc(-c3ccc(N(c4ccccc4)c4ccc5c(c4)sc4ccccc45)cc3)cc2)c2ccc3c(c2)sc2ccccc23)cc1 ; CC1(C)c2ccccc2-c2ccc(N(c3ccc(-c4ccccc4)cc3)c3ccc4c(c3)C3(c5ccccc5-c5ccccc53)c3ccccc3-4)cc21 ; N#Cc1nc2c3nc(C#N)c(C#N)nc3c3nc(C#N)c(C#N)nc3c2nc1C#N ; N#CC(C#N)=c1c(F)c(F)c(=C(C#N)C#N)c(F)c1F ; N#CC1=C(C#N)C(=O)C(Cl)=C(Cl)C1=O ; c1ccc(-c2ccc(N(c3ccc(-c4ccccc4)cc3)c3ccc(-c4cccc5c4oc4ccccc45)cc3)cc2)cc1]

Among the above-presented hole transporting materials, HT16 to HT18 can reduce the driving voltage when used in the layer in contact with the anode. HT16 is widely used in organic light-emitting elements. HT2, HT3, HT4, HT5, HT6, HT10, or HT12 may be used in the organic compound layer in contact with HT16. A plurality of materials may be used in one organic compound layer.

Other luminescent dopants may be used in addition to the luminescent dopant of the present disclosure.

Examples of such compounds include condensed ring compounds (e.g., fluorene derivatives, naphthalene derivatives, pyrene derivatives, perylene derivatives, tetracene derivatives, anthracene derivatives, rubrene, etc.), quinacridone derivatives, coumarin derivatives, stilbene derivatives, organoaluminum complexes such as tris(8-quinolinolato)aluminum, iridium complexes, platinum complexes, rhenium complexes, copper complexes, europium complexes, ruthenium complexes, and polymer derivatives such as poly(phenylene vinylene) derivatives, poly(fluorene) derivatives, and poly(phenylene) derivatives.

Examples of compounds that can be used as the luminescent material include, but are not limited to, the following:

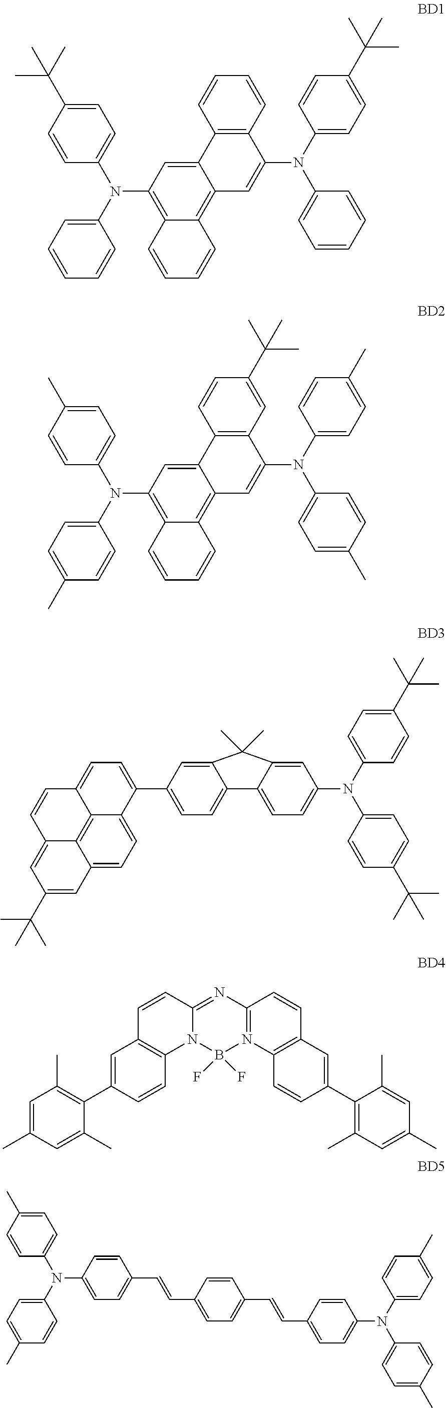

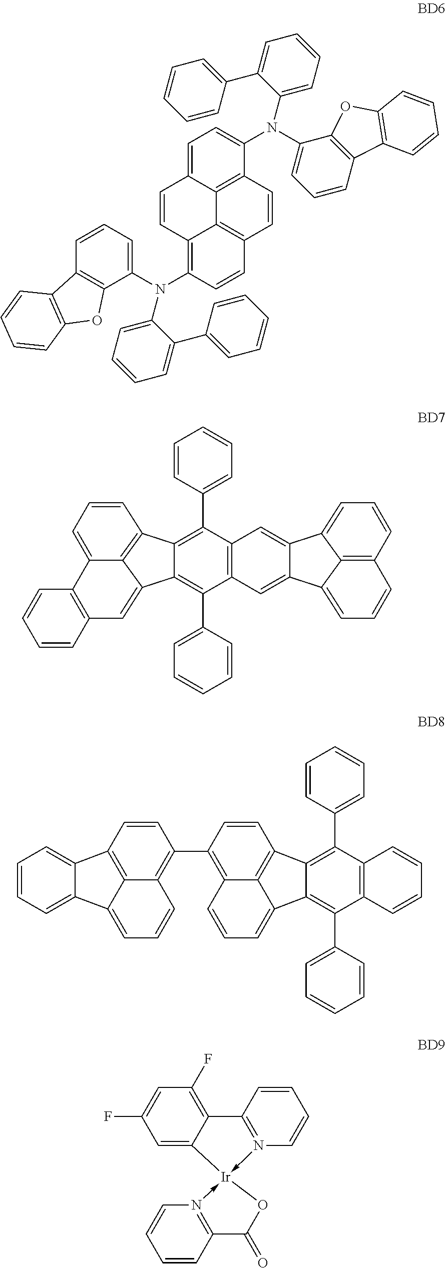

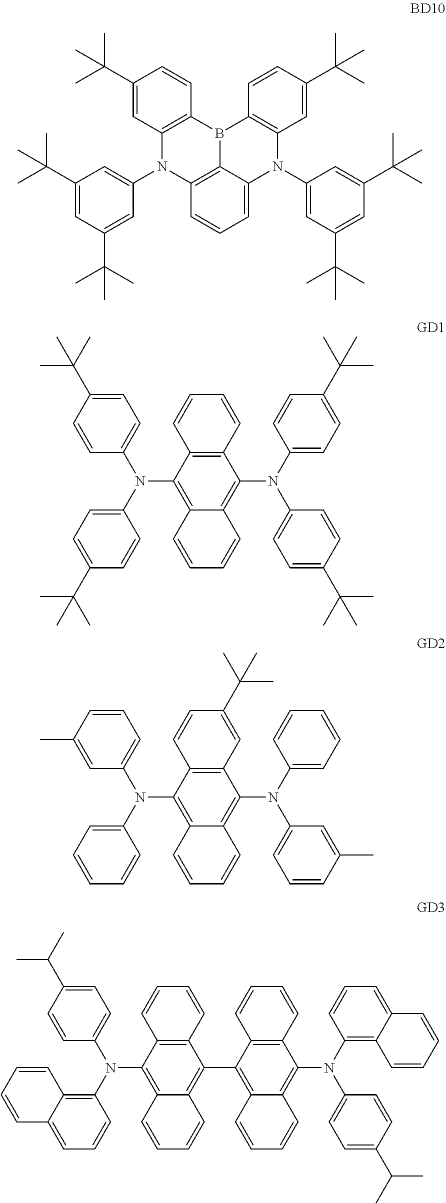

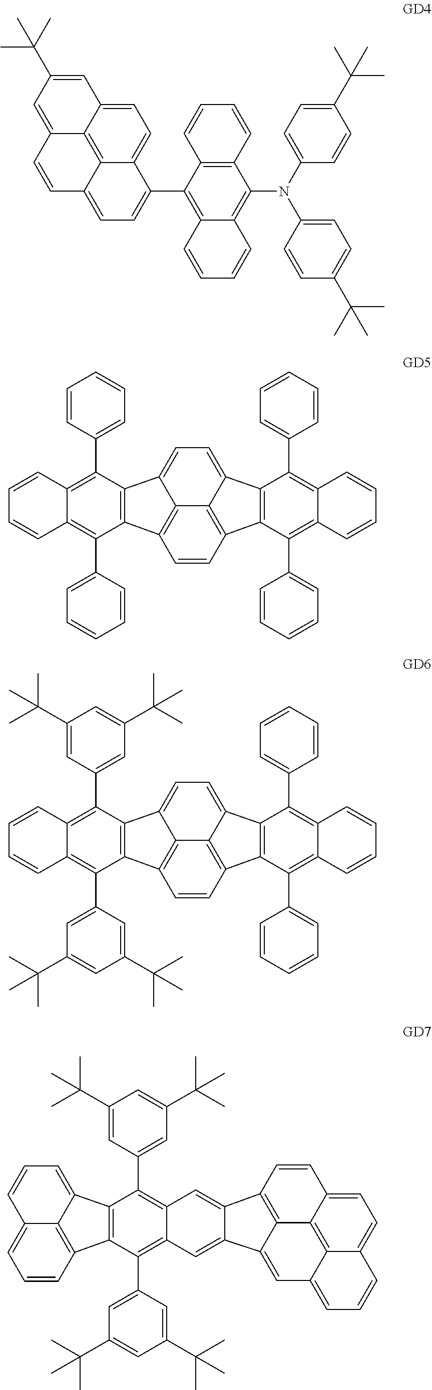

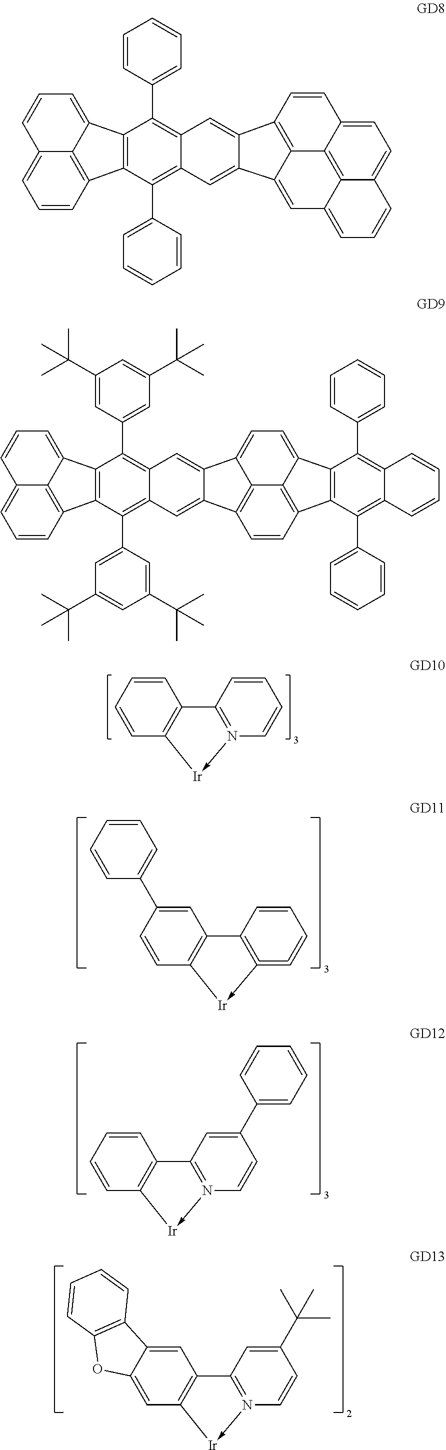

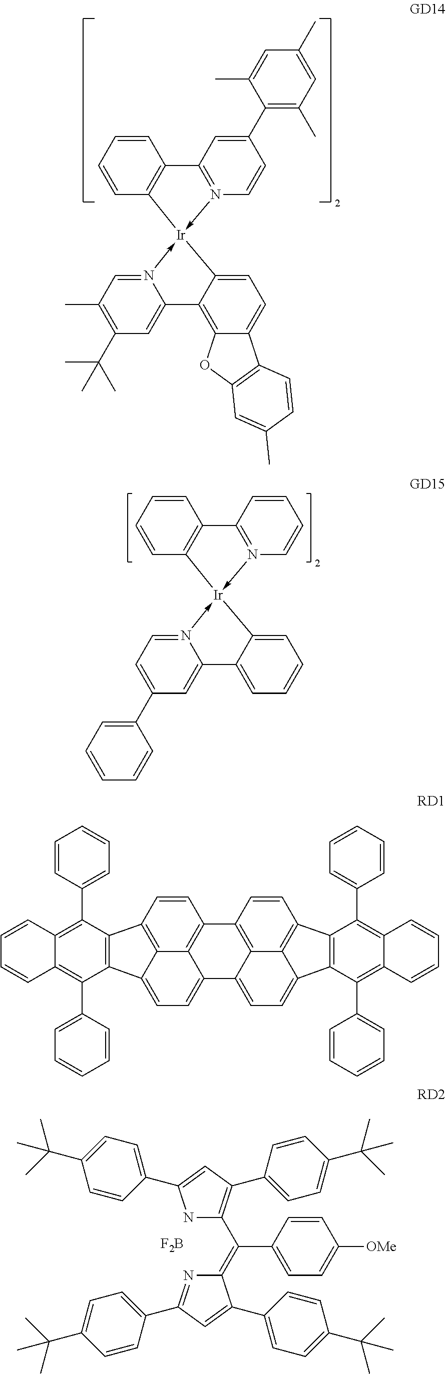

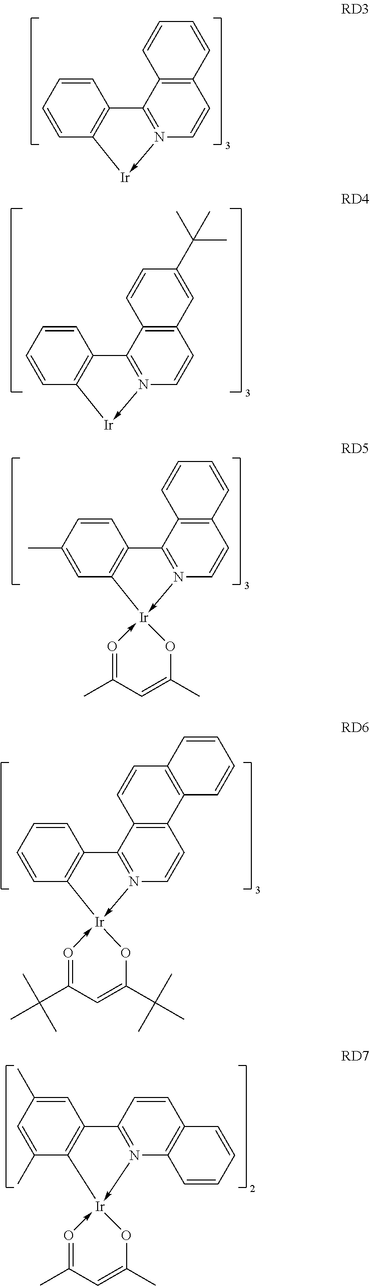

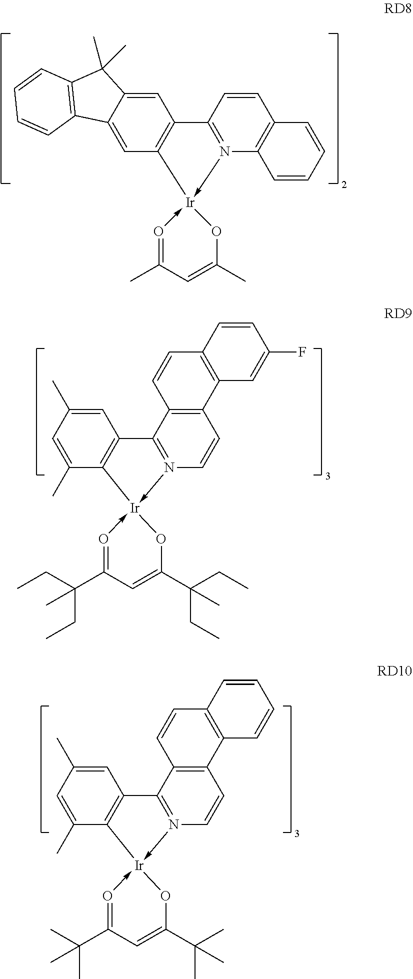

Luminescent materials that are hydrocarbon compounds are preferred because such compounds can reduce the decrease of luminous efficiency caused by exciplex formation and the degradation of color purity caused by changes of the emission spectrum of the luminescent material. Hydrocarbon compounds are made up only of carbon and hydrogen. Among the above exemplified compounds, BD7, BD8, GD5 to GD9, and RD1 correspond to hydrocarbon compounds.

Luminescent materials that are condensed polycyclic rings containing a 5-membered ring are further preferred because such compounds have high ionization potential and are less likely to oxidize, accordingly, providing long-life elements with high endurance. BD7, BD8, GD5 to GD9, and RD1 correspond to such compounds.

Examples of the host material or assist material contained in the luminescent layer include aromatic hydrocarbons and their derivatives, carbazole derivatives, dibenzofuran derivatives, dibenzothiophene derivatives, organoaluminum complexes such as tris(8-quinolinolato)aluminum, and organoberyllium complexes.

Specific examples include, but are not limited to, the following:

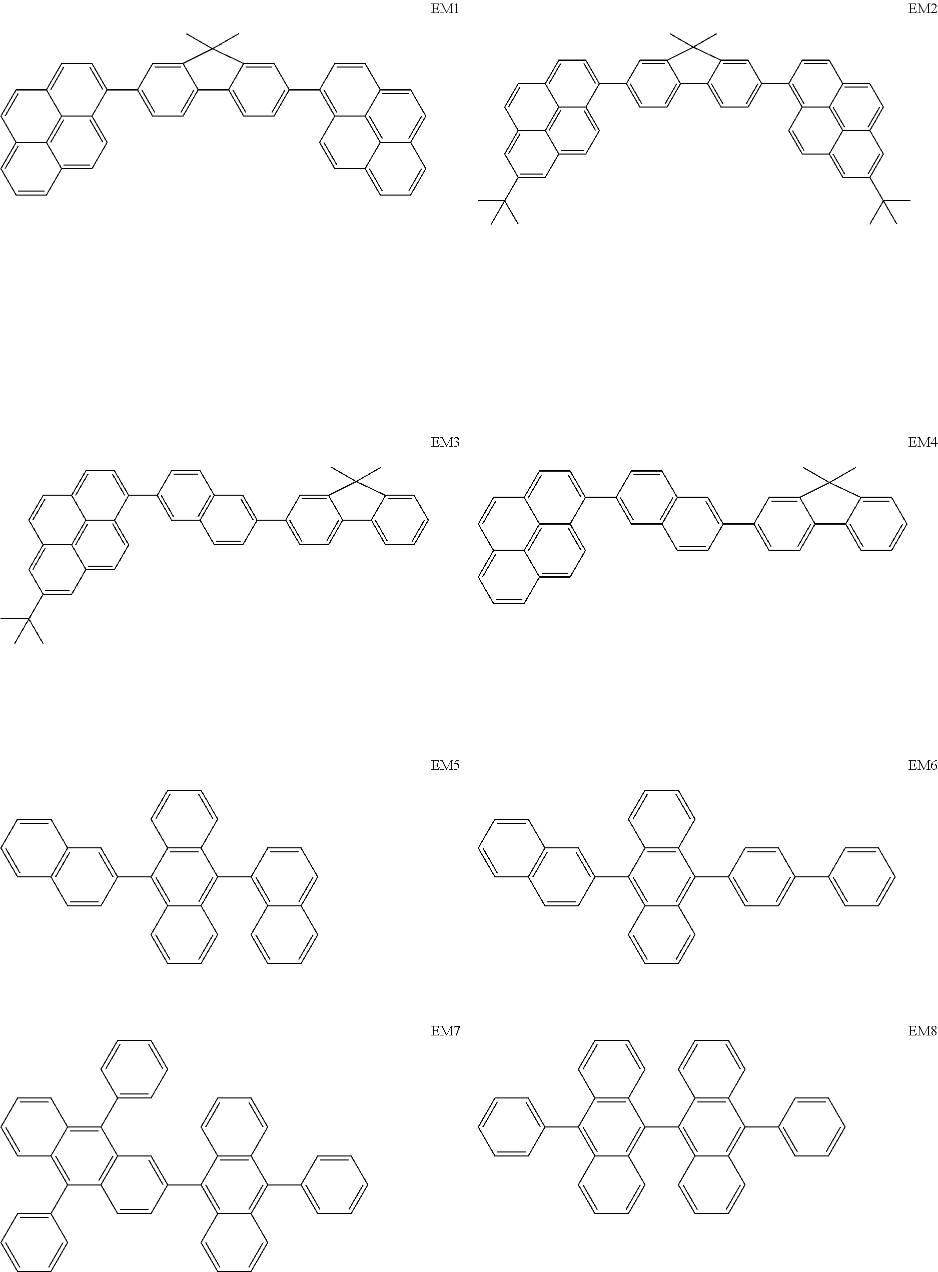

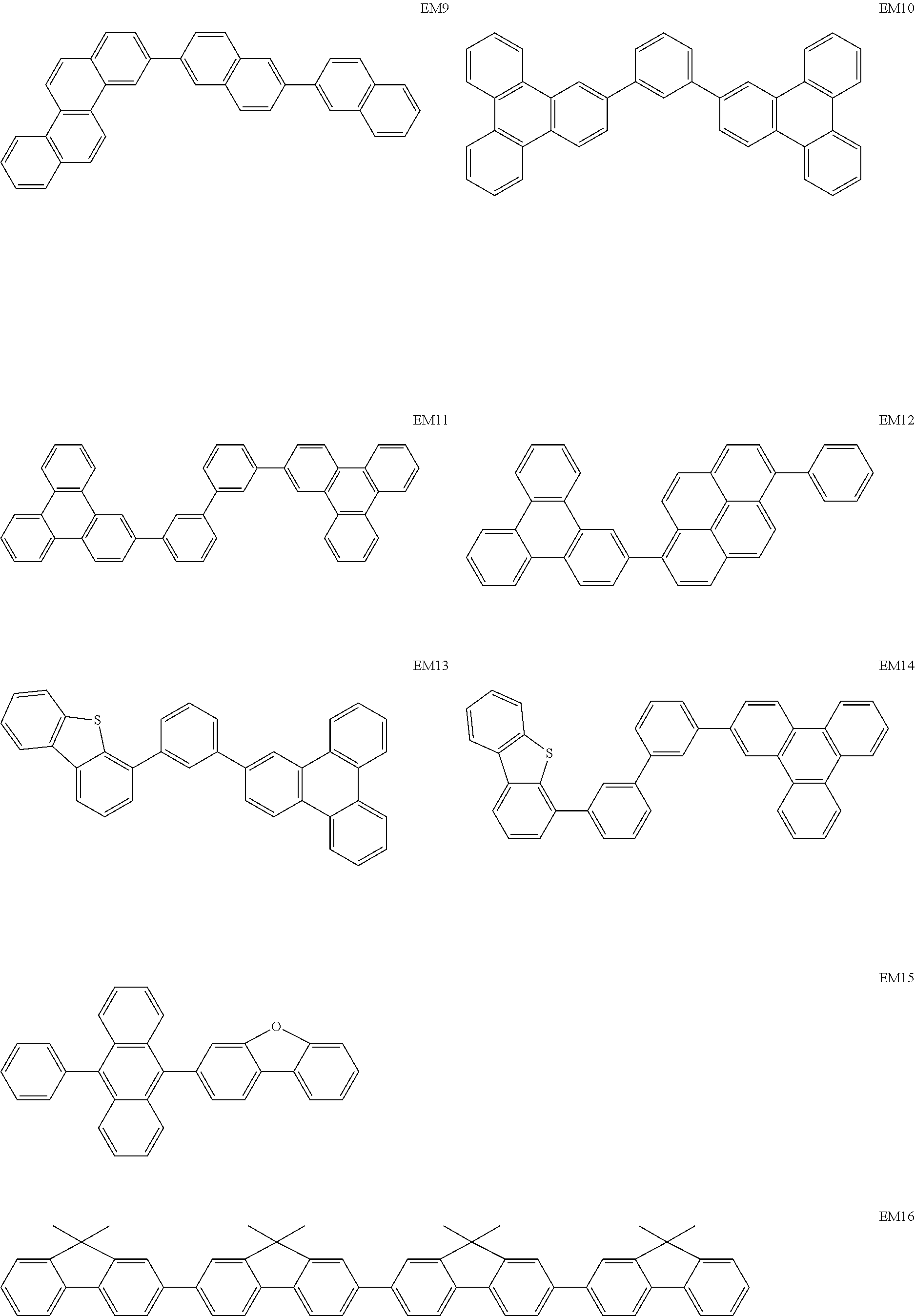

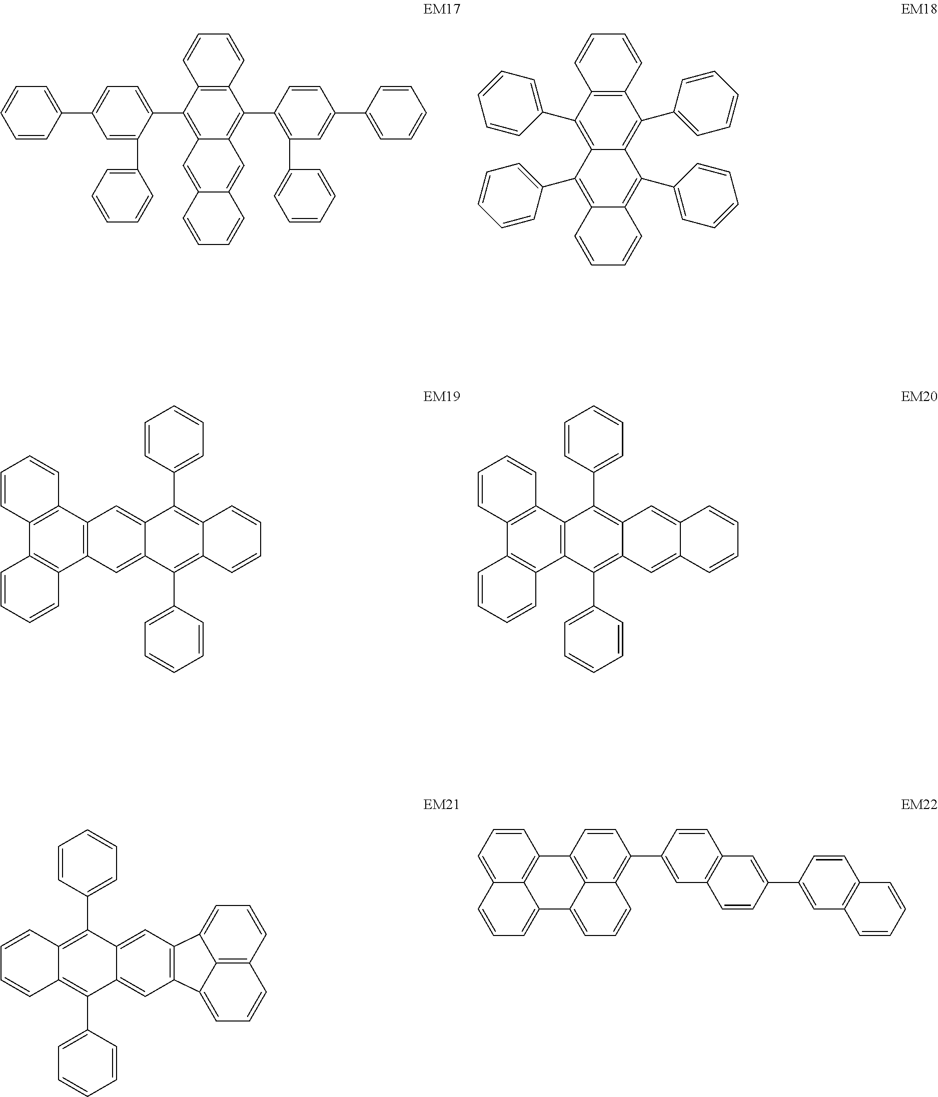

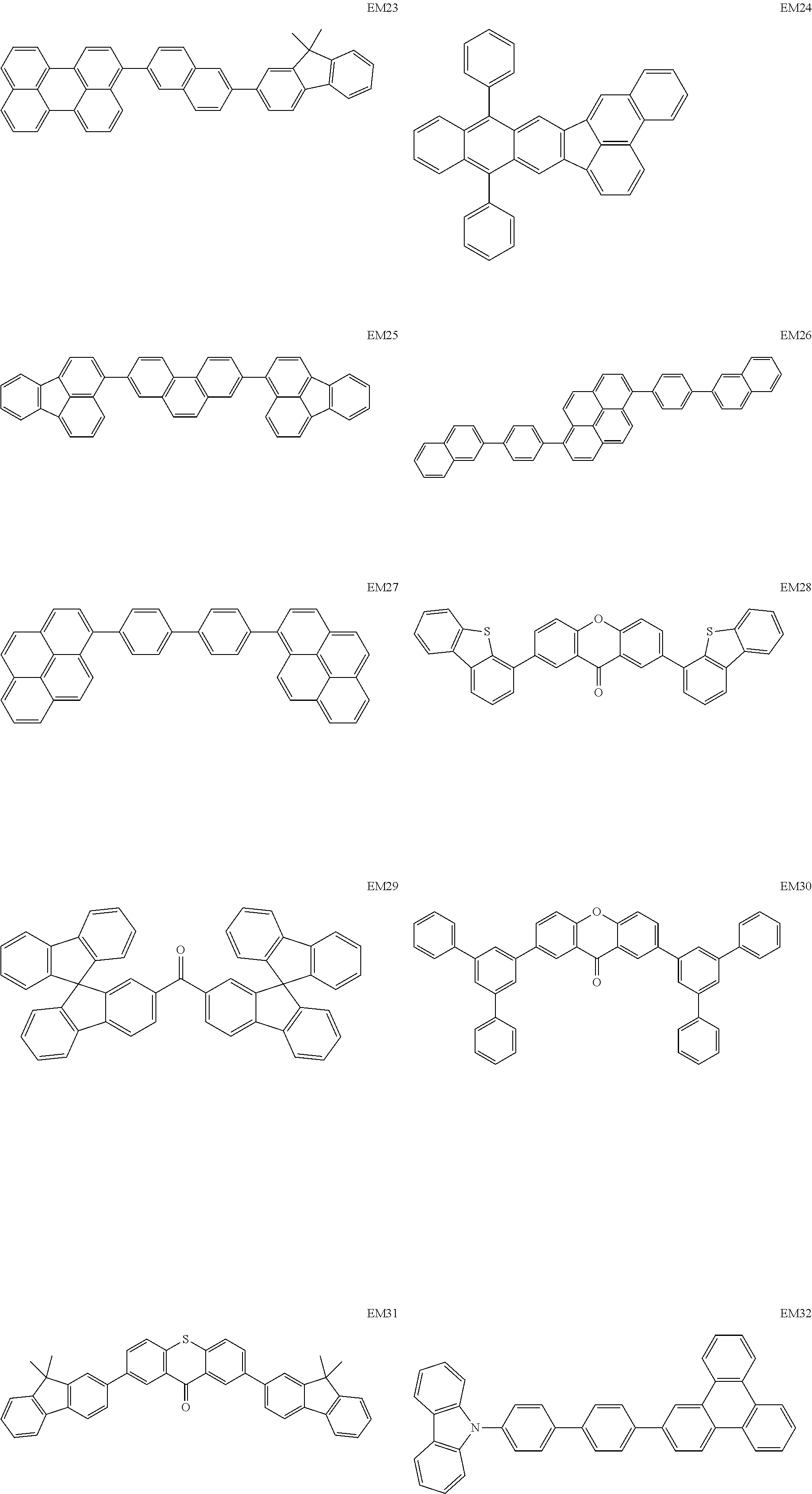

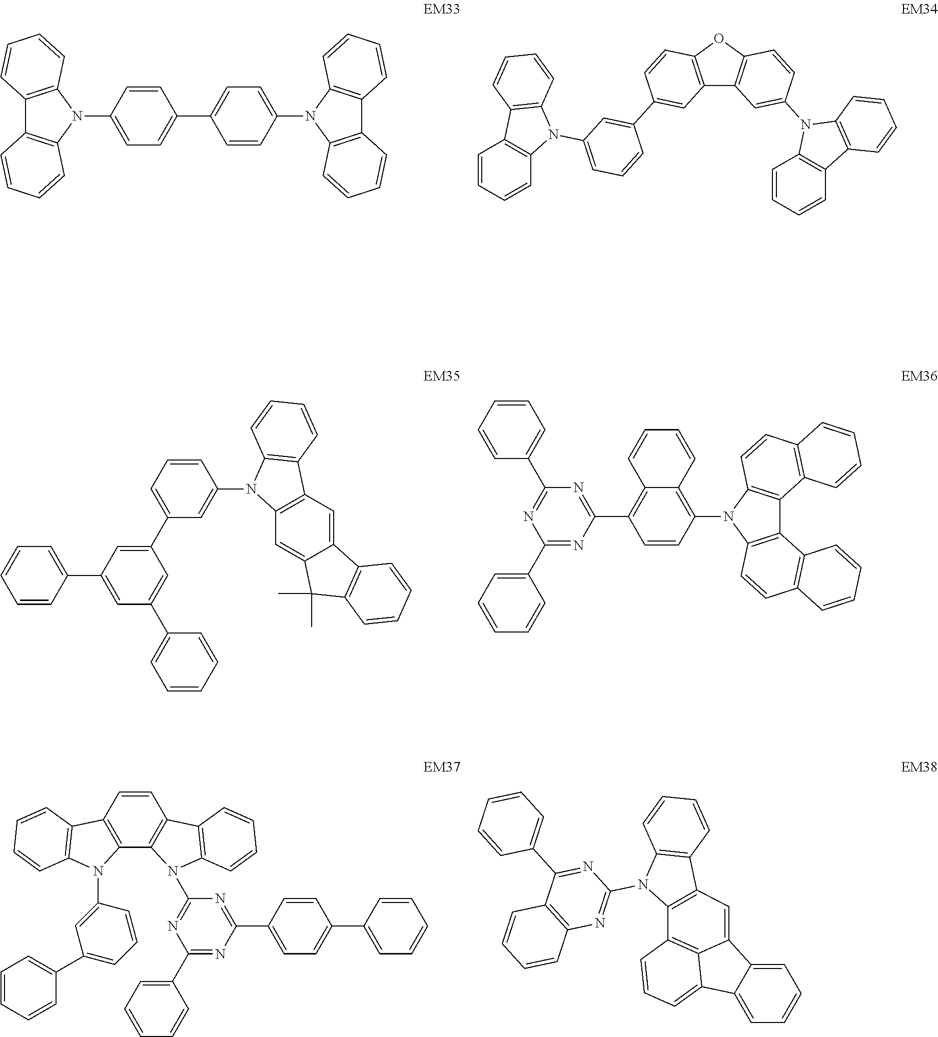 [SMILES: c1ccc2c(c1)c1ccccc1n2-c1ccc(-c2ccc(-n3c4ccccc4c4ccccc43)cc2)cc1 ; c1cc(-c2ccc3oc4ccc(-n5c6ccccc6c6ccccc65)cc4c3c2)cc(-n2c3ccccc3c3ccccc32)c1 ; CC1(C)c2ccccc2-c2cc3c4ccccc4n(-c4cccc(-c5cc(-c6ccccc6)cc(-c6ccccc6)c5)c4)c3cc21 ; c1ccc(-c2nc(-c3ccccc3)nc(-c3ccc(-n4c5ccc6ccccc6c5c5c6ccccc6ccc54)c4ccccc34)n2)cc1 ; c1ccc(-c2ccc(-c3nc(-c4ccccc4)nc(-n4c5ccccc5c5ccc6c7ccccc7n(-c7cccc(-c8ccccc8)c7)c6c54)n3)cc2)cc1 ; c1ccc(-c2nc(-n3c4ccccc4c4cc5c6c(cccc6c43)-c3ccccc3-5)nc3ccccc23)cc1]

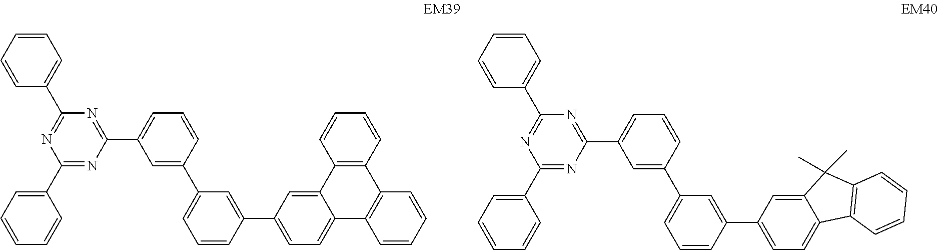 [SMILES: c1ccc(-c2nc(-c3ccccc3)nc(-c3cccc(-c4cccc(-c5ccc6c7ccccc7c7ccccc7c6c5)c4)c3)n2)cc1 ; CC1(C)c2ccccc2-c2ccc(-c3cccc(-c4cccc(-c5nc(-c6ccccc6)nc(-c6ccccc6)n5)c4)c3)cc21]

Host materials that are hydrocarbon compounds allow the compound of the present disclosure to easily trap electrons and holes, thus being favorably effective in increasing efficiency. Hydrocarbon compounds are made up only of carbon and hydrogen. Among the above exemplified compounds, EM1 to EM12 and EM16 to EM27 correspond to such compounds.

The electron transporting material can be selected arbitrarily from the compounds capable of transporting electrons injected from the cathode to the luminescent layer and is selected in view of the balance with the hole mobility of the hole transporting material. Electron transporting materials include oxadiazole derivatives, oxazole derivatives, pyrazine derivatives, triazole derivatives, triazine derivatives, quinoline derivatives, quinoxaline derivatives, phenanthroline derivatives, organoaluminum complexes, and condensed ring compounds (e.g., fluorene derivatives, naphthalene derivatives, chrysene derivatives, anthracene derivatives, etc.) The above electron transporting materials are also suitably used in the hole blocking layer.

Examples of the compounds that can be used as the electron transporting material include, but are not limited to, the following:

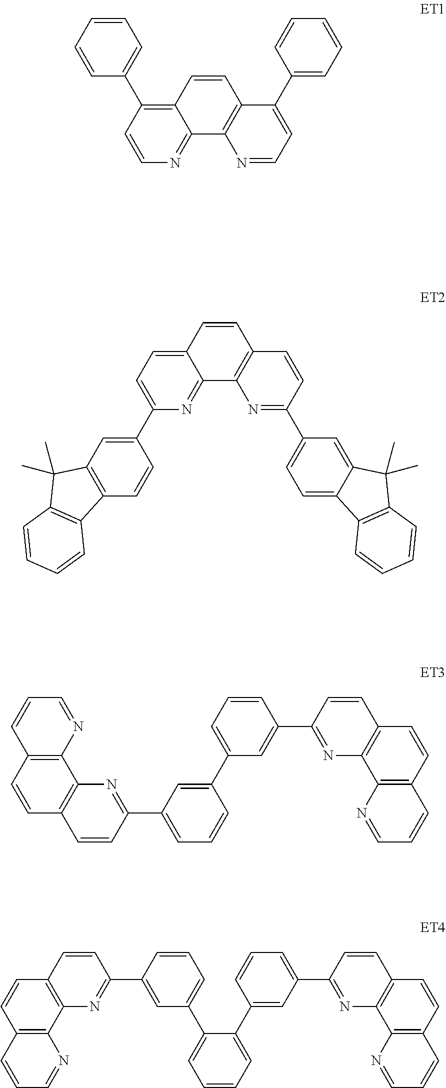

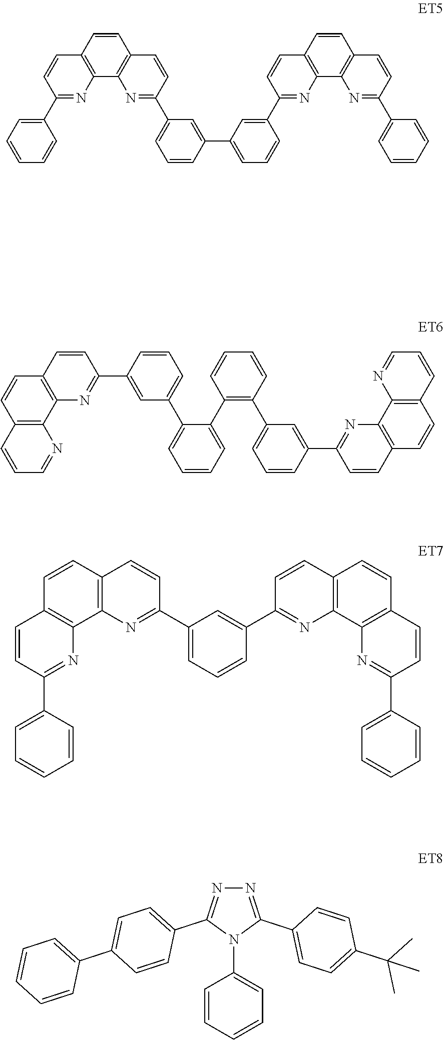 [SMILES: c1ccc(-c2ccc3ccc4ccc(-c5cccc(-c6cccc(-c7ccc8ccc9ccc(-c%10ccccc%10)nc9c8n7)c6)c5)nc4c3n2)cc1 ; c1cc(-c2ccc3ccc4cccnc4c3n2)cc(-c2ccccc2-c2ccccc2-c2cccc(-c3ccc4ccc5cccnc5c4n3)c2)c1 ; c1ccc(-c2ccc3ccc4ccc(-c5cccc(-c6ccc7ccc8ccc(-c9ccccc9)nc8c7n6)c5)nc4c3n2)cc1 ; CC(C)(C)c1ccc(-c2nnc(-c3ccc(-c4ccccc4)cc3)n2-c2ccccc2)cc1]

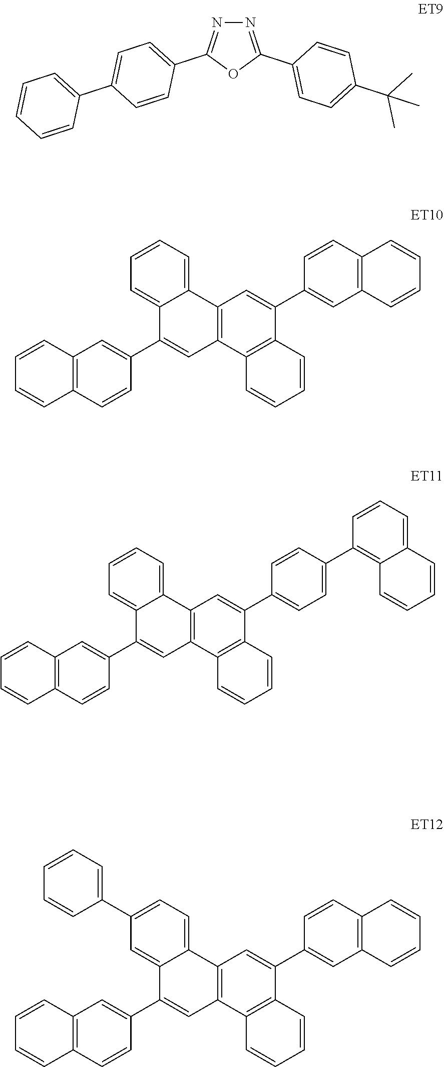

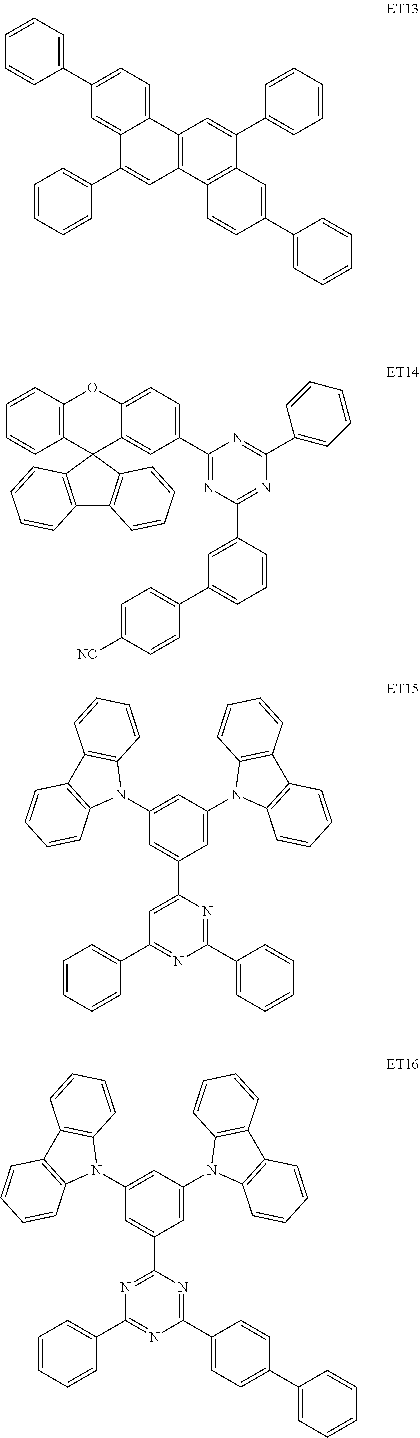

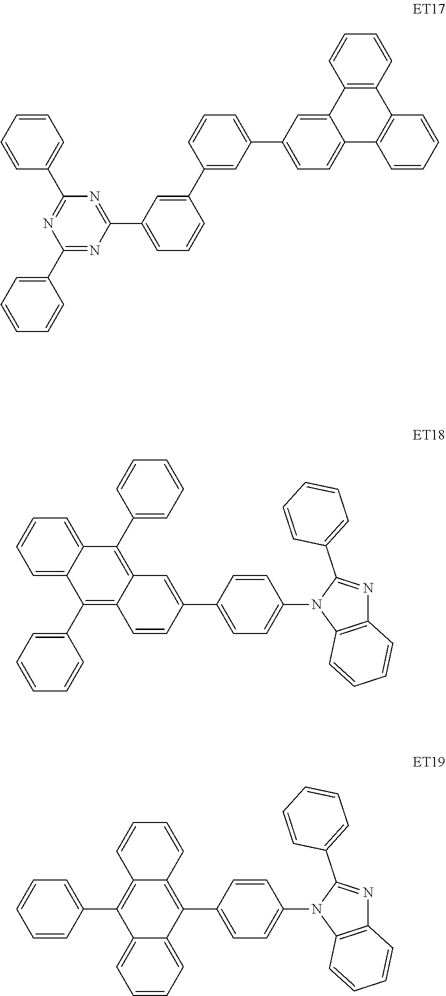 [SMILES: c1ccc(-c2nc(-c3ccccc3)nc(-c3cccc(-c4cccc(-c5ccc6c7ccccc7c7ccccc7c6c5)c4)c3)n2)cc1 ; c1ccc(-c2c3ccccc3c(-c3ccccc3)c3cc(-c4ccc(-n5c(-c6ccccc6)nc6ccccc65)cc4)ccc23)cc1 ; c1ccc(-c2c3ccccc3c(-c3ccc(-n4c(-c5ccccc5)nc5ccccc54)cc3)c3ccccc23)cc1]

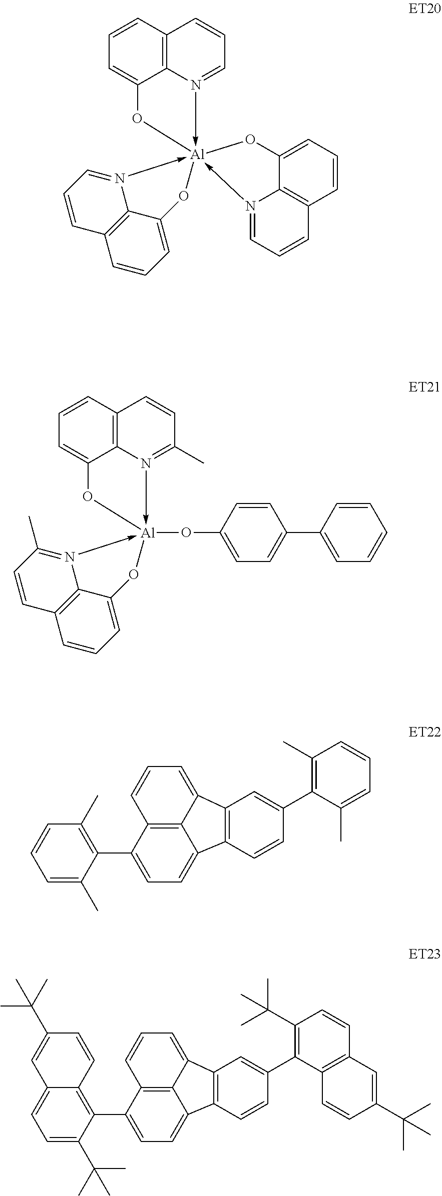

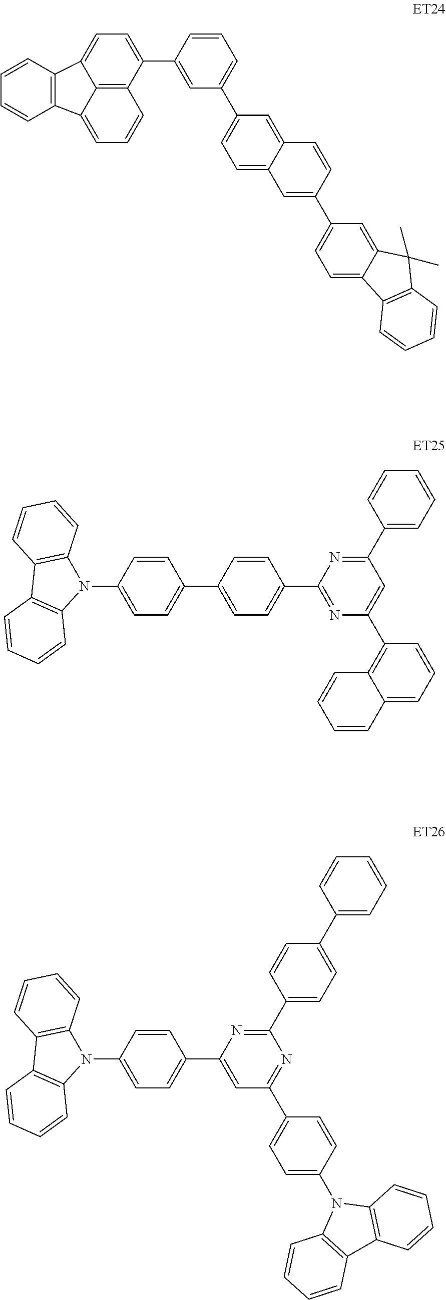

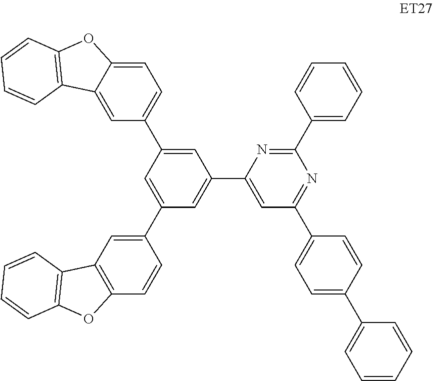 [SMILES: c1ccc(-c2ccc(-c3cc(-c4cc(-c5ccc6oc7ccccc7c6c5)cc(-c5ccc6oc7ccccc7c6c5)c4)nc(-c4ccccc4)n3)cc2)cc1]

The electron injecting material can be selected arbitrarily from the compounds that can facilitate the injection of electrons from the cathode and is selected in view of, for example, the balance with hole injection. The organic compounds also include n-type dopants and reducing dopants. Examples include alkali metal-containing compounds such as lithium fluoride, lithium complexes such as lithium quinolinol, benzoimidazolidene derivatives, imidazolidene derivatives, fulvalene derivatives, and acridine derivatives.

### Structure of Organic Light-Emitting Element

The organic light-emitting element is provided by forming an insulating layer, a first electrode, one or more organic compound layers, and a second electrode on a substrate. A protective layer, a color filter, a microlens, or the like may be provided over the cathode. For the color filter, if provided, a planarizing layer may be disposed between the protective layer and the color filter. The planarizing layer may be made of, for example, acrylic resin. The same applies when a planarizing layer is disposed between the color filter and the microlens.

### Substrate

The substrate may be made of quartz, glass, silicon wafer, resin, metal, or the like. A switching element, such as a transistor, and wires may be arranged on the substrate, and over which an insulating layer is formed. The insulating layer may be made of any material, provided that contact holes can be formed in the insulating layer for wiring to the first electrode, and that insulation can be ensured from wiring lines not being connected. For example, a resin such as polyimide or silicon oxide, silicon nitride, or the like may be used.

### Electrodes

A pair of electrodes may be used as electrodes. The pair of electrodes may be an anode and a cathode. In the organic light-emitting element to which an electric field is applied in the light-emitting direction, the electrode with a higher potential is the anode, and the other is the cathode. Also, the electrode that supplies holes to the luminescent layer is the anode, and the electrode that supplies electrons is the cathode.

The anode is desirably made of a material having as high a work function as possible. Examples of such a material include simple metals, such as gold, platinum, silver, copper, nickel, palladium, cobalt, selenium, vanadium, and tungsten, mixtures containing simple metals or alloys formed by combining those metals, and metal oxides, such as tin oxide, zinc oxide, indium oxide, indium tin oxide (ITO), and zinc indium oxide. Electrically conductive polymers, such as polyaniline, polypyrrole, and polythiophene, may also be used.

These electrode materials may be used individually or in combination. The anode may be composed of a single layer or a plurality of layers.

For a reflection electrode, for example, chromium, aluminum, silver, titanium, tungsten, molybdenum, or an alloy or multilayer composite of these metals may be used. These materials can also function as a reflection film that does not serve as an electrode. For a transparent electrode, an electrically conductive transparent metal oxide layer of, for example, indium tin oxide (ITO) or indium zinc oxide, but not limited to, may be used. Photolithography technology can be used to from the electrodes.

The cathode is desirably made of a material having a low work function. Examples of the cathode material include alkali metals, such as lithium; alkaline-earth metals, such as calcium; other simple metals, such as aluminum, titanium, manganese, silver, lead, and chromium; and mixtures containing these simple metals. Alloys formed by combining these simple metals may be used. Examples of such an alloy include magnesium-silver, aluminum-lithium, aluminum-magnesium, silver-copper, and zinc-silver. A metal oxide, such as indium tin oxide (ITO), may be used. These electrode materials may be used individually or in combination. The cathode may be composed of a single layer or a plurality of layers. Preferably, silver is used, and silver alloy is further preferred because silver alloy reduces the aggregation of silver. Any proportions in the alloy are acceptable as long as the aggregation of silver can be reduced. For example, the ratio of silver to other metals may be 1:1 or 3:1.

The cathode may be defined by, but not limited to, an electrically conductive oxide layer, such as ITO, to provide a top emission element or a reflection electrode, such as aluminum (Al), to provide a bottom emission element. The cathode may be formed by any method without limitation, but direct current or alternating current sputtering is useful for film coverage and reducing resistance.

### Organic Compound Layer

The organic compound layer may be composed of a single layer or a plurality of layers. A plurality of organic compound layers may be called a hole injection layer, a hole transport layer, an electron blocking layer, a luminescent layer, a hole blocking layer, an electron transport layer, and an electron injection layer, depending on the function. The organic compound layer is mainly made of organic compounds but may contain inorganic atoms or inorganic compounds. For example, the organic compound layer may contain copper, lithium, magnesium, aluminum, iridium, platinum, molybdenum, zinc, or the like. The organic compound layer may be disposed between the first electrode and the second electrode and may be disposed in contact with the first and the second electrodes.

### Protective Layer

A protective layer may be provided over the cathode. For example, a glass sheet with a moisture absorbent may be bonded onto the cathode to reduce the penetration of water or the like into the organic compound layer, thus reducing the occurrence of display failure. In another embodiment, a passivation film of silicon nitride or the like may be provided over the cathode to reduce the penetration of water or the like into the organic compound layers. For example, after being formed, the cathode is transported to another chamber with a vacuum maintained, and a 2 μm-thick silicon nitride film may be deposited by CVD, thus obtaining a protective layer. After deposition by CVD, a protective layer may be formed by atomic layer deposition (ALD). The material of the film formed by ALD may be, but is not limited to, silicon nitride, silicon oxide, aluminum oxide, or the like. A silicon nitride film may be further formed by CVD on the film formed by ALD. The thickness of the film formed by ALD may be smaller than the film formed by CVD. Specifically, it may be 50% or less, or even 10% or less.

### Color Filter

A color filter may be provided on the protective layer. For example, a color filter that allows for the size of the organic light-emitting element may be provided on another substrate, and the color filter and the substrate provided with the organic light-emitting element are bonded together. Alternatively, the color filter may be patterned on the protective layer described above by photolithography technology. The color filter may be made of a polymer.

### Planarizing Layer

A planarizing Layer may be disposed between the color filter and the protective layer. The planarizing layer is intended to reduce the unevenness of the underlying layer. Such a layer may be called a material resin layer when its purpose is not limited. The planarizing layer may be made of an organic compound, which may be low molecular weight or polymeric but is preferably polymeric.

Planarizing layers may be provided on each of the upper and lower side of the color filter, and their material may be the same or different. Examples include polyvinylcarbazole resin, polycarbonate resin, polyester resin, ABS resin, acrylic resin, polyimide resin, phenol resin, epoxy resin, silicone resin, and urea resin.

### Microlens

The organic light-emitting device may include an optical member, such as a microlens, on the light emitting side. The microlens may be made of acrylic resin, epoxy resin, or the like. The microlens may be used to increase the amount of light extracted from the organic light-emitting device and to control the direction of the extracted light. The microlens may have a hemispherical shape. For a hemispherical microlens, the apex of the microlens is the contact point of the tangent line parallel to the insulating layer, among the tangent lines of the hemisphere, with the hemisphere. The apex of the microlens can be determined in the same manner in any sectional view. More specifically, in a sectional view of a microlens, the contact point of the tangent line of the hemisphere parallel to the insulating layer, among the tangent lines of the microlens, with the hemisphere is the apex of the microlens.

Also, the midpoint of the microlens can be defined. In a cross-section of microlenses, the midpoint of an imaginary line segment from the point where an arc shape ends to the point where another arc shape ends can be called the midpoint of a microlens. The cross-section to determine the apex and the midpoint may be a cross-section perpendicular to the insulating layer.

### Opposing Substrate

An opposing substrate may be disposed on the planarizing layer. The opposing substrate is located opposing the foregoing substrate and is, therefore, called the opposing substrate. The opposing substrate may be made of the same material as the foregoing substrate. When the foregoing substrate is a first substrate, the opposing substrate may be a second substrate.

Organic compound Layer(s)

The organic compound layers (hole injection layer, hole transport layer, electron blocking layer, luminescent layer, electron blocking layer, luminescent layer, hole blocking layer, electron transport layer, electron injection layer, etc.) of the organic light-emitting element according to an embodiment of the present disclosure are formed by the following process.

The organic compound layers of the organic light-emitting element according to an embodiment of the present disclosure can be formed in a dry process, such as vacuum deposition, ionized deposition, sputtering, or using plasma. As an alternative to the dry process, a wet process may be applied in which layers are formed by a known coating of a material dissolved in an appropriate solvent (e.g., spin coating, dipping, casting method, LB method, or ink jet method.

Layers formed by vacuum deposition, solution coating, or the like are less likely to crystallize and thus stable over time. When a layer is formed by coating, an appropriate binder resin may be combined.

Examples of the binder resin include, but are not limited to, polyvinylcarbazole resin, polycarbonate resin, polyester resin, ABS resin, acrylic resin, polyimide resin, phenol resin, epoxy resin, silicone resin, and urea resin.

Such a binder resin may be used individually as a homopolymer or a copolymer, or two or more resins may be mixed. Other known additives, such as a plasticizer, an antioxidant, and an ultraviolet light adsorbent, may further be used if necessary.

### Pixel Circuit

A light-emitting device may include a pixel circuit connected to the light-emitting element. The pixel circuit may be a type of active matrix that independently controls a first light-emitting element and a second light-emitting element for emission. The active matrix circuit may be controlled by either voltage programming or current programming. The driving circuit includes a pixel circuit for each pixel. The pixel circuit may include a transistor to control the light-emitting element and the luminance of emission from the light-emitting element, a transistor to control emission timing, a capacitor to hold the gate voltage of the transistor to control the luminance of emission, and a transistor for connection to the GND but not via the light-emitting element.

The light-emitting device includes a display region and a peripheral region around the display region. The display region has pixel circuits, and the peripheral region has a display control circuit. In the transistor of the pixel circuit, the mobility may be lower than that in the transistor of the display control circuit.

The transistor of the pixel circuit may have current-voltage characteristics with a smaller slope than the transistor of the display control circuit. The slope of current-voltage characteristics can be measured using what is called Vg-Ig characteristics.

The transistor of the pixel circuit is the transistor connected to a light-emitting element, such as a first light-emitting element.

### Pixel

The organic light-emitting device has a plurality of pixels. Each pixel includes sub-pixels that emit different colors from each other. Sub-pixels may have their respective RGB emission colors.

The pixels emit light from a region called a pixel aperture. This region is the same as a first region. The pixel aperture may be 15 μm or less and may be 5 μm or more. More specifically, it may be 11 μm, 9.5 μm, 7.4 μm, 6.4 μm, and so forth.

The distance between adjacent sub-pixels may be 10 μm or less, for example, 8 μm, 7.4 μm, or 6.4 μm.

The pixels may be arranged in a known array in plan view. For example, the pixels may be arranged in striped array, a delta array, pentile array, or a Bayer array. The sub-pixels may have any known shape in plan view. For example, the shape may be quadrilateral, such as rectangular or rhombic, hexagonal, and so forth. Of course, the shape may not be an exact figure, and, for example, a shape close to a rectangle is considered rectangular. The shape of sub-pixels and the pixel arrangement may be combined.

Applications of Organic Light-Emitting Element According to an Embodiment of the Disclosure

The organic light-emitting element according to an embodiment of the present disclosure may be used as a member of a display device or a lighting device. In addition, the organic light-emitting element may be used as an exposure light source of an electrophotographic image forming apparatus, a backlight of a liquid crystal display device, or a light-emitting device including a white light source provided with a color filter.

The display device may be used in an image information processing apparatus that includes an image input section to which image information is input from an area CCD, a linear CCD, a memory card, or the like and an information processing section in which the inputted information is processed, and a display section on which the inputted information is displayed.

The display section of an imaging device or an ink jet printer may have a function as a touch panel. The touch panel function may be operated by, but not limited to, using infrared, a capacitive scheme, a resistive film, or electromagnetic induction. Also, the display device may be used as a display section of a multifunctional printer.

The display device disclosed herein will now be described with reference to drawings.

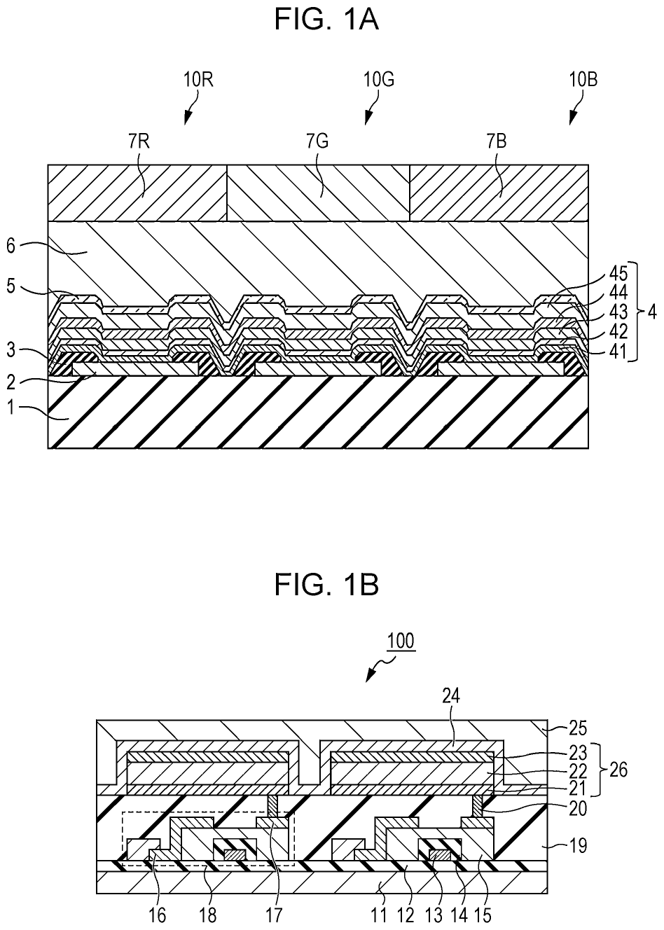

FIGS. 1A and 1B are each a schematic sectional view of a display device including organic light-emitting elements and transistors connected to the respective organic light-emitting elements. The transistors are an example of active elements. The transistors may be thin-film transistors (TFTs).

FIG. 1A depicts an example of a pixel that is a component of the display device in an implementation of the present disclosure. The pixel includes sub-pixels 10. The sub-pixels are categorized into 10R, 10G, and 10B depending on the emission color. Emission colors may be identified by the wavelength of the light emitted from the luminescent layer, or color filters may selectively transmit the light emitted from the sub-pixels or convert the color of the light. Each sub-pixel includes, on an interlayer insulating layer 1, a reflection electrode 2, which is a first electrode, an insulating layer 3 covering the edge of the reflection electrode 2, an organic compound layer 4 covering the first electrode and the insulating layer, a transparent electrode 5, a protective layer 6, and a color filter 7.

Transistors and capacitor elements may be disposed under or within the interlayer insulating layer 1. The transistors and the respective first electrodes may be electrically coupled through a contact hole (not shown) or the like.

The insulating layer 3 is also called a bank or pixel isolation film. The insulating layer covers the edges of the first electrodes and surrounds the first electrodes. The portion of the first electrode not covered with the insulating layer is in contact with the organic layer 4 to act as a light-emitting region.

The organic compound layer 4 includes a hole injection layer 41, a hole transport layer 42, a first luminescent layer 43, a second luminescent layer 44, and an electron transport layer 45.

The second electrode 5 may be transparent, reflective, or semitransparent.

The protective layer 6 reduces water permeation into the organic compound layer. The protective layer, which is illustrated as a single layer, may include a plurality of layers. Each layer may include an inorganic compound layer or an organic compound layer.

Color filters 7 are categorized into 7R, 7G, and 7B depending on the color. The color filters may be formed on a planarizing layer (not shown). Also, the color filters may be provided with a resin protective layer (not shown) over the color filters. The color filters may be formed on the protective layer 6. The color filters may be formed on an opposing substrate, which may be a glass substrate or the like, and then bonded.

In the display device 100 depicted in FIG. 1B, organic light-emitting elements 26 and TFTs 18, as an example of transistors, are illustrated. A substrate 11 made of glass, silicon, or the like and an insulating layer 12 over the substrate are provided. Active elements 18, such as TFTs, are arranged on the insulating layer. In each active element, a gate electrode 13, a gate insulating film 14, and a semiconductor layer 15 are disposed. The TFT 18 further includes a semiconductor layer 15, a drain electrode 16, and a source electrode 17. An insulating film 19 is provided over the TFTs 18. The source electrode 17 is connected to the anode 21 of the corresponding organic light-emitting element 26 through a contact hole 20 formed in the insulating film.

The electrical coupling between the electrode (anode or cathode) of the organic light-emitting element 26 and the electrode (source electrode or drain electrode) of the TFT is not limited to the manner illustrated in FIG. 1B. In other words, either the anode or the cathode is electrically coupled to either the source electrode or drain electrode of the TFT. A TFT refers to a thin film transistor.

Although the display device 100 depicted in FIG. 1B is illustrated as if it had only one organic compound layer, the organic compound layer 22 may have a plurality of layers. A first protective layer 24 and a second protective layer 25 are disposed over the cathodes 23 to reduce the deterioration of the organic light-emitting elements.

Although the display device 100 depicted in FIG. 1B uses transistors as switching elements, other switching elements may be used instead of transistors.

The transistors of the display device 100 depicted in FIG. 1B are not limited to the transistors using a monocrystalline silicon wafer and may be thin film transistors including an active layer on the insulating surface of a substrate. The active layer may be made of monocrystalline silicon, non-monocrystalline silicon, such as amorphous silicon or microcrystalline silicon, or a non-monocrystalline oxide semiconductor, such as indium zinc oxide or indium gallium zinc oxide. Thin film transistors are also referred to as TFT elements.

The transistors in the display device 100 depicted in FIG. 1B may be formed within a substrate such as a Si substrate. To be formed in the substrate implies that the transistors are formed by working the substrate. In other words, transistors formed in a substrate implies that the substrate and the transistors are formed in one body.

In an embodiment, the organic light-emitting element may be used to display images. In this embodiment, the luminance of the emission from the organic light-emitting element is controlled by a TFT, which is an example of switching elements, and a plurality of such organic light-emitting elements are arranged in a plane so that the emission luminance of the organic light-emitting elements is involved in displaying images. In the implementation of the present disclosure, the switching element is not limited to a TFT and may be a transistor made of a low-temperature polysilicon or an active matrix driver on a substrate such as a Si substrate. The phrase “on a substrate” may also mean within the substrate. Whether providing transistors within a substrate or using TFTs depends on the size of the display section. For example, in the case of about 0.5 inch in size, providing organic light-emitting elements on a silicon substrate is preferred.

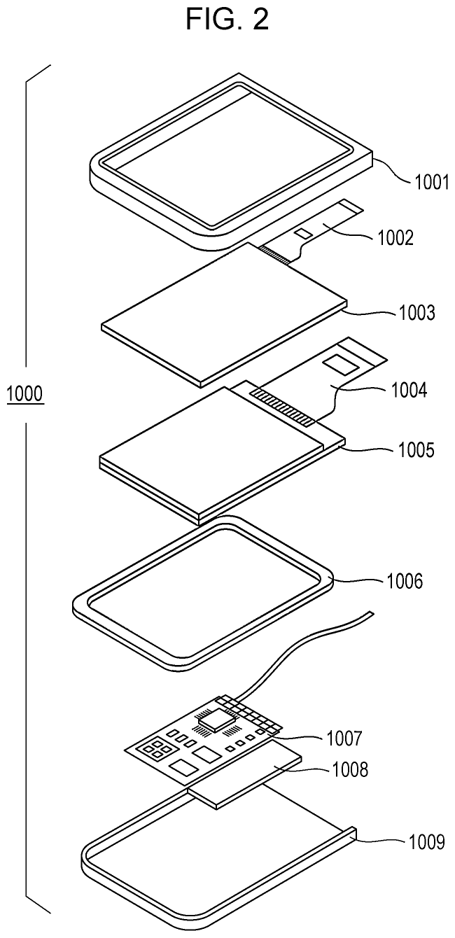

FIG. 2 is a schematic illustrative representation of a display device according to an embodiment of the present disclosure. The display device 1000 may include a touch panel 1003, a display panel 1005, a frame 1006, a circuit board 1007, and a battery 1008 between an upper cover 1001 and a lower cover 1009. The touch panel 1003 and the display panel 1005 are connected to flexible printed circuits FPCs 1002 and 1004, respectively. Transistors are printed on the circuit board 1007. The battery 1008 is not necessarily provided unless the display device is for mobile use, and, for mobile use, the battery may be located in another position.

In an embodiment, the display device may include red, green, and blue color filters. The red, green, and blue color filters may be arranged in a delta array.

In an embodiment, the display device may be used in the display section of a mobile terminal. In this instance, the display device may have both a displaying function and an operational function. The mobile terminal may be a cellular phone, such as a smartphone, a tablet PC, a head-mounted display, or the like.

In an embodiment, the display device may be used as a display section of an imaging device including an optical system having a plurality of lenses and an imaging element to receive light that has passed through the optical system.

The imaging device may have a display section on which information obtained by the imaging element is displayed. The display section may be exposed to the outside of the imaging device or may be disposed within a finder. The imaging device may be a digital camera or a digital video camera.

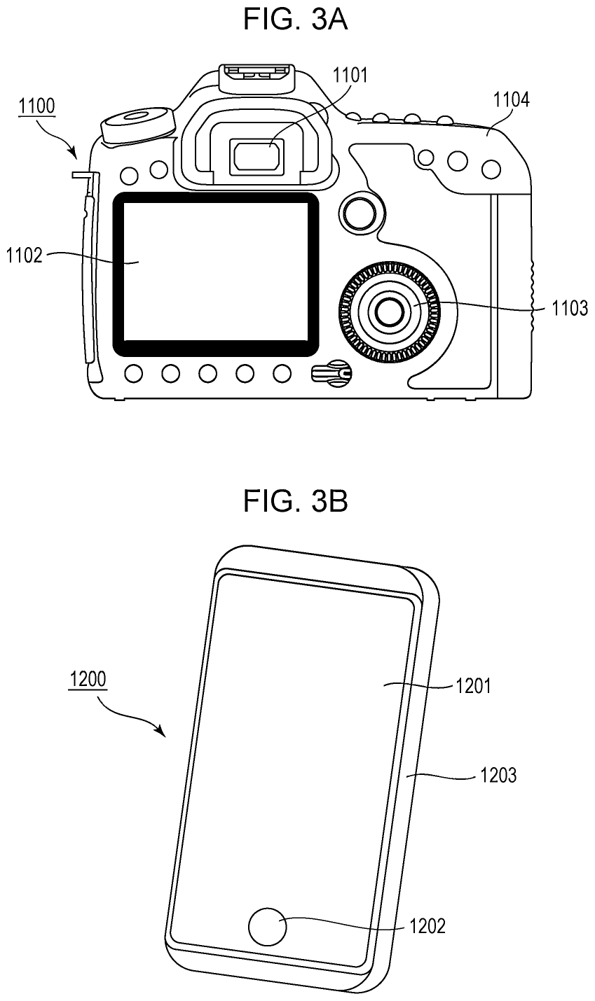

FIG. 3A is a schematic illustrative representation of an imaging device according to an embodiment of the present disclosure. The imaging device 1100 may include a viewfinder 1101, a rear display 1102, an operational section 1103, and a housing 1104. The viewfinder 1101 may include the display device according to an embodiment of the present disclosure. In this instance, the display device may display not only images to be taken but also environmental information, imaging instructions, or the like. The environmental information may include the intensity and the direction of external light, the speed at which the subject moves, and the possibility that an object hides the subject.

Since the appropriate timing for taking an image is only a short period, it is desirable to display information as quickly as possible. Accordingly, the display device using the organic light-emitting elements of the present disclosure is preferred. This is because the organic light-emitting elements respond quickly. The display device using the organic light-emitting elements is more suitably used than liquid crystal display devices in apparatuses required to display information quickly.

The imaging device 1100 includes an optical system (not shown). The optical system includes a plurality of lenses and forms an image on the imaging element in the housing 1104. The focus can be adjusted by adjusting the relative positions of the plurality of lenses. This may be automatically performed. The imaging device may be called a photoelectric conversion device.

The photoelectric conversion device may take images by a method of detecting differences from the previous image or cutting an image out of images continuously recorded instead of sequentially taking images.

FIG. 3B is a schematic illustrative representation of an electronic apparatus according to an embodiment of the present disclosure. The electronic apparatus 1200 includes a display section 1201, an operational section 1202, and a housing 1203. The housing 1203 may contain a circuit, a printed board having the circuit, a battery, and a communication section. The operational section 1202 may be a button or a touch panel responder. The operational section may have a biometrically authenticating function of recognizing the fingerprint and releasing the lock. An electronic apparatus including a communication section may be referred to as a communication apparatus. The electronic apparatus may further include a lens and an imaging element to function as a camera. Images taken by the function as a camera are displayed on the display section. Such electronic apparatuses include smartphones and laptop PCs.

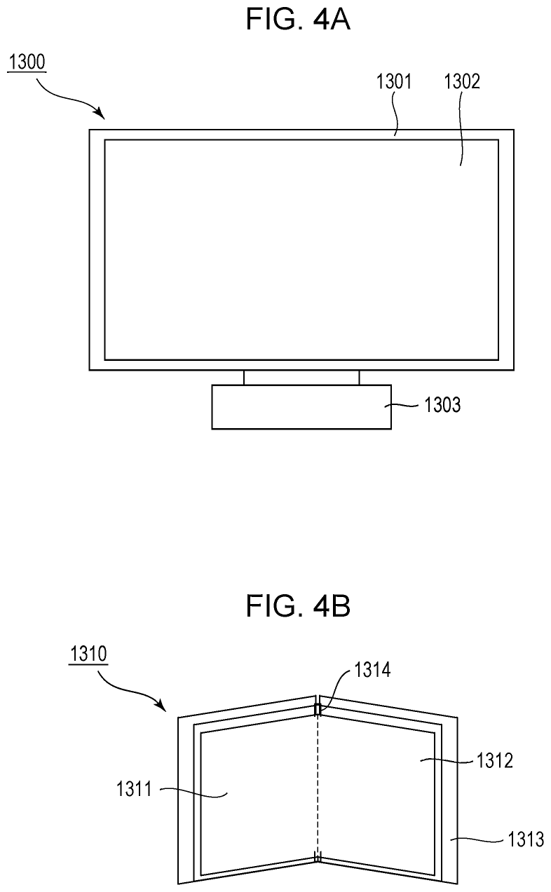

FIGS. 4A and 4B are each a schematic illustrative representation of a display device according to an embodiment of the present disclosure. FIG. 4A illustrates a display device such as a TV monitor or a PC monitor. The display device 1300 includes a frame 1301 and a display section 1302. The display section 1302 may include the light-emitting device according to an embodiment of the present disclosure.

The display device also includes a frame 1301 and a base 1303 supporting the display section 1302. The base 1303 is not limited to the form illustrated in FIG. 4A. The lower side of the frame 1301 may serve as the base.

The frame 1301 and the display section 1302 may be curved. The radius of curvature may be 5000 mm to 6000 mm.

FIG. 4B is a schematic illustrative representation of a display device according to another embodiment of the present disclosure. The display device 1310 depicted in FIG. 4B is foldable and is, thus, what is called a foldable display device. The display device 1310 includes a first display section 1311, a second display section 1312, and a housing 1313 and has a folding line 1314. The first display section 1311 and the second display section 1312 each may include the light-emitting device according to an embodiment of the present disclosure. The first display section 1311 and the second display section 1312 may constitute a seamless one-piece display device. The first display section 1311 and the second display section 1312 can be separated from each other along the folding line. The first display section 1311 and the second display section 1312 may display different images from each other, or a single image may be displayed on a set of the first and second display sections.

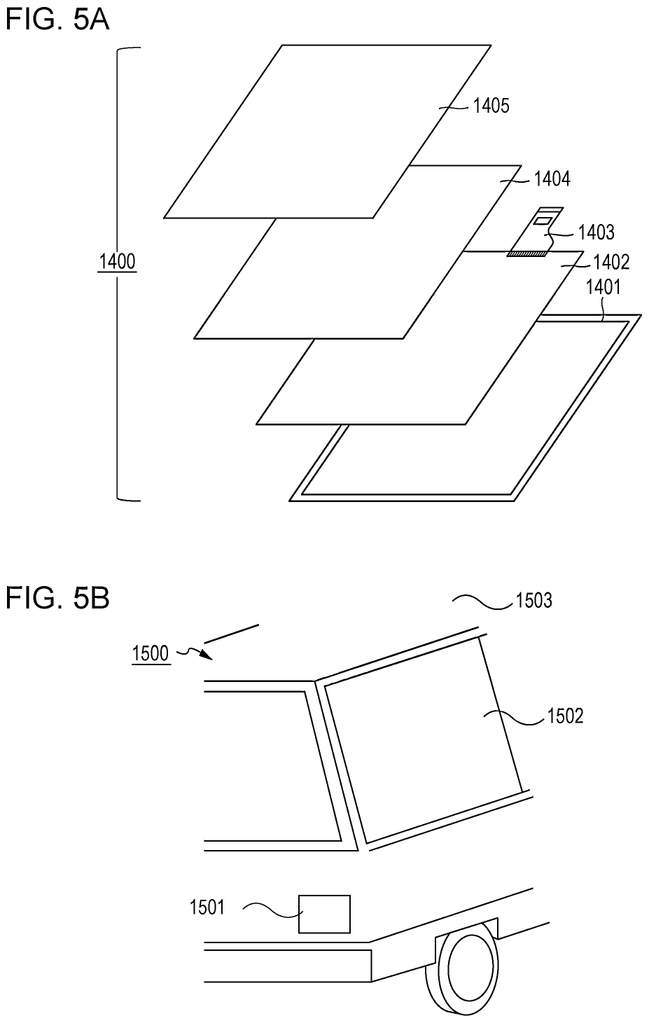

FIG. 5A is a schematic illustrative representation of a lighting device according to an embodiment of the present disclosure. The lighting device 1400 may include a housing 1401, a light source 1402, a circuit board 1403, an optical film 1404, and a light diffusing section 1405. The light source may include the organic light-emitting element according to an embodiment of the present disclosure. The optical filter may be a filter to improve the color rendering properties of the light source. The light diffusing section diffuses light emitted from the light source effectively so that the light reaches a wide area for, for example, lighting up. The optical filter and the light diffusing section may be disposed on the light emitting side of lighting. A cover may be provided at an outermost portion.

The lighting device illuminates, for example, a room. The lighting device may emit light of cool white, sunshine color, or any other color from blue to red. The lighting device may include a dimmer circuit that dims the light. The lighting device may include the organic luminescent element of the present disclosure and a power supply circuit connected to the organic luminescent element. The power supply circuit converts alternating voltage to direct voltage. Cool white has a color temperature of 4200 K and sunshine color has a color temperature of 5000 K. The lighting device may include a color filter.

The lighting device according to an embodiment of the present disclosure may include a heat radiation section. The heat radiation section is intended to dissipate heat from the device to the outside and may be made of, for example, a metal having a high specific heat or liquid silicon.

FIG. 5B is a schematic illustrative representation of an automobile that is an implementation of the movable apparatus according to an embodiment of the present disclosure. The automobile has a tail lamp that is an example of lighting fixtures. The automobile 1500 has a tail lamp 1501, and the tail lamp may be such that it turns on when braking operation or the like is performed.

The tail lamp 1501 may include the organic light-emitting element according to an embodiment of the present disclosure. The tail lamp may include a protective member that protects the organic EL element. Although the protective member may be made of any material provided that it has a certain degree of high strength and is transparent, polycarbonate or the like is preferred. The polycarbonate may be mixed with a furandicarboxylic acid derivative, an acrylonitrile derivative, or the like.

The automobile 1500 may include a car body 1503 and a window 1502 attached to the car body. The window may be a transparent display unless it is intended to be used to check the front and rear of the automobile. The transparent display may include the organic light-emitting element according to an embodiment of the present disclosure. In this instance, the members such as electrodes of the organic light-emitting element are made of transparent materials.

In an embodiment, the movable apparatus may be a ship, an aircraft, a drone, or the like. The movable apparatus may include an apparatus body and a lighting fixture provided at the apparatus body. The lighting fixture may emit light to notify the position of the apparatus body. The lighting fixture includes the organic light-emitting element according to an embodiment of the present disclosure.

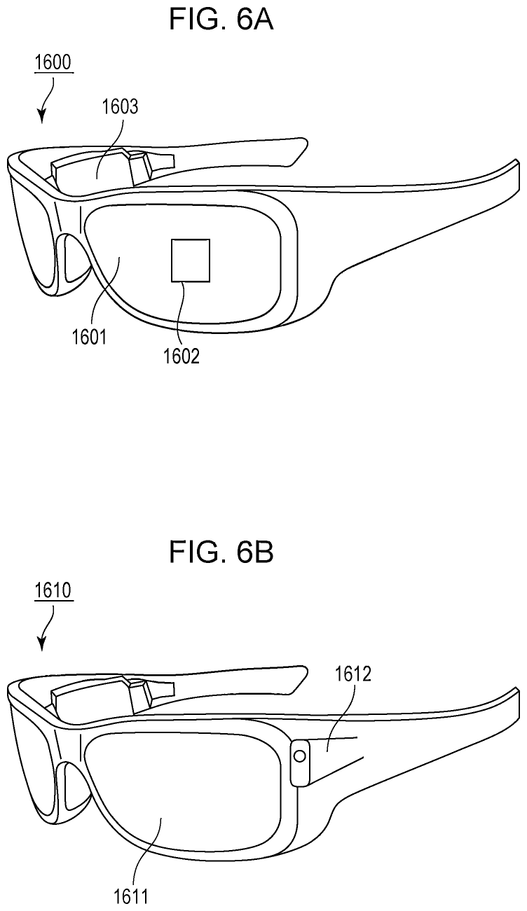

Examples of the application of the display device according to the above embodiments will now be described with reference to FIGS. 6A and 6B. The display device may be applied to systems that can be worn as a wearable device, such as smart glasses, an HMD, or smart contact lenses. An imaging display device used in such an application includes an imaging device capable of photoelectrically converting visible light and a display device capable of emitting visible light.

FIG. 6A illustrates glasses 1600 (smart glasses) according to an application. The glasses 1600 is provided with an imaging device 1602, such as a CMOS sensor or a SPAD, on the front surface of the lenses 1601. Also, a display device according to an embodiment described above is provided on the rear surface of the lenses 1601.

The glasses 1600 further include a controller 1603. The controller 1603 functions as a power supply to supply power to the imaging device 1602 and the display device according to an embodiment. The controller 1603 also controls the operations of the imaging device 1602 and the display device. In the lenses 1601, an optical system is formed to focus light on the imaging device 1602.

FIG. 6B illustrates glasses 1610 (smart glasses) according to an application. The glasses 1610 include a controller 1612, and the controller 1612 includes an imaging device corresponding to the imaging device 1602 and a display device. In the lenses 1611, an optical system for projecting light emitted from the controller 1612 is formed, and images are projected on the lenses 1611. The controller 1612 functions as a power supply to supply power to the imaging device and the display device and also controls the operations of the imaging device and the display device. The controller may have a sight line detector that detects the wearer's line of sight. Infrared light may be used to detect the line of sight. An infrared emission section emits infrared light to an eyeball of the user gazing at the displayed image. An imaging section with a light receiving element detects the reflection of emitted infrared light from the eyeball, thus obtaining a captured image of the eyeball. The deterioration of image quality is reduced by providing a reducing means that reduces the light in plan view to the display section from the infrared emission section.

The user's line of sight to the displayed image is detected from the captured image of the eyeball obtained by capturing the infrared light. Known techniques can be applied to detect the line of sight using a captured image of the eyeball. For example, a sight line detection method based on the Purkinje image formed by the reflection of irradiation light at the cornea can be used.

More specifically, sight line detection is performed based on pupil center corneal reflection. The sight line vector representing the direction (rotation angle) of the eyeball is calculated based on the image of the pupil and the Purkinje image included in the captured image of the eyeball, using pupil center corneal reflection, thus detecting the user's line of sight.

In an embodiment of the present disclosure, the display device may include an imaging device having a light receiving element, and the image displayed on the display device may be controlled based on the user's line-of-sight information from the imaging device.

More specifically, the display device determines a first view field area at which the user gazes and a second view field area other than the first view field area based on the line-of-sight information. The first view field area and the second view field area may be determined by the controller of the display device, or the display device may receive those determined by an external controller. In the display region of the display device, the display resolution of the first view field area may be controlled to be higher than that of the second view field area. In other words, the resolution of the second view field area may be lower than that of the first view field area.

Also, the display region includes a first display area and a second display area different from the first display area, and the area with higher priority is determined from the first and second display areas based on the line-of-sight information. The first view field area and the second view field area may be determined by the controller of the display device, or the display device may receive those determined by an external controller. The resolution of the area taking priority may be controlled to be higher than that of the other area. In other words, the resolution may be lowered for the area with relatively low priority.

The first view field area or the area with higher priority may be determined using AI. The AI may be a model configured to estimate the angle of the line of sight from the image of the eyeball and the distance to an object beyond the line of sight, using as teacher data the image of the eyeball and the direction of the actual eyeball look. The AI program may be contained in the display device, the imaging device, or an external device. When contained in an external device, the program is transmitted to the display device using communication.

For display control based on visual detection, smart glasses further including an imaging device that takes external images are useful. The smart glasses can display information about external images taken in real time.

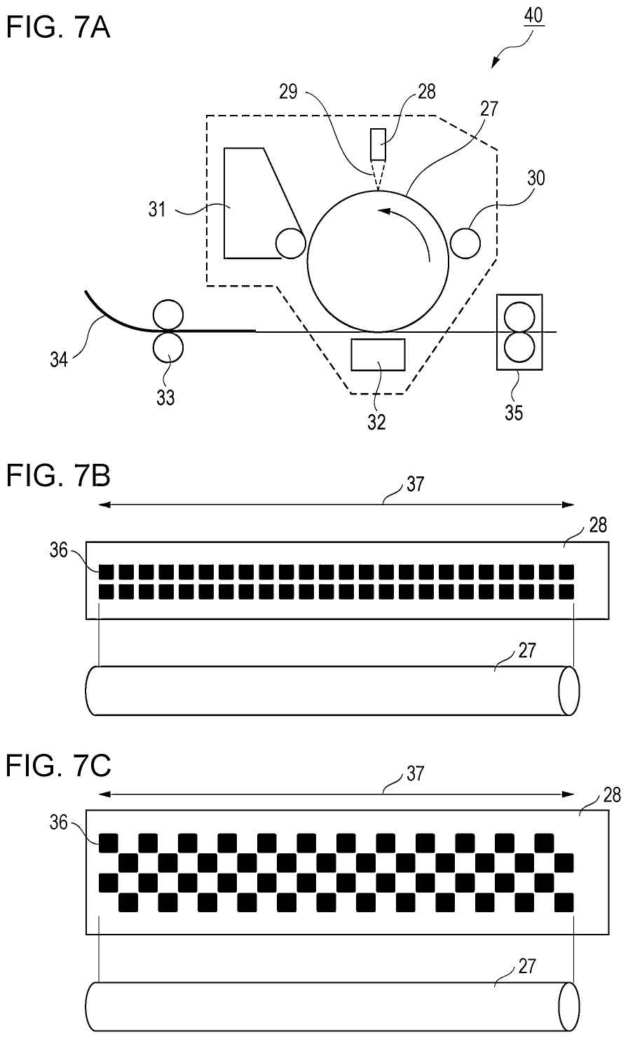

FIG. 7A is a schematic illustrative representation of an image forming apparatus according to an embodiment of the present disclosure. The image forming apparatus 40, which is an electrophotographic image forming apparatus, includes a photosensitive member 27, an exposure light source 28, a charging section 30, a developing section 31, a transfer device 32, conveying rollers 33, and a fuser 35. The exposure light source 28 emits light 29 to form an electrostatic latent image on the surface of the photosensitive member 27. The exposure light source 28 includes the organic light-emitting element according to an embodiment of the present disclosure. The developing section 31 contains a toner or the like. The charging section 30 charges the photosensitive member 27. The transfer device 32 transfers developed images to a recording medium 34. The conveying rollers 33 convey the recording medium 34. The recording medium 34 is, for example, a paper sheet. The fuser 35 fixes the image formed on the recording medium 34.

FIGS. 7B and 7C are each a schematic illustrative representation of the exposure light sources 28 having emitting portions 36 arranged on a long substrate. Arrows 37 each indicate the row direction in which organic light-emitting elements are arranged. The row direction is the same as the direction of the rotation axis of the photosensitive member 27. This direction can be called the longitudinal axis direction of the photosensitive member 27. FIG. 7B illustrates a form in which the emitting portions 36 are arranged along the longitudinal direction of the photosensitive member 27. FIG. 7C illustrates a form different from the form in FIG. 7B, in which the emitting portions 36 are arranged alternately in the row direction between the first and second rows. The emitting portions in the first rows and those in the second rows are at different positions in the column direction. In the first rows, the emitting portions 36 are aligned at intervals. In the second rows, the emitting portions 36 are placed at positions corresponding to the spaces between the emitting portions 36 in the first rows. Thus, the emitting portions 36 are arranged at intervals also in the column direction. The arrangement in FIG. 7C can be rephrased as, for example, a lattice arrangement, a staggered arrangement, or a checkerboard pattern.

As described above, the device including the organic light-emitting elements according to an embodiment of the present disclosure can display high-quality images stably in long-time displaying.

### EXAMPLES

The present disclosure will be further described with reference to Examples below. It should be appreciated that the invention is not limited to the following Examples.

### Example 1 (Synthesis of Exemplified Compound C-1)

Exemplified Compound C-1 was synthesized according to the following scheme:

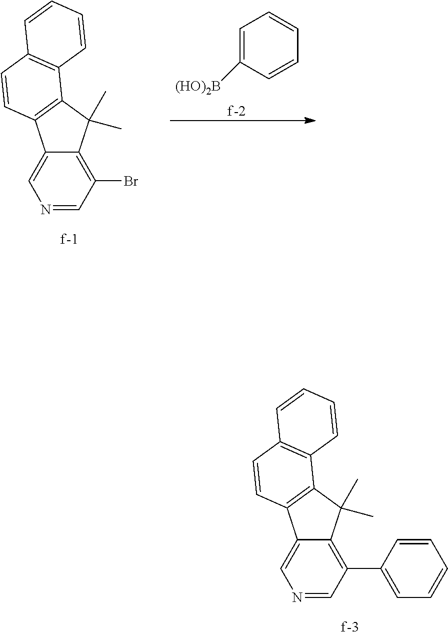

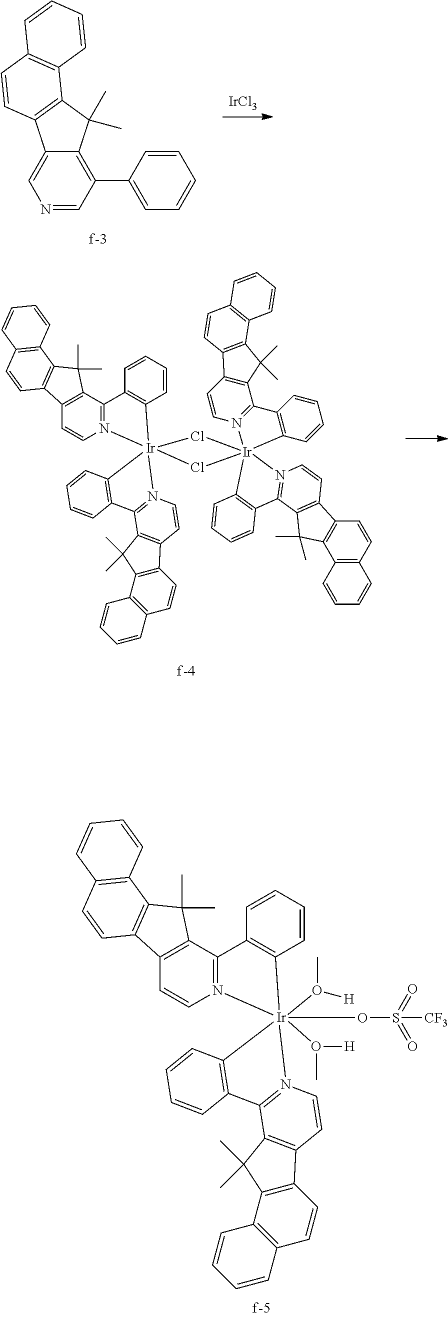

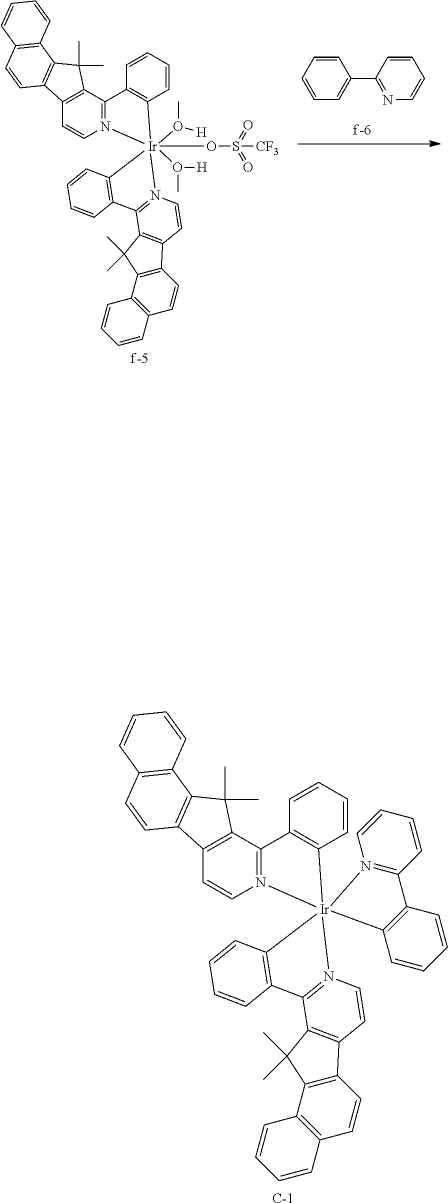

### (1) Synthesis of Compound f-3

The following reagents and solvents presented below were placed into a 200 mL recovery flask.
Compound f-1:6.46 g (20.0 mmol)
Compound f-2:2.27 g (20.0 mmol)
Sodium carbonate: 5.3 g (50.0 mmol)
Pd(PPh₃)₄:578 mg
Toluene: 90 mL
Water: 35 mL
Ethanol: 10 mL

The reaction solution was then heated, refluxed, and stirred for 10 hours under a nitrogen stream. After completion of the reaction, the product was extracted with toluene, and the organic phase was concentrated to dryness. The resulting solid was purified by silica gel column chromatography (mixture of toluene and ethyl acetate) to afford 0.77 g (yield: 12%) of clear solid (f-3).

### (2) Synthesis of Compound f-4

The following reagents and solvents presented below were placed into a 50 mL recovery flask.
Compound f-3:3.21 g (10.0 mmol)
Iridium chloride hydrate: 0.80 g
Ethoxyethanol: 15 mL
Water: 5 mL

The reaction solution was then heated and stirred at 130° C. for 5 hours under a nitrogen stream. After completion of the reaction, the reaction solution was filtered, and the resulting solid was rinsed on the filter with water and methanol. Thus, 1.9 of yellow solid (f-4) was obtained.

### (3) Synthesis of Compound f-5

The following reagents and solvents presented below were placed into a 100 mL recovery flask.
Compound f-5:1.74 g (1.00 mmol)
Silver triflate: 0.514 g (2.00 mmol)
Methylene chloride: 30 mL
Methanol: 1.3 mL

The reaction solution was then heated and stirred at room temperature for 6 hours under a nitrogen stream. After completion of the reaction, the solvent of the reaction solution was removed at 40° C. Thus, 1.85 g of yellowish brown solid (f-5) was obtained.

### (4) Synthesis of Exemplified Compound C-1

The following reagents and solvent presented below were placed into a 100 mL recovery flask.
Compound f-5:1.20 g
Compound f-3:0.16 g (1.00 mmol)
Ethanol: 60 mL

The reaction solution was then heated and stirred at 90° C. for 5 hours under a nitrogen stream. After completion of the reaction, the reaction solution was filtered, and the resulting solid was rinsed on the filter with water and methanol. The resulting solid was purified by silica gel column chromatography (mixture of toluene and ethyl acetate) to afford 0.28 g (yield: 28%) of yellow solid (Exemplified Compound C-1).

Exemplified compound C-1 was subjected to mass spectrometry using MALDI-TOF-MS (Autoflex LRF manufactured by Bruker).

MALDI-TOF-MS

Measured value: m/z=987, Calculation value: C₅₉H₄₄IrN₃=987

### Examples 2 to 21 (Synthesis of Exemplified Compounds)

Exemplified compounds of Examples 2 to 21 presented in Table 3 were synthesized in the same manner as in Example 1, except for replacing raw materials f-1, f-2, and f-6 used in Example 1 with raw materials 1, 2, and 3, respectively. The measured values m/z of the mass spectrometry results obtained in the same manner as in Example 1 are also presented.

TABLE 3

| | Exemplified | | | | |
|---|---|---|---|---|---|
| Example | compound | Raw material 1 | Raw material 2 | Raw material 3 | m/z |
| 2 | C-3 | 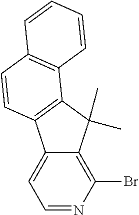 [SMILES: CC1(C)c2c(ccnc2Br)-c2ccc3ccccc3c21] | 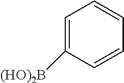 | 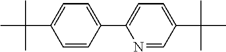 [SMILES: CC(C)(C)c1ccc(-c2ccc(C(C)(C)C)cn2)cc1] | 1099 |
| 3 | C-22 | 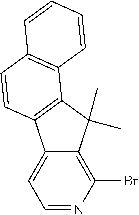 [SMILES: CC1(C)c2c(ccnc2Br)-c2ccc3ccccc3c21] | 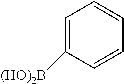 | 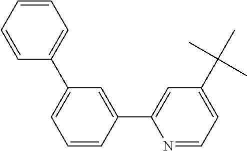 [SMILES: CC(C)(C)c1ccnc(-c2cccc(-c3ccccc3)c2)c1] | 1119 |
| 4 | C-28 | 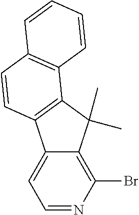 [SMILES: CC1(C)c2c(ccnc2Br)-c2ccc3ccccc3c21] | 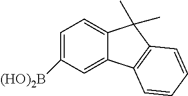 [SMILES: CC1(C)c2ccccc2-c2cc(B(O)O)ccc21] | 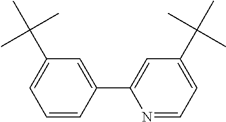 [SMILES: CC(C)(C)c1cccc(-c2cc(C(C)(C)C)ccn2)c1] | 1332 |
| 5 | D-1 | 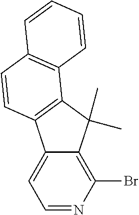 [SMILES: CC1(C)c2c(ccnc2Br)-c2ccc3ccccc3c21] | 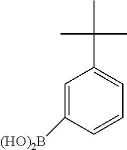 | 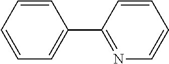 [SMILES: c1ccc(-c2ccccn2)cc1] | 1099 |
| 6 | D-2 | 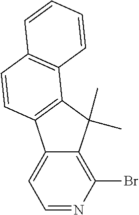 [SMILES: CC1(C)c2c(ccnc2Br)-c2ccc3ccccc3c21] | 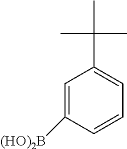 | 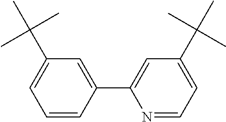 [SMILES: CC(C)(C)c1cccc(-c2cc(C(C)(C)C)ccn2)c1] | 1221 |
| 7 | D-10 | 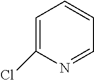 | 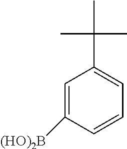 | 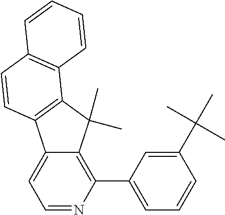 [SMILES: CC(C)(C)c1cccc(-c2nccc3c2C(C)(C)c2c-3ccc3ccccc23)c1] | 989 |
| 8 | D-18 | 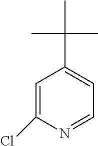 | 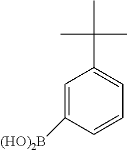 | 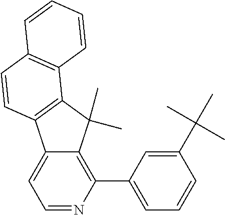 [SMILES: CC(C)(C)c1cccc(-c2nccc3c2C(C)(C)c2c-3ccc3ccccc23)c1] | 1101 |
| 9 | E-1 | 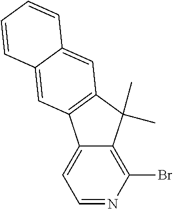 [SMILES: CC1(C)c2cc3ccccc3cc2-c2ccnc(Br)c21] | 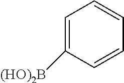 | 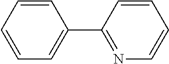 [SMILES: c1ccc(-c2ccccn2)cc1] | 987 |
| 10 | E-2 | 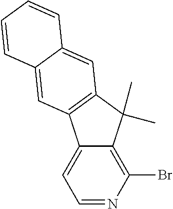 [SMILES: CC1(C)c2cc3ccccc3cc2-c2ccnc(Br)c21] | 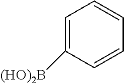 | 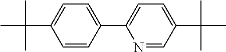 [SMILES: CC(C)(C)c1ccc(-c2ccc(C(C)(C)C)cn2)cc1] | 1099 |
| 11 | E-14 | 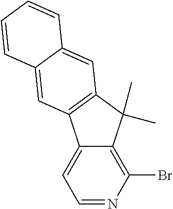 [SMILES: CC1(C)c2cc3ccccc3cc2-c2ccnc(Br)c21] | 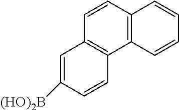 [SMILES: OB(O)c1ccc2c(ccc3ccccc32)c1] | 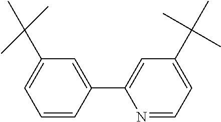 [SMILES: CC(C)(C)c1cccc(-c2cc(C(C)(C)C)ccn2)c1] | 1299 |
| 12 | E-18 | 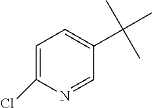 | 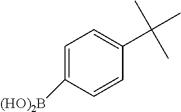 | 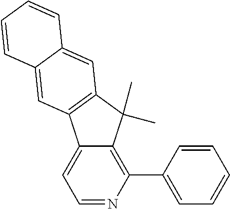 [SMILES: CC1(C)c2cc3ccccc3cc2-c2ccnc(-c3ccccc3)c21] | 1045 |
| 13 | E-26 | 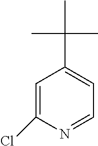 | 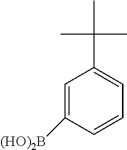 | 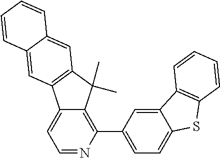 [SMILES: CC1(C)c2cc3ccccc3cc2-c2ccnc(-c3ccc4sc5ccccc5c4c3)c21] | 1151 |
| 14 | F-2 | 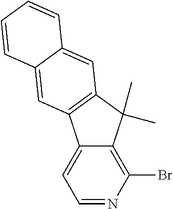 [SMILES: CC1(C)c2cc3ccccc3cc2-c2ccnc(Br)c21] | 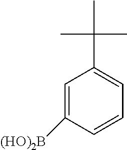 | 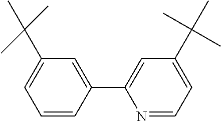 [SMILES: CC(C)(C)c1cccc(-c2cc(C(C)(C)C)ccn2)c1] | 1221 |
| 15 | F-5 | 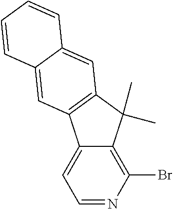 [SMILES: CC1(C)c2cc3ccccc3cc2-c2ccnc(Br)c21] | 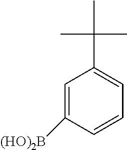 | 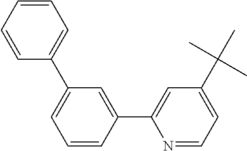 [SMILES: CC(C)(C)c1ccnc(-c2cccc(-c3ccccc3)c2)c1] | 1231 |
| 16 | F-11 | 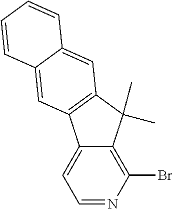 [SMILES: CC1(C)c2cc3ccccc3cc2-c2ccnc(Br)c21] | 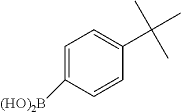 | 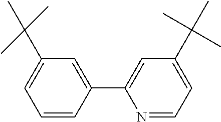 [SMILES: CC(C)(C)c1cccc(-c2cc(C(C)(C)C)ccn2)c1] | 1221 |
| 17 | G-1 | 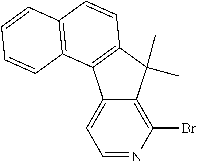 [SMILES: CC1(C)c2ccc3ccccc3c2-c2ccnc(Br)c21] | 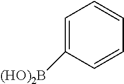 | 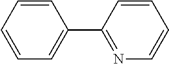 [SMILES: c1ccc(-c2ccccn2)cc1] | 987 |
| 18 | G-23 | 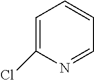 | 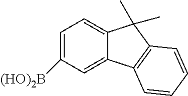 [SMILES: CC1(C)c2ccccc2-c2cc(B(O)O)ccc21] | 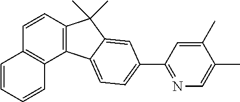 [SMILES: Cc1cnc(-c2ccc3c(c2)C(C)(C)c2ccc4ccccc4c2-3)cc1C] | 1081 |
| 19 | H-1 | 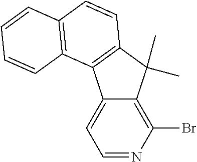 [SMILES: CC1(C)c2ccc3ccccc3c2-c2ccnc(Br)c21] | 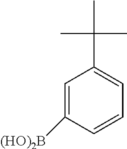 | 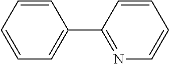 [SMILES: c1ccc(-c2ccccn2)cc1] | 1099 |
| 20 | H-5 | 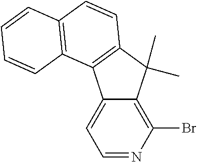 [SMILES: CC1(C)c2ccc3ccccc3c2-c2ccnc(Br)c21] | 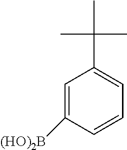 | 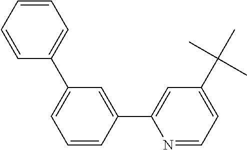 [SMILES: CC(C)(C)c1ccnc(-c2cccc(-c3ccccc3)c2)c1] | 1231 |
| 21 | H-14 | 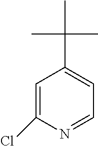 | 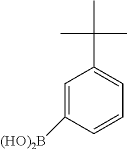 | 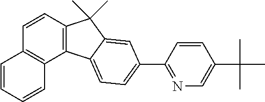 [SMILES: CC(C)(C)c1ccc(-c2ccc3c(c2)C(C)(C)c2ccc4ccccc4c2-3)nc1] | 1101 |

### Example 22 (Synthesis of Exemplified Compound C-35)

Exemplified Compound C-35 was synthesized according to the following scheme. Intermediate f-4 was synthesized using raw material f-3 in the same manner as in Example 1.

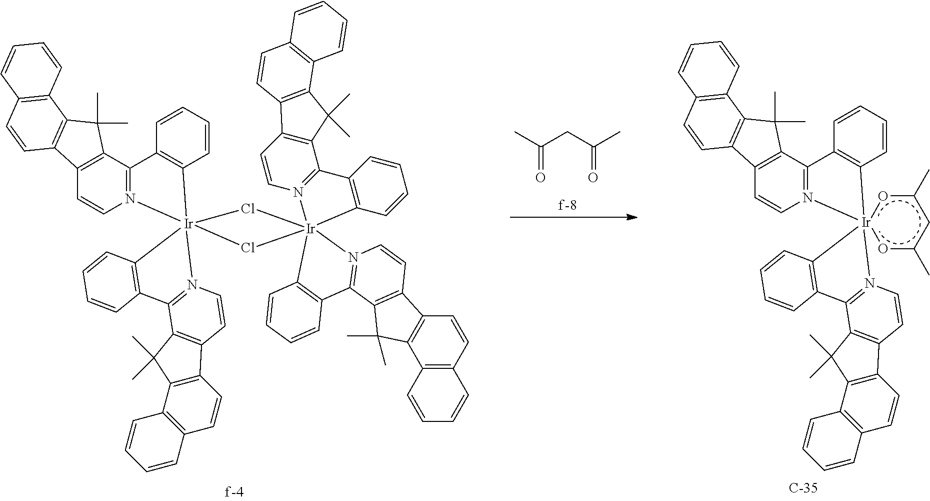

The following reagents and solvents presented below were placed into a 100 mL recovery flask.
Compound f-7:1.73 g (1.00 mmol)
Compound f-8:0.40 g (4.00 mmol)
Sodium carbonate: 1.06 g (10.0 mmol)
Ethoxyethanol: 33 mL
Water: 12 mL

The reaction solution was then heated and stirred at 100° C. for 5 hours under a nitrogen stream. After cooling, methanol was added, and the product was filtered and rinsed with methanol. Thus, 0.33 g (yield: 35%) of yellow solid (C-35) was obtained.

Exemplified compound C-35 was subjected to mass spectrometry using MALDI-TOF-MS (Autoflex LRF manufactured by Bruker).

MALDI-TOF-MS

Measured value: m/z=933, Calculation value: C₅₃H₄₆IrO₂N₃=933

### Examples 23 to 28 (Synthesis of Exemplified Compounds)

Exemplified compounds of Examples 23 to 28 presented in Table 4 were synthesized in the same manner as in Example 22, except for replacing raw materials f-3 and f-8 used in Example 22 with raw materials 1 and 2, respectively. The measured values m/z of the mass spectrometry results obtained in the same manner as in Example 22 are also presented.

TABLE 4

| | Exemplified | | | |
|---|---|---|---|---|
| Example | compound | Raw material 1 | Raw material 2 | m/z |
| 24 | D-23 | 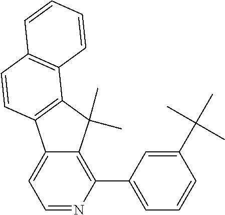 [SMILES: CC(C)(C)c1cccc(-c2nccc3c2C(C)(C)c2c-3ccc3ccccc23)c1] | 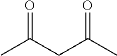 | 1044 |
| 25 | E-36 | 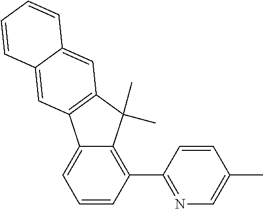 [SMILES: Cc1ccc(-c2cccc3c2C(C)(C)c2cc4ccccc4cc2-3)nc1] | 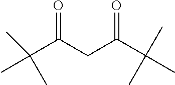 | 1044 |
| 26 | F-23 | 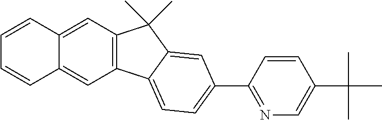 [SMILES: CC(C)(C)c1ccc(-c2ccc3c(c2)C(C)(C)c2cc4ccccc4cc2-3)nc1] | 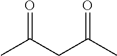 | 1044 |
| 27 | G-36 | 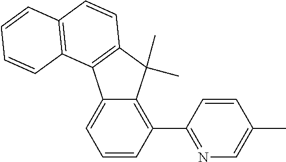 [SMILES: Cc1ccc(-c2cccc3c2C(C)(C)c2ccc4ccccc4c2-3)nc1] | 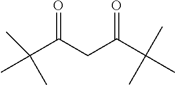 | 1044 |
| 28 | H-24 | 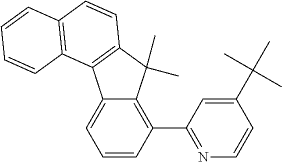 [SMILES: CC(C)(C)c1ccnc(-c2cccc3c2C(C)(C)c2ccc4ccccc4c2-3)c1] | 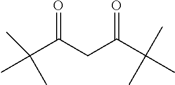 | 1128 |

### Example 29 (Synthesis of Exemplified Compound C-31)

Exemplified Compound C-31 was synthesized according to the following scheme.

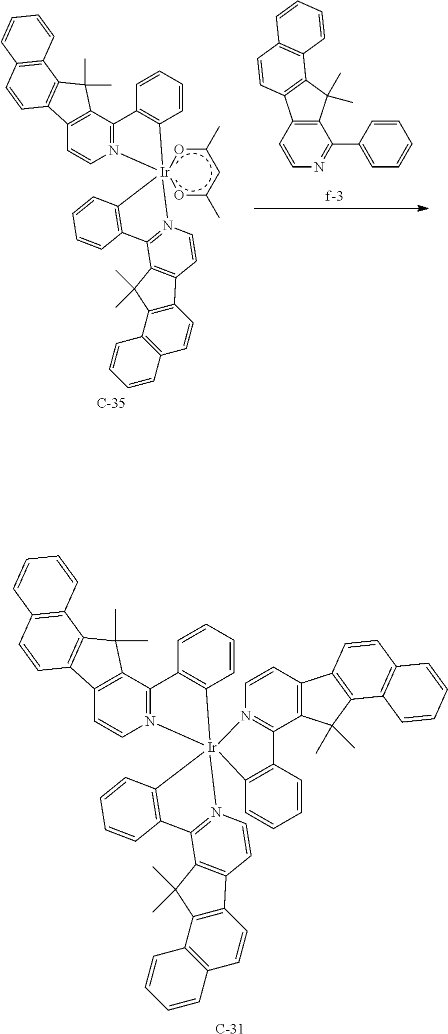

### (1) Synthesis of Exemplified Compound C-31

The following reagents and solvents presented below were placed into a 100 mL recovery flask.
Compound C-35:0.93 g (1.00 mmol)
Compound f-3:0.80 g (2.50 mmol)
Sodium carbonate: 1.06 g (10.0 mmol)
Glycerol: 40 mL

After being degassed with nitrogen, the reaction solution was heated and stirred at 180° C. for 7 hours. After cooling, methanol was added, and the product was filtered and rinsed with methanol. The resulting solid was purified by silica gel column chromatography (mixture of toluene and ethyl acetate) to afford 0.15 g (yield: 13%) of yellow solid

### (Exemplified Compound J-1).

Exemplified compound C-31 was subjected to mass spectrometry using MALDI-TOF-MS (Autoflex LRF manufactured by Bruker).

MALDI-TOF-MS

Measured value: m/z=1153, Calculation value: C₇₂H₅₄IrN₃=1153

### Examples 30 to 32 (Synthesis of Exemplified Compounds)

Exemplified compounds of Examples 30 to 32 presented in Table 5 were synthesized in the same manner as in Example 29, except for replacing raw materials C-35 and f-3 used in Example 29 with raw materials 1 and 2, respectively. The measured values m/z of the mass spectrometry results obtained in the same manner as in Example 29 are also presented.

TABLE 5

| | Exemplified | | | |
|---|---|---|---|---|
| Example | compound | Raw material 1 | Raw material 2 | m/z |
| 30 | D-19 | D-23 | 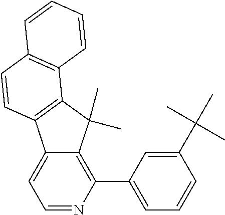 [SMILES: CC(C)(C)c1cccc(-c2nccc3c2C(C)(C)c2c-3ccc3ccccc23)c1] | 1321 |
| 31 | F-19 | F-23 | 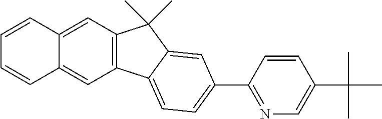 [SMILES: CC(C)(C)c1ccc(-c2ccc3c(c2)C(C)(C)c2cc4ccccc4cc2-3)nc1] | 1321 |
| 32 | F-20 | F-24 | 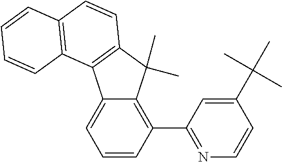 [SMILES: CC(C)(C)c1ccnc(-c2cccc3c2C(C)(C)c2ccc4ccccc4c2-3)c1] | 1321 |

### Example 33

An organic light-emitting element having a bottom emission structure was prepared which included an anode, a hole injection layer, a hole transport layer, an electron blocking layer, a luminescent layer, a hole blocking layer, an electron transport layer, an electron injection layer, and a cathode, in this order, on a substrate.

First, ITO was deposited on a glass substrate and then subjected to desired patterning to form an ITO electrode (anode). The thickness of the ITO electrode was 100 nm at this time. The resulting substrate with the ITO electrode was used as an ITO substrate in the following step. Then, organic compound layers and an electrode layer, as presented in Table 6, were continuously formed on the ITO substrate by vapor deposition with resistance heating in a vacuum chamber at 1.3×10⁻⁴ Pa. In this operation, the area of the opposing electrode (metal electrode layer, cathode) was adjusted to 3 mm².

TABLE 6

| | |
|---|---|
| | Thickness |
| Material | (nm) |

| | | |
|---|---|---|
| Cathode | Al | 100 |
| Electron injection layer (EIL) | LiF | 1 |
| Electron transport layer (ETL) | ET2 | 20 |
| Hole blocking layer (HBL) | ET12 | 25 |

| | Host | Dopant | |
|---|---|---|---|
| | material | material | |
| Luminescent layer (EML) | Q-1-18 | C-3 | 30 |
| Luminescent layer mass % | 88 | 12 | |

| | | |
|---|---|---|
| Electron blocking layer (EBL) | HT7 | 10 |
| Hole transport layer (HTL) | HT2 | 20 |
| Hole injection layer (HIL) | HT16 | 5 |

The properties of the resulting element were measured and evaluated. The luminous efficiency of the light-emitting element was 68 cd/A.

Furthermore, a continuous driving test was conducted at a current density of 50 mA/cm², and the period until when the luminance was 5% degraded was measured. This period in the present Example was defined as 1.0.

For measuring apparatuses used in the present Example, specifically, the current-voltage characteristics were measured with a microammeter 4140B manufactured by Hewlett Packard, and the emission luminance was measured with BM7 manufactured by Topcon.

### Examples 34 to 38, COMPARATIVE EXAMPLES 1 to 3

In Examples 34 to 38 and Comparative Examples 1 to 3, organic light-emitting elements were prepared in the same manner as in Example 33, except for using the materials presented in Table 7 for the luminescent layer as needed. The resulting elements were evaluated in the same manner as in Example 33. Furthermore, a continuous driving test was conducted at a current density of 50 mA/cm², and the period until when the luminance was 5% degraded was measured. The period to luminance degradation is presented as the ratio to the period to 5% degradation in luminance in Example 33, which was defined as 1.0.

The measurement results are presented in Table 7.

Compounds 0-2-1 and A-1 are presented below.

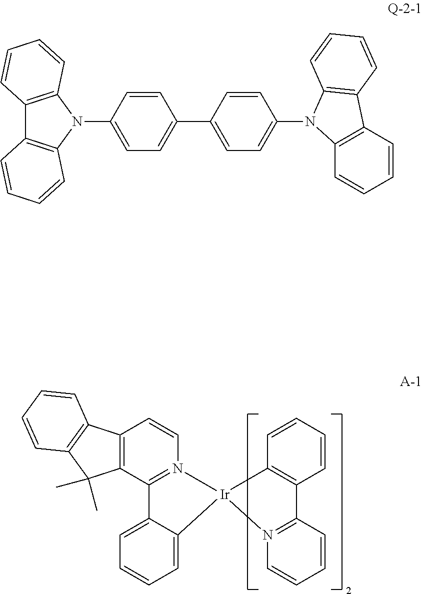

TABLE 7

| | EML | | | |
|---|---|---|---|---|
| | Host | Dopant | Efficiency | Ratio of period until |
| | material | material | Cd/A | luminance degradation |
| Example 34 | Q-1-24 | C-1 | 65 | 1.1 |
| Example 35 | Q-1-19 | D-1 | 67 | 1.1 |
| Example 36 | Q-1-22 | D-10 | 66 | 1.0 |
| Example 37 | Q-1-18 | E-2 | 68 | 0.9 |
| Example 38 | Q-1-14 | H-14 | 66 | 0.8 |
| Comparative | Q-2-1 | A-1 | 48 | 0.2 |
| Example 1 | | | | |
| Comparative | Q-2-1 | D-1 | 54 | 0.4 |
| Example 2 | | | | |
| Comparative | HT19 | E-2 | 55 | 0.5 |
| Example 3 | | | | |

Table 7 suggests that the light-emitting elements according to the present disclosure have high luminous efficiency and exhibit reduced degradation in luminance. In Comparative Example 1, the light-emitting element, in which an organometallic complex with an azafluorene ring was used as the dopant material, had low luminous efficiency and exhibited large degradation in luminance. In Comparative Examples 2 and 3, the light-emitting elements, in which the host material was not hydrocarbon and contained highly polar atoms such as nitrogen, had low luminous efficiency because of weak interaction with the iridium complex of the disclosure and exhibited large degradation in luminance because of low stability of the host material.

Thus, using any of the compounds according to the present disclosure, represented by general formulas (1) to (3) as the luminescent dopant and, in addition, selecting a suitable host material can provide an element with high efficiency and excellent endurance.

### Example 39

An organic light-emitting element having a bottom emission structure was prepared which included an anode, a hole injection layer, a hole transport layer, an electron blocking layer, a luminescent layer, a hole blocking layer, an electron transport layer, an electron injection layer, and a cathode, in this order, on a substrate.

First, ITO was deposited on a glass substrate and then subjected to desired patterning to form an ITO electrode (anode). The thickness of the ITO electrode was 100 nm at this time. The resulting substrate with the ITO electrode was used as an ITO substrate in the following step. Then, organic compound layers and an electrode layer, as presented in Table 8, were continuously formed on the ITO substrate by vapor deposition with resistance heating in a vacuum chamber at 1.3×10⁻⁴ Pa. In this operation, the area of the opposing electrode (metal electrode layer, cathode) was adjusted to 3 mm².

TABLE 8

| | | | | Thickness |
|---|---|---|---|---|
| | Material | | | (nm) |
| Cathode | Al | | | 100 |
| Electron injection layer (EIL) | LiF | | | 1 |
| Electron transport layer (ETL) | ET2 | | | 20 |
| Hole blocking layer (HBL) | ET12 | | | 20 |
| | Host | Assist | Dopant | |
| | material | material | material | |
| Luminescent layer (EML) | Q-1-19 | S-1-25 | C-3 | 30 |
| Luminescent layer mass % | 65 | 25 | 10 | |

| | | |
|---|---|---|
| Electron blocking layer (EBL) | HT7 | 15 |
| Hole transport layer (HTL) | HT2 | 20 |
| Hole injection layer (HIL) | HT16 | 5 |

The properties of the resulting element were measured and evaluated. The luminous efficiency of the light-emitting element was 66 cd/A.

Furthermore, a continuous driving test was conducted at a current density of 50 mA/cm², and the period until when the luminance was 5% degraded was measured. This period in the present Example was defined as 1.0.

For measuring apparatuses used in the present Example, specifically, the current-voltage characteristics were measured with a microammeter 4140B manufactured by Hewlett Packard, and the emission luminance was measured with BM7 manufactured by Topcon.

### Examples 40 TO 44, Comparative Examples 4 to 6

In Examples 40 to 44, organic light-emitting elements were prepared in the same manner as in Example 39, except for using the materials presented in Table 9 as the dopant material as needed. The resulting elements were evaluated in the same manner as in Example 39. Furthermore, a continuous driving test was conducted at a current density of 50 mA/cm², and the period until when the luminance was 5% degraded was measured. The period to luminance degradation is presented as the ratio to the period to 5% degradation in luminance in Example 39, which was defined as 1.0.

The measurement results are presented in Table 9.

TABLE 9

| | EML | | | | Ratio of period |
|---|---|---|---|---|---|
| | Host | Assist | Dopant | Efficiency | until luminance |
| | material | material | material | Cd/A | degradation |
| Example 40 | Q-1-24 | S-1-5 | C-1 | 65 | 0.9 |
| Example 41 | Q-1-18 | S-1-25 | D-1 | 66 | 1.1 |
| Example 42 | Q-1-22 | S-1-25 | D-10 | 67 | 0.9 |
| Example 43 | Q-1-20 | S-2-6 | E-2 | 61 | 1.0 |
| Example 44 | Q-1-14 | S-2-8 | G-1 | 66 | 0.8 |
| Comparative | Q-2-1 | S-1-4 | H-14 | 55 | 0.2 |
| Example 4 | | | | | |
| Comparative | HT-12 | S-1-25 | D-1 | 56 | 0.3 |
| Example 5 | | | | | |
| Comparative | HT-13 | S-4-1 | E-2 | 54 | 0.4 |
| Example 6 | | | | | |

Table 9 suggests that the light-emitting elements according to the present disclosure have high luminous efficiency and exhibit reduced degradation in luminance. In Comparative Examples 4 to 6, the light-emitting elements, in which the host material was not hydrocarbon and contained highly polar atoms such as a nitrogen atom or a sulfur atom, had low luminous efficiency because of weak interaction with the iridium complex of the disclosure and exhibited large degradation in luminance because of low stability of the host material.

Thus, using any of the compounds according to the present disclosure, represented by general formulas (1) to (3) as the dopant material and, in addition, selecting suitable host and assist materials can provide an element with high efficiency and excellent endurance.

The organometallic complex according to the present disclosure can be an organometallic complex with excellent luminous efficiency when used in organic light-emitting elements.

While the present disclosure has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

1. An organometallic complex represented by any one of formulas (1) to (3): 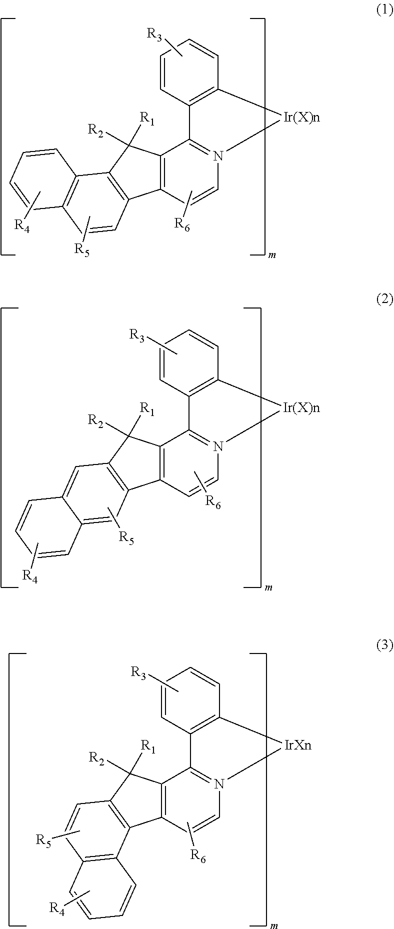
wherein in formulas (1) to (3), R₁ and R₂ are each independently selected from the group consisting of a hydrogen atom, a deuterium atom, halogen atoms, substituted or unsubstituted alkyl groups, substituted or unsubstituted silyl groups, and substituted or unsubstituted aryl groups;
wherein R₃s each independently represent a substituent of the phenyl group and is independently selected from the group consisting of a deuterium atom, halogen atoms, a cyano group, substituted or unsubstituted alkyl groups, substituted or unsubstituted alkoxy groups, substituted or unsubstituted silyl groups, substituted or unsubstituted aryl groups, substituted or unsubstituted heterocyclic groups, and substituted or unsubstituted amino groups, and the R₃s may form a ring with each other;
wherein R₄ to R₆ are substituents of the ring structures forming an azabenzofluorene and are each independently selected from the group consisting of a deuterium atom, halogen atoms, a cyano group, substituted or unsubstituted alkyl groups, substituted or unsubstituted alkoxy groups, substituted or unsubstituted silyl groups, substituted or unsubstituted aryl groups, substituted or unsubstituted heterocyclic groups, and substituted or unsubstituted amino groups;
wherein m represents an integer of 1 to 3, n represents an integer of 0 to 2, and m+n is 3; and
wherein X represents a bidentate ligand, the substructure Ir(X)n is represented by either formula (4) or (5), and three ligands are the same or different: 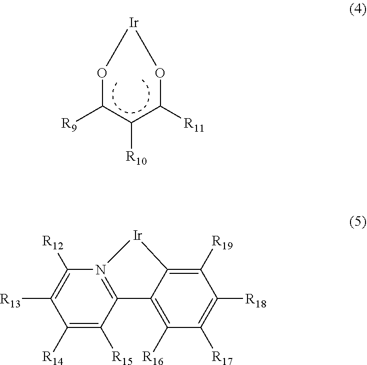
wherein in formula (4) or (5), R₉ to R₁₉ are each independently selected from the group consisting of a hydrogen atom, a deuterium atom, halogen atom atoms, a cyano group, substituted or unsubstituted alkyl groups, substituted or unsubstituted alkoxy groups, substituted or unsubstituted silyl groups, substituted or unsubstituted aryl groups, and substituted or unsubstituted heterocyclic groups, and substituents of R₁₆ to R₁₉ may form a ring with each other.

2. The organometallic complex according to claim 1, wherein in formulas (1) to (3), a plurality of R₃s form a ring structure that is a condensed ring structure of four or fewer rings.

3. The organometallic complex according to claim 2, wherein in formulas (1) to (3), the ring structure formed by a plurality of R₃s is represented by any one of the following formulas (10) to (20): 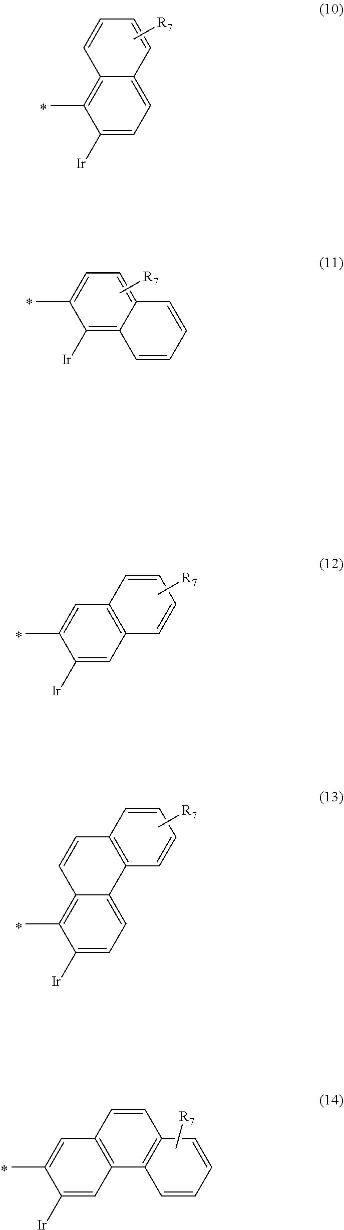 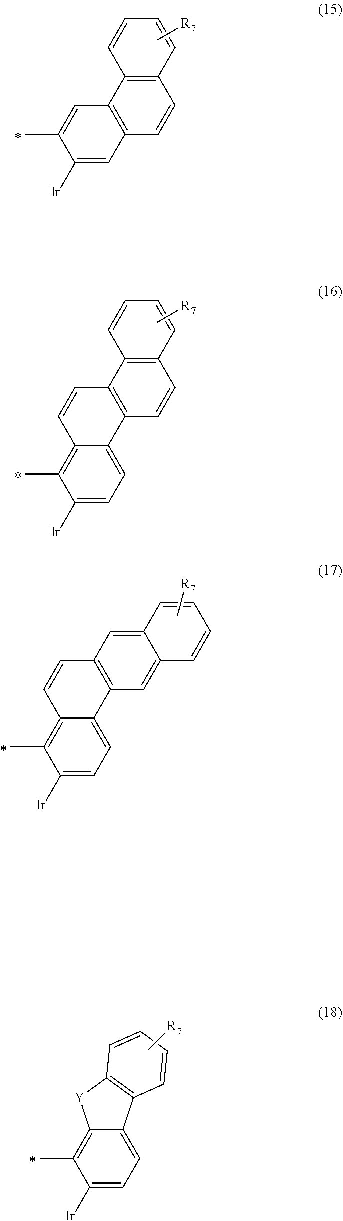 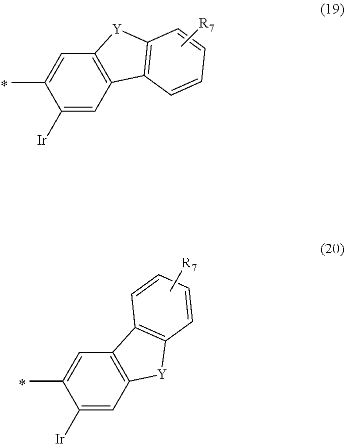
wherein R₇s in formulas (10) to (20) are each independently selected from the group consisting of a deuterium atom, halogen atoms, a cyano group, substituted or unsubstituted alkyl groups, substituted or unsubstituted alkoxy groups, substituted or unsubstituted silyl groups, substituted or unsubstituted aryl groups, and substituted or unsubstituted heterocyclic groups; and Y represents any one of an oxygen atom, a sulfur atom, and C(R₂₀) (R₂₁), wherein R₂₀ and R₂₁ are each independently selected from the group consisting of a hydrogen atom, a deuterium atom, substituted or unsubstituted alkyl groups, substituted or unsubstituted silyl groups, and substituted or unsubstituted aryl groups, and asterisk * indicates the position of the bond to the azabenzofluorene ring.

4. The organometallic complex according to claim 3, wherein in formulas (1) to (3), the ring structure formed by a plurality of R₃s is represented by any one of formulas (11), (12), (14), (15), (17), (19), and (20).

5. The organometallic complex according to claim 4, wherein in formulas (1) to (3), R₁ and R₂ are substituents.

6. The organometallic complex according to claim 5,
wherein in formulas (1) to (3), R₁ and R₂ are each a halogen atom or a substituted or unsubstituted alkyl group with 1 to 4 carbon atoms.

7. The organometallic complex according to claim 6, wherein in formulas (1) to (3), R₁ and R₂ are each a methyl group or a fluorine atom.

8. The organometallic complex according to claim 7, wherein in formulas (1) to (3), at least one of R₃ or R₄ is a substituent.

9. The organometallic complex according to claim 8, wherein in formulas (1) to (3), at least one of R₃ or R₄ is a tertiary alkyl group with 4 to 10 carbon atoms.

10. The organometallic complex according to claim 9, wherein in formulas (1) to (3), at least one of R₃ or R₄ is a tert-butyl group.

11. An organic light-emitting element comprising: a first electrode and a second electrode; and
an organic compound layer disposed between the first electrode and the second electrode,
wherein the organic compound layer contains the organometallic complex as set forth in claim 1.

12. The organic light-emitting element according to claim 11, wherein
the organic compound layer includes a luminescent layer, and
the luminescent layer contains the organometallic complex.

13. The organic light-emitting element according to claim 12, wherein
the luminescent layer further contains a first compound, and
the first compound has a higher lowest excited triplet energy than the organometallic complex.

14. The organic light-emitting element according to claim 13, wherein the first compound is a hydrocarbon compound.

15. The organic light-emitting element according to claim 13, wherein the first compound has at least one skeleton of triphenylene, naphthalene, phenanthrene, chrysene, or fluoranthene.

16. The organic light-emitting element according to claim 13, wherein the first compound contains no SP3 carbon.

17. The organic light-emitting element according to claim 13, wherein
the luminescent layer further contains a second compound, and
the second compound has a lowest excited triplet energy equal to or higher than the lowest excited triplet energy of the organometallic complex.

18. The organic light-emitting element according to claim 17, wherein the second compound has an electron-withdrawing group.

19. The organic light-emitting element according to claim 18, wherein the second compound has at least one of the following structures: 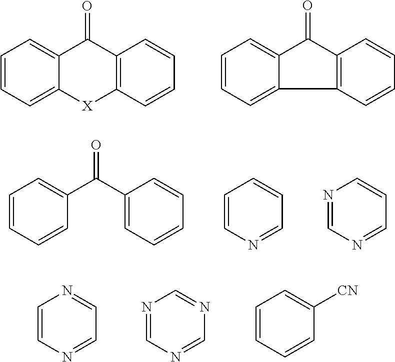
wherein X represents an oxygen atom, a sulfur atom, or a substituted or unsubstituted carbon atom.

20. The organic light-emitting element according to claim 19, wherein the second compound is any one of the following compounds:

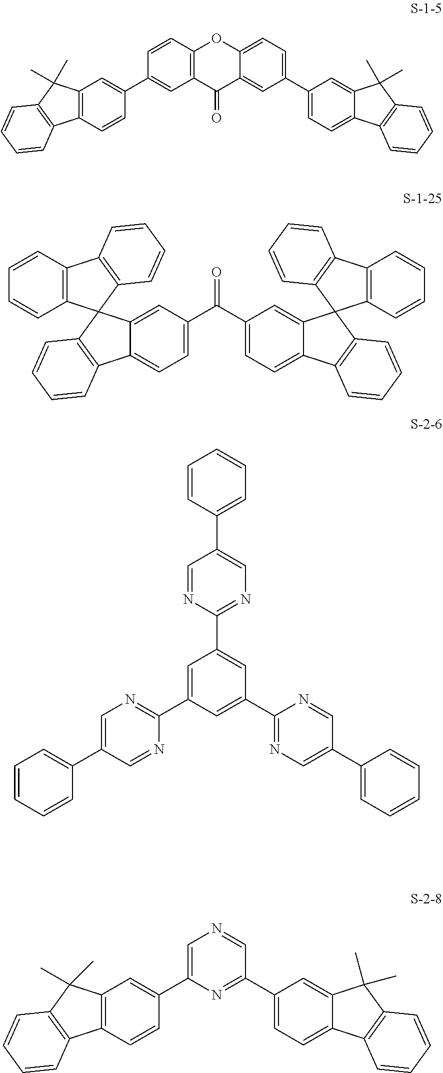 [SMILES: CC1(C)c2ccccc2-c2ccc(-c3ccc4oc5ccc(-c6ccc7c(c6)C(C)(C)c6ccccc6-7)cc5c(=O)c4c3)cc21 ; O=C(c1ccc2c(c1)C1(c3ccccc3-c3ccccc31)c1ccccc1-2)c1ccc2c(c1)C1(c3ccccc3-c3ccccc31)c1ccccc1-2 ; c1ccc(-c2cnc(-c3cc(-c4ncc(-c5ccccc5)cn4)cc(-c4ncc(-c5ccccc5)cn4)c3)nc2)cc1 ; CC1(C)c2ccccc2-c2ccc(-c3cncc(-c4ccc5c(c4)C(C)(C)c4ccccc4-5)n3)cc21]

21. A display device comprising: a plurality of pixels, wherein at least one of the pixels includes the organic light-emitting element as set forth in claim 11, and a transistor connected to the organic light-emitting element.

22. A photoelectric conversion device comprising:
an optical section including a plurality of lenses;
an imaging element operable to receive light that has passed through the optical section; and
a display section on which an image taken by the imaging element is displayed,
wherein the display section includes the organic light-emitting element as set forth in claim 11.

23. An electronic apparatus comprising:
a display section including the organic light-emitting element as set forth of claim 11;
a housing provided with the display section; and
a communication section provided at the housing, the communication section being operable to communicate with the outside.

24. A lighting device comprising:
a light source including the organic light-emitting element as set forth in claim 11; and
a light diffusing section or an optical film through which light emitted from the light source passes.

25. A movable apparatus comprising:
a lighting fixture including the organic light-emitting element as set forth in claim 11; and
an apparatus body provided with the lighting fixture.

26. An image forming apparatus comprising:
a photosensitive member; and
an exposure light source operable to expose the photosensitive member,
wherein the exposure light source includes the organic light-emitting element as set forth in claim 11.
